(19) United States
(12) Patent Application Publication
(10) Pub. No.: US 2018/0039372 A1
(43) Pub. Date: Feb. 8, 2018

(54) ELECTRONIC APPARATUS WITH DISPLAY

(71) Applicant: Samsung Electronics Co., Ltd., Suwon-si (KR)

(72) Inventors: Eunsung CHO, Ansan-si (KR); Jung Won KIM, Hwaseong-si (KR); Euijin KIM, Suwon-si (KR); Han-Vit KANG, Suwon-si (KR); Ho-Kyung KANG, Daegu (KR); Byeong-Cheol KIM, Suwon-si (KR); Hyungsup BYEON, Suwon-si (KR); Jeongsik JEONG, Hwaseong-si (KR); Kwang-Tai KIM, Yongin-si (KR); Hyun-Ju HONG, Osan-si (KR)

(21) Appl. No.: 15/667,147

(22) Filed: Aug. 2, 2017

(30) Foreign Application Priority Data
Aug. 2, 2016 (KR) 10-2016-0098335

(51) Int. Cl. G06F 3/041; H01L 51/52; H05K 5/03; H01L 27/32; G06F 3/044; H05K 5/00

(52) U.S. Cl. CPC G06F 3/0416; G06F 3/044; G06F 3/0412; H05K 5/0017; H05K 5/03; H01L 27/323; H01L 51/524; G06F 2203/04105; G06F 2203/04111

(57) ABSTRACT

An electronic apparatus is provided that includes a housing comprising a first surface facing a first direction, a second surface facing a second direction which is opposite to the first direction, and a transparent cover which forms at least part of the first surface, a display interposed between the first and second surfaces of the housing and exposed through the transparent cover, a first electrode interposed between the transparent cover and the display, a second electrode interposed between the first electrode and the display, a third electrode interposed between the second electrode and the display, a first dielectric layer interposed between the first and second electrodes, a second dielectric layer interposed between the second and third electrodes, and a processor configured to detect a location of a touch on the first surface using the first and second electrodes, and detect pressure on the first surface using the second and third electrodes.

### CROSS-REFERENCE TO RELATED APPLICATION(S)

This application claims the benefit under 35 U.S.C. § 119(a) of a Korean patent application filed on Aug. 2, 2016 in the Korean Intellectual Property Office and assigned Serial number 10-2016-0098335, the entire disclosure of which is hereby incorporated by reference.

### TECHNICAL FIELD

The present disclosure relates generally to an electronic apparatus including a display.

### BACKGROUND

An electronic device mostly conducts a multi-function in addition to various functions. For example, the electronic device can perform a mobile communication function, a data communication function, a photographing function, a sound recording function, and so on. The electronic device can provide a user interaction through various input means. In particular, recent electronic devices employ a pressure sensor (or a force sensor) for detecting a pressure level, as a new input means.

When the pressure sensor for detecting the pressure level is applied to the electronic device, a thickness and a volume of the electronic device can increase. Alternatively, a separate control circuit for controlling the pressure sensor is added, thus increasing power consumption. Alternatively, when the pressure sensor is applied to a flexible electronic device, each layer can be detached.

The above information is presented as background information only to assist with an understanding of the present disclosure. No determination has been made, and no assertion is made, as to whether any of the above might be applicable as prior art with regard to the present disclosure.

### SUMMARY

Aspects of the present disclosure are to address at least the above-mentioned problems and/or disadvantages and to provide at least the advantages described below.

Accordingly, an aspect of the present disclosure is to provide an electronic apparatus. The electronic apparatus includes a housing including a first surface facing a first direction, a second surface facing a second direction which is opposite to the first direction, and a transparent cover which forms at least part of the first surface, a display interposed between the first surface and the second surface of the housing and exposed through the transparent cover, a first electrode interposed between the transparent cover and the display, a second electrode interposed between the first electrode and the display, a third electrode interposed between the second electrode and the display, a first dielectric layer interposed between the first electrode and the second electrode, a second dielectric layer interposed between the second electrode and the third electrode, and at least one processor electrically coupled to the display, the first electrode, the second electrode, and the third electrode, wherein the at least one processor is configured to detect a location of a touch input of an external object on the first surface using the first electrode and the second electrode, and detect pressure of the touch input of the external object on the first surface using the second electrode and the third electrode.

Another aspect of the present disclosure is to provide an electronic apparatus. The electronic apparatus includes a housing including a first surface facing a first direction, a second surface facing a second direction which is opposite to the first direction, and a transparent cover which forms at least part of the first surface, a display interposed between the first surface and the second surface of the housing and exposed through the transparent cover, a first electrode interposed between the transparent cover and the display, a second electrode interposed between the first electrode and the display, a third electrode substantially coplanar with the second electrode, a first dielectric layer interposed between the first electrode and the second electrode, a second dielectric layer interposed between the second electrode and the third electrode, and at least one processor electrically coupled to the display, the first electrode, the second electrode, and the third electrode, wherein the processor is configured to detect pressure of a touch input of an external object on the first surface using the first electrode and the second electrode, and detect a location of the touch input of the external object on the first surface using the first electrode and the third electrode.

Another aspect of the present disclosure is to provide an electronic apparatus. The electronic apparatus includes a housing comprising a first surface facing a first direction, a second surface facing a second direction which is opposite to the first direction, and a transparent cover which forms at least part of the first surface, a display interposed between the first surface and the second surface of the housing and exposed through the transparent cover, a first electrode interposed between the transparent cover and the display, a second electrode interposed between the transparent cover and the display, and at least one processor electrically coupled to the display, the first electrode, and the second electrode, wherein the processor is configured to detect a location of a touch input of an external object on the first surface using the first electrode and the second electrode, and detect pressure of the touch input of the external object on the first surface using the first electrode and the second electrode.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a diagram of a network system according to various embodiments of the present disclosure;

FIGS. 2A and 2B are block diagrams of an electronic apparatus according to various embodiments of the present disclosure;

FIG. 3 is a block diagram of a programming module according to various embodiments of the present disclosure;

FIG. 4 is a perspective view of an electronic apparatus according to various embodiments of the present disclosure;

FIG. 5 is an exploded view of an electronic apparatus according to various embodiments of the present disclosure;

FIG. 6 is a perspective view of a first electrode in an electronic apparatus according to various embodiments of the present disclosure;

FIG. 7 is a perspective view of a second electrode in an electronic apparatus according to various embodiments of the present disclosure;

FIG. 8 is a perspective view of a third electrode in an electronic apparatus according to various embodiments of the present disclosure;

FIG. 9A is a perspective view of a first electrode, a second electrode, and a third electrode in an electronic apparatus according to various embodiments of the present disclosure;

FIG. 9B is a plane view of a first electrode, a second electrode, and a third electrode in an electronic apparatus according to various embodiments of the present disclosure;

FIGS, 10A, 1013, 10C, 10D, 10E, 10F, 10G, 10H, and 10I are cross-sectional views taken along I-I′ of FIG. 5 according to various embodiments of the present disclosure;

FIG. 11A is a block diagram of an electronic apparatus according to various embodiments of the present disclosure;

FIGS. 11B, 11C, 11D, 11E, 11F, 11G, 11H, 11I, and 11J are graphs illustrating driving of an electronic apparatus according to various embodiments of the present disclosure;

FIG. 12 is an exploded view of an electronic apparatus according to various embodiments of the present disclosure;

FIG. 13A is a plane view of a first electrode in an electronic apparatus according to various embodiments of the present disclosure;

FIG. 13B is a plane view of a second electrode and a third electrode in an electronic apparatus according to various embodiments of the present disclosure;

FIG. 14A is a perspective view of a first electrode, a second electrode, and a third electrode in an electronic apparatus according to various embodiments of the present disclosure;

FIG. 14B is a plane view of a first electrode, a second electrode, and a third electrode in an electronic apparatus according to various embodiments of the present disclosure;

FIGS. 15A, 15B, 15C, 15D, 15E, 15F, and 15G are cross-sectional views taken along II-II′ of FIG. 12 according to various embodiments of the present disclosure;

FIG. 16 is an exploded view of an electronic apparatus according to various embodiments of the present disclosure;

FIG. 17A is a perspective view of a first electrode in an electronic apparatus according to various embodiments of the present disclosure;

FIG. 17B is a perspective view of a second electrode in an electronic apparatus according to various embodiments of the present disclosure;

FIGS. 18A, 18B, 18C, 18D, 18E, and 18F are cross-sectional views taken along III-III′ of FIG. 16 according to various embodiments of the present disclosure;

FIGS. 19A and 19B are block diagrams of an electronic apparatus according to various embodiments of the present disclosure;

FIG. 19C is graphs illustrating driving of an electronic apparatus according to various embodiments of the present disclosure;

FIGS. 20A, 20B, 20C, 20D, 20E, and 20F are block diagrams of an electronic apparatus according to various embodiments of the present disclosure;

FIGS. 21A, 21B, and 21C are block diagrams of an electronic apparatus according to various embodiments of the present disclosure;

FIG. 22 is an exploded view of an electronic apparatus according to various embodiments of the present disclosure;

FIGS. 23A, 23B, 23C, 23D, 23E, and 23F are cross-sectional views taken along IV-IV′ of FIG. 22 according to various embodiments of the present disclosure;

FIG. 24 is an exploded view of an electronic apparatus according to various embodiments of the present disclosure;

FIG. 25A is a front view of a first electrode in an electronic apparatus according to various embodiments of the present disclosure;

FIG. 25B is a front view of a second electrode in an electronic apparatus according to various embodiments of the present disclosure;

FIGS. 26A, 26B, 26C, 26D, 26E, and 26F are cross-sectional views taken along V-V′ of FIG. 24 according to various embodiments of the present disclosure; and

FIGS. 27A and 27B are block diagrams of an electronic apparatus according to various embodiments of the present disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the present disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the present disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the present disclosure. Accordingly, it should be apparent to those skilled in the art that the following description of various embodiments of the present disclosure is provided for illustration purpose only and not for the purpose of limiting the present disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

In the present disclosure, the expressions “have”, “can have”, “comprise”, “can comprise”, etc. indicate the existence of a corresponding feature (e.g., a numeral value, a function, an operation, or a constituent element such as a component, etc. and do not exclude the existence of an additional feature.

In the present disclosure, the expressions “A or B”, “at least one of A or/and B”, “one or more of A or/and B”, etc. can include all available combinations of items enumerated together. For example, “A or B”, “at least one of A and B”, or “at least one of A or B” can denote all of the cases of (1) including at least one A, (2) including at least one B, or (3) including all of at least one A and at least one B.

The expressions “1st”, “2nd”, “first”, “second”, etc. used in the present disclosure can modify various constituent elements irrespective of order and/or importance, and are just used to distinguish one constituent element from another constituent element and do not limit the corresponding constituent elements. For example, a first user device and a second user device can represent different user devices regardless of order or importance. For example, a first constituent element can be named a second constituent element without departing from the scope of right mentioned in the present disclosure and similarly, even the second constituent element can be interchangeably named the first constituent element.

When it is mentioned that any constituent element a first constituent element) is “(operatively or communicatively) coupled with/to” or is “connected to” another constituent element (e.g., a second constituent element), it will have to be understood that the any constituent element can be directly coupled to the other constituent element, or be coupled to the other constituent element through a further constituent element (e.g., a third constituent element). On the other hand, when it is mentioned that any constituent element (e.g., a first constituent element) is “directly coupled” or is “directly connected” to another constituent element (e.g., a second constituent element), it can be understood that a further constituent element (e.g., a third constituent element) does not exist between the any constituent element and another constituent element.

The expression “configured (or set) to˜” used in the present disclosure can be used interchangeably with, for example, “suitable for˜”, “having the capacity to˜”, “designed to˜”, “adapted to˜”, “made to˜”, or “capable of˜” in accordance to a situation. The term “configured (or set) to˜” may not necessarily mean only “specifically designed to” in hardware. Instead, in any situation, the expression “device configured to˜” can represent that the device is “capable of˜” together with other devices or components. For example, the phrase “processor configured (or set) to perform A, B, and C” can represent an exclusive processor (e.g., embedded processor) for performing a corresponding operation, or a generic-purpose processor (e.g., a central processing unit (CPU) or an application processor (AP)) capable of performing corresponding operations by executing one or more software programs stored in a memory device.

The terms used in the present disclosure are used to just describe specific example embodiments, and may not have an intention to limit the scope of various other embodiments. For example, the expression of a singular form can include the expression of a plural form unless the disclosure or corresponding description clearly dictates otherwise. The terms used herein inclusive of technological or scientific terms can have the same meaning as those commonly understood by a person having ordinary knowledge in the art mentioned in the present disclosure. Among the terms used in the present disclosure, the terms defined in a general dictionary can be interpreted as the same or similar meanings as the contextual meanings of a related technology, and are not interpreted as ideal or excessively formal meanings unless defined clearly in the present disclosure. According to cases, even if the term is defined in the present disclosure, it should not be interpreted to exclude example embodiments of the present disclosure.

An electronic device according to various example embodiments of the present disclosure can include at least one of a smart phone, a tablet personal computer (PC), a mobile phone, a video phone, an electronic book (e-book) reader, a desktop PC, a laptop PC, a netbook computer, a workstation, a server, a personal digital assistant (PDA), a portable multimedia player (PMP), a moving picture experts group (MPEG-1 or MPEG-2) audio layer 3 (MP3) player, a mobile medical instrument, a camera, or a wearable device, or the like, but is not limited thereto. According to various embodiments, the wearable device can include at least one of an accessory type (e.g., a watch, a ring, a wristlet, an anklet, a necklace, glasses, a contact lens, or a head-mounted-device (MID)), a fabric or clothing integrated type (e.g., electronic clothes), a body mount type (e.g., a skin pad or tattoo), or a bio implantation type (e.g., an implantable circuit), or the like, but is not limited thereto.

In various embodiments, the electronic device can be a home appliance. The home appliance can, for example, include at least one of a television (TV), a digital versatile disc (DVD) player, an audio system, a refrigerator, an air conditioner, a cleaner, an oven, a microwave, a washing machine, an air cleaner, a set-top box, a home automation control panel, a security control panel, a TV box (for example, Samsung HomeSync®, Apple TV®, or Google TV®), a game console (e.g., Xbox®, PlayStation®), an electronic dictionary, an electronic locking system, a camcorder, or an electronic frame, or the like, but is not limited thereto.

In another embodiment, the electronic device can include at least one of various medical instruments (e.g., various portable medical measurement instruments (i.e., a blood sugar measuring instrument, a heartbeat measuring instrument, a blood pressure measurement instrument, a body temperature measurement instrument, etc.), magnetic resonance angiography (MRA), magnetic resonance imaging (MRI), computerized tomography (CT), a photographing machine, an ultrasonic machine, etc.), a navigation device, a global navigation satellite system (GNSS), an event data recorder (IDR), a flight data recorder (FDR), a car infotainment device, an electronic equipment for ship (e.g., a navigation device for ship, a gyrocompass, etc.), avionics, a security instrument, a head unit for car, an industrial or home robot, an automatic teller's machine (ATM) of a financial institution, a point of sales (POS) of a shop, or an internet of things (IoT) device (e.g., an electric bulb, various sensors, an electricity or gas meter, a sprinkler device, a fire alarm, a thermostat, a streetlight, a toaster, an exerciser, a hot water tank, a heater, a boiler, etc.), or the like, but is not limited thereto.

According to various embodiments of the present disclosure, the electronic device can include at least one of a part of furniture or building/structure, an electronic board, an electronic signature receiving device, a projector, or various metering instruments (e.g., tap water, electricity, gas, a radio wave metering instrument, etc.), or the like, but is not limited thereto. In various embodiments of the present disclosure, the electronic device can be a combination of one or more of the aforementioned devices. The electronic device according to various embodiment can be a flexible electronic device. Also, the electronic device according to various embodiments of the present disclosure is not limited to the aforementioned instruments, and can include a new electronic device according to the development of a technology and as would be understood to be covered by the person of ordinary skill in the art.

An electronic device according to various embodiments is described below with reference to the accompanying drawings. In the present disclosure, the term ‘user’ can denote a person who uses the electronic device or a device (e.g., an artificial-intelligent electronic device) which uses the electronic device.

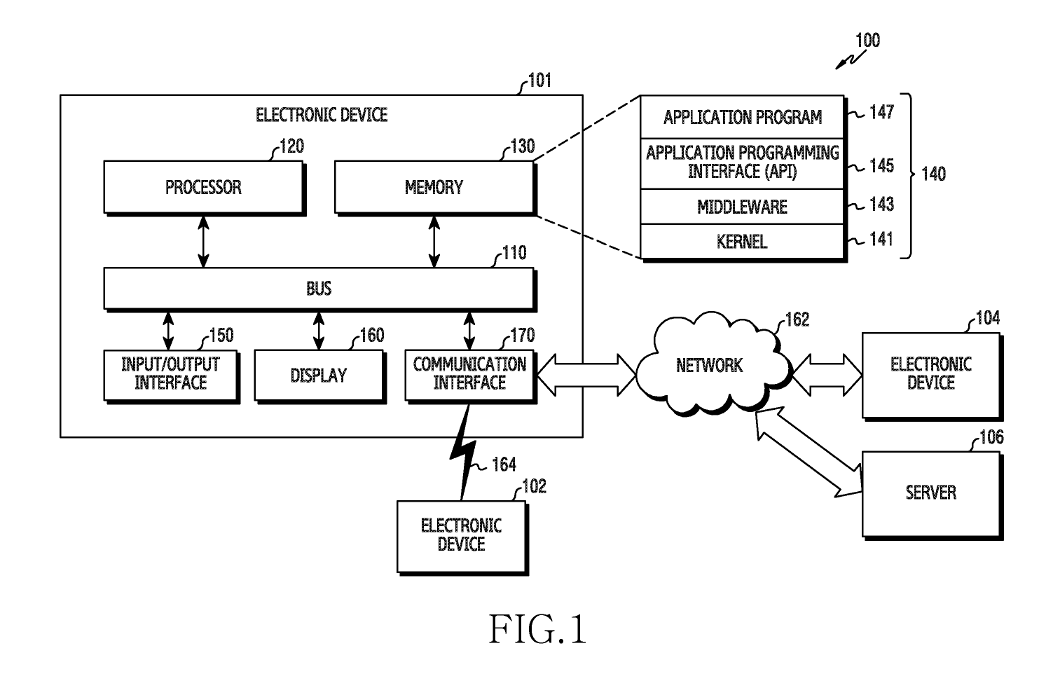

FIG. 1 is a diagram of a network system according to various embodiments of the present disclosure.

Referring to FIG. 1, an electronic device 101 within a network environment 100 in various embodiments is mentioned. The electronic device 101 can include a bus 110, a processor (e.g., including processing circuitry) 120, a memory 130, an input/output interface (e.g., including input/output circuitry) 150, a display 160, and a communication interface (e.g., including communication circuitry) 170. In various embodiments, the electronic device 101 can omit at least one of the constituent elements or additionally have another constituent element.

The bus 110 can, for example, include a circuit coupling the constituent elements 110 to 170 with one another and forwarding communication (e.g., a control message and/or data) between the constituent elements.

The processor 120 may include various processing circuitry, such as, for example, and without limitation, one or more of a dedicated processor, a CPU, an AP, or a communication processor (CP). The processor 120 can, for example, execute operation or data processing for control and/or communication of at least one another constituent element of the electronic device 101.

The memory 130 can include a volatile and/or non-volatile memory. The memory 130 can, for example, store a command or data related to at least one another constituent element of the electronic device 101. According to one example embodiment, the memory 130 can store a software and/or program 140. The program 140 can, for example, include a kernel 141, a middleware 143, an application programming interface (API) 145, an application program (or “application”) 147, etc. At least a part of the kernel 141, the middleware 143, or the API 145 can be called an operating system (OS).

The kernel 141 can, for example, control or manage system resources (e.g., bus 110, processor 120, memory 130, etc.) that are used for executing operations or functions implemented in the other programs (e.g., middleware 143, API 145, or application program 147). Also, the kernel 141 can provide an interface through which the middleware 143, the API 145, or the application program 147 can access the individual constituent element of the electronic device 101 and control or manage the system resources of the electronic device 101.

The middleware 143 can, for example, perform a relay role of enabling the API 145 or the application program 147 to communicate and exchange data with the kernel 141.

Also, the middleware 143 can process one or more work requests received from the application program 147 in accordance with the order of priority. For example, the middleware 143 can grant at least one of the application programs 147 the order of priority for using the system resources (e.g., bus 110, processor 120, memory 130, etc.) of the electronic device 101. For instance, the middleware 143 can perform scheduling, load balancing, etc. for the one or more work requests, by processing the one or more work requests in accordance with the priority order granted to the at least one of the application programs 147.

The API 145 is, for example, an interface for enabling the application program 147 to control a function of the kernel 141 or the middleware 143. And, the API 145 can, for example, include at least one interface or function (e.g., an instruction) for file control, window control, image processing, character control, etc.

The input/output interface 150 can, for example, include various input/output circuitry configured to play a role of an interface capable of forwarding a command or data inputted from a user or another external device, to the other constituent element(s) of the electronic device 101. Also, the input output interface 150 can output a command or data received from the other constituent element(s) of the electronic device 101, to the user or another external device.

The display 160 can, for example, include a liquid crystal display (LCD), a light emitting diode (LED) display, an organic light emitting diode (OLED) display, or a microelectromechanical systems (MEMS) display, or an electronic paper display, or the like, but is not limited thereto. The display 160 can, for example, display various contents (e.g., a text, an image, a video, an icon, a symbol, etc.) to a user. The display 160 can include a touch screen. And, for example, the display 160 can receive a touch, gesture, proximity, or hovering input that uses an electronic pen or a part of the user's body.

The communication interface 170 may include various communication circuitry and can, for example, establish communication between the electronic device 101 and an external device (e.g., 1st external electronic device 102, 2nd external electronic device 104, or server 106). For example, through wireless communication or wired communication, the communication interface 170 can be coupled to a network 162 and communicate with the external device (e.g., 2nd external electronic device 104 or server 106).

The wireless communication, for example, a cellular communication protocol, can use at least one of long term evolution (LTE), LIE-advanced (LTE-A), code division multiple access (CDMA), wideband CDMA (WCDMA), universal mobile telecommunications system (UNITS), wireless broadband (WiBro), global system for mobile communications (GSM), etc., for example. Also, the wireless communication can, for example, include a short-range communication 164. The short-range communication 164 can, for example, include at least one of Bluetooth (BT), near field communication (NEC), global navigation satellite system (GNSS), etc. In accordance with a use area, a bandwidth, etc., the GNSS can, for example, include at least one of a global positioning system (GPS), a Global navigation satellite system (Glonass), a Bei dou navigation satellite system (hereinafter, “Beidou”), Galileo, or the European global satellite-based navigation system. Below, in the present disclosure, the “GPS” can be used interchangeably with the “GNSS”. The wired communication can, for example, include at least one of a universal serial bus (USB), a high definition multimedia interface (HDMI), a recommended standard-232 (RS-232), a plain old telephone service (POTS), etc. The network 162 can include at least one of a telecommunications network, for example, a computer network (e.g., local area network (LAN) or wide area network (WAN)), the Internet, or a telephone network.

Each of the 1st and 2nd electronic devices 102 and 104 can be a device that is the same as or different in type from the electronic device 101. According to an embodiment, the server 106 can include a group of one or more servers. According to various embodiments, all or some of operations executed in the electronic device 101 can be executed in another or a plurality of electronic devices (e.g., electronic devices 102 and 104 or server 106). According to an embodiment, in case where the electronic device 101 performs some function or service automatically or in response to a request, instead of or additionally to executing the function or service in itself, the electronic device 101 can send a request for at least a partial function associated with this to another electronic device e.g., electronic device 102, 104 or server 106). The other electronic device (e.g., electronic device 102, 104 or server 106) can execute the requested function or additional function, and forward the execution result to the electronic device 101. The electronic device 101 can process the received result as it is or additionally and provide the requested function or service. For this, a cloud computing, distributed computing, or client-server computing technology can be used, for example.

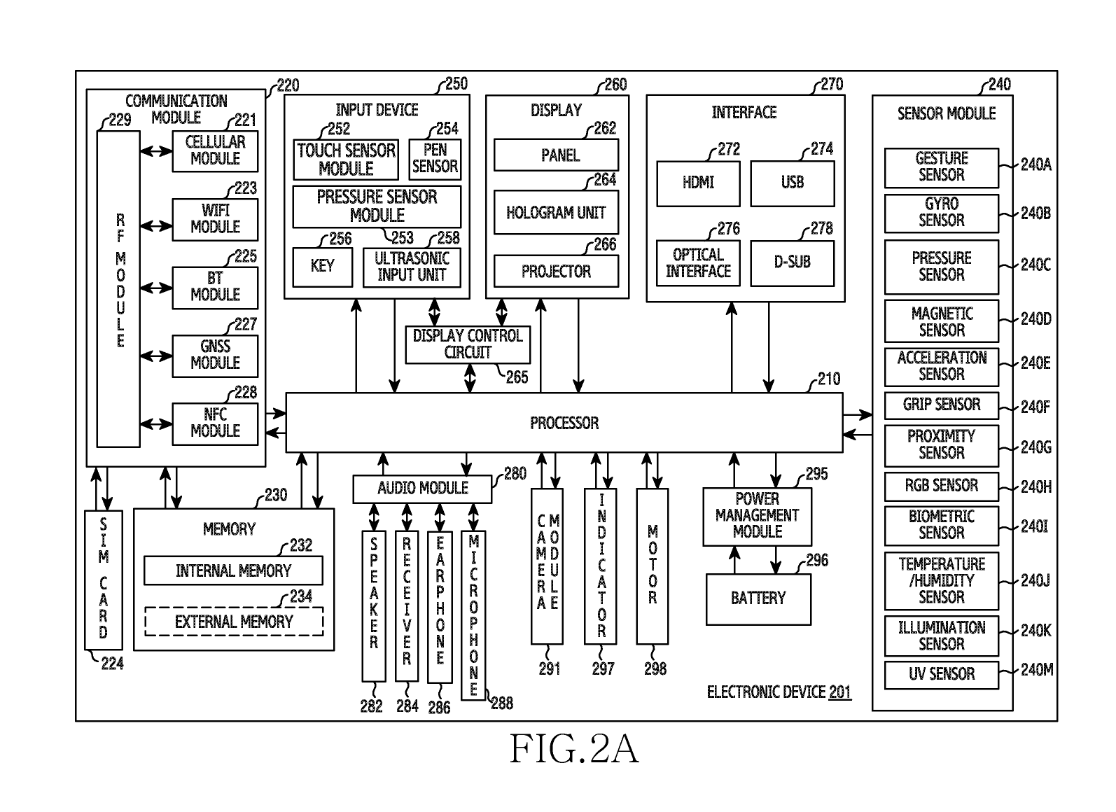

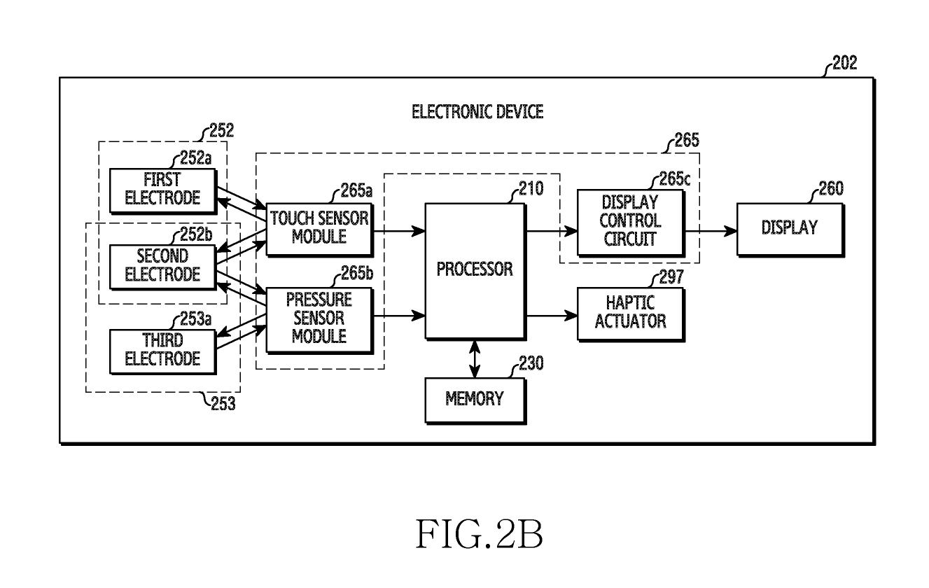

FIG. 2A is a block diagram illustrating an electronic device 201 according to various embodiments of the present disclosure.

Referring to FIG. 2A, the electronic device 201 can, for example, include the entire or part of the electronic device 101 illustrated in FIG. 1. The electronic device 201 can include one or more processors (e.g., AP) (e.g., including processing circuitry) 210, a communication module (e.g., including communication circuitry) 220, a subscriber identification module (SIM) 224, a memory 230, a sensor module 240, an input device (e.g., including input circuitry) 250, a display 260, an interface (e.g., including interface circuitry) 270, an audio module 280, a camera module 291, a power management module 295, a battery 296, an indicator 297, and a motor 298.

For example, by driving an operating system or an application program, the processor 210 can control a plurality of hardware or software constituent elements coupled to the processor 210, and can perform various data processing and operations. The processor 210 can be, for example, implemented as a system on chip (SoC). According to one example embodiment, the processor 210 can further include a graphic processing unit (GPU) and/or an image signal processor (ISP). The processor 210 can include at least some (e.g., cellular module 221) of the constituent elements illustrated in FIGS. 2A and 2B as well. The processor 210 can load a command or data received from at least one of the other constituent elements (e.g., non-volatile memory), into a volatile memory, and process the loaded command or data, and store the result data in the non-volatile memory.

The communication module 220 can have the same or similar construction with the communication interface 170. The communication module 220 may include various communication circuitry, such as, for example, and without limitation, a cellular module 221, a Wi-Fi module 223, a Bluetooth module 225, a GNSS module 227, an NEC module 228, and a radio frequency (RF) module 229. The cellular module 221 can, for example, provide voice telephony, video telephony, a text service, an Internet service, etc., through a telecommunication network. According to an embodiment, the cellular module 221 can perform the distinction and authentication of the electronic device 201 within the telecommunication network, by using the subscriber identification module (e.g., SIM card) 224. According to an embodiment, the cellular module 221 can perform at least some functions among functions that the processor 210 can provide. According to an embodiment, the cellular module 221 can include a CP. According to an embodiment, at least some (e.g., two or more) of the cellular module 221, the Wi-Fi module 223, the Bluetooth module 225, the GNSS module 227 or the NFC module 228 can be included within one integrated chip (IC) or IC package. The RF module 229 can, for example, transceive a communication signal (e.g., RF signal). The RF module 229 can, for example, include a transceiver, a power amplifier module (PAM), a frequency filter, a low noise amplifier (IAA), an antenna, etc. According to another embodiment, at least one of the cellular module 221, the Wi-Fi module 223, the Bluetooth module 225, the GNSS module 227 or the NFC module 228 can transceive an RF signal through a separate RF module. The subscriber identification module 224 can, for example, include a card including a subscriber identification module and/or an embedded SIM. And, the subscriber identification module 224 can include unique identification information (e.g., integrated circuit card identifier (ICCID)) or subscriber information (e.g., international mobile subscriber identity (IMSI)).

The memory 230 (e.g., memory 130) can, for example, include an internal memory 232 and/or an external memory 234. The internal memory 232 can, for example, include at least one of a volatile memory (e.g., a dynamic random access memory (DRAM), a static RAM (SRAM), a synchronous dynamic RAM (SDRAM), etc.), and/or a non-volatile memory (e.g., one time programmable read only memory (OTPROM), a programmable ROM (PROM), an erasable PROM (EPROM), an electrically EPROM (EEPROM), a mask ROM, a flash ROM, a flash memory, a hard drive, or a solid state drive (SSD)). The external memory 234 can include a flash drive, for example, a compact flash (CF), a secure digital (SD), a micro-SD, a mini-SD, an extreme Digital (xD), a multi media Card (MMC), a memory stick, etc. The external memory 234 can be operatively or physically coupled with the electronic device 201 through various interfaces,

The sensor module 240 can, for example, measure a physical quantity or detect an activation state of the electronic device 201. And, the sensor module 240 can convert measured or detected information into an electrical signal. The sensor module 240 can, for example, include at least one of a gesture sensor 240A, a gyro sensor 240B, a barometer (e.g., atmospheric pressure sensor) 240C, a magnetic sensor 240D, an acceleration sensor 240E, a grip sensor 240F, a proximity sensor 240G, a color sensor 240H (e.g., a red, green, blue (RGB) sensor), a biometric sensor 2401, a temperature/humidity sensor 244, an illuminance (e.g., light) sensor 240K, or an ultra violet (UV) sensor 240M. Additionally or alternatively, the sensor module 240 can, for example, include an E-nose sensor, an electromyography (EMG) sensor, an electroencephalogram (EEG) sensor, an electrocardiogram (ECG) sensor, an infrared (IR) sensor, an iris scan sensor, and/or a finger scan sensor. The sensor module 240 can further include a control circuit for controlling at least one or more sensors belonging therein. In an embodiment, the electronic device 201 can further include a processor configured to control the sensor module 240, as a part of the processor 210 or separately from the processor 210. And, the processor can control the sensor module 240 while the processor 210 is in a sleep state.

The input device 250 may include various input circuitry, such as, for example, and without limitation, a touch sensor module 252, a (digital) pen sensor 254, a key 256, or an ultrasonic input device 258. The sensor module 252 can, for example, use at least one scheme among a capacitive overlay scheme, a pressure sensitive scheme, an infrared beam scheme, or an ultrasonic scheme.

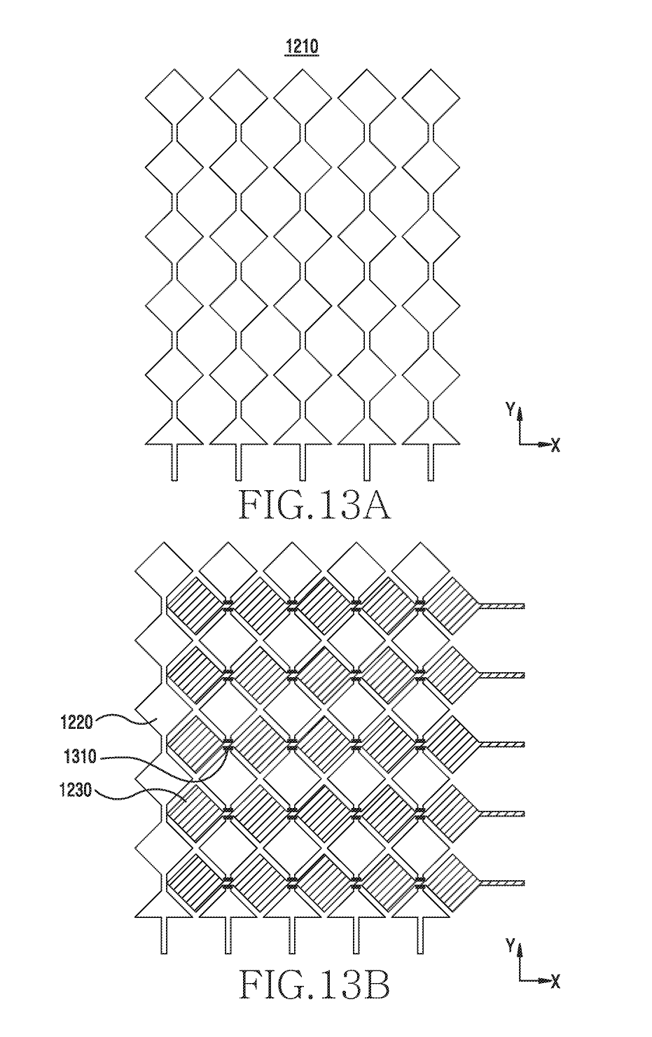

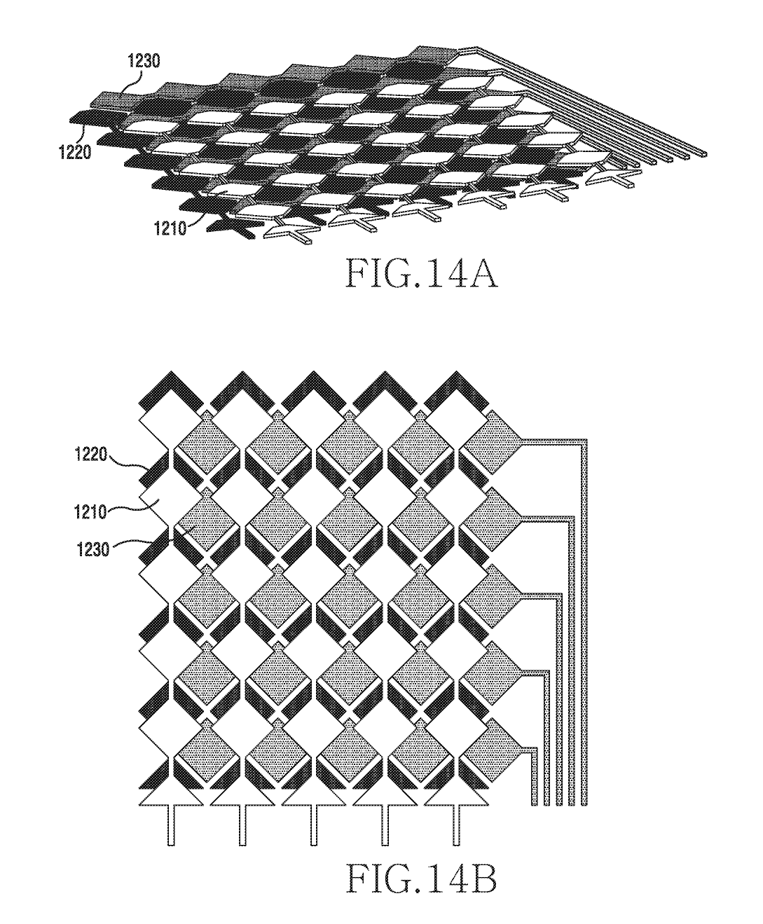

The touch sensor module 252 can include at least one electrode layer. The at least one electrode layer can be directly formed on a 2nd-direction (D2) surface of a transparent plate (e.g., transparent plate 1301 of FIGS. 13A and 13B) or a 1st-direction (D1) surface of a display (e.g., display 1303 of FIGS. 13A and 13B). Or, the at least one electrode layer can be formed on a separate film (not shown) and be attached to the transparent plate 1301 or the display 1303. For example, at least one electrode of the touch sensor module 252 can be arranged within the display 1303. In this case, the at least one electrode can be arranged between an upper plate of the display 1303 and a lower plate thereof, and can be arranged between electrodes configured to drive the display 1303. Or, the at least one electrode of the touch sensor module 252 can be formed integrally with a polarization plate (e.g., polarization plate 1407 of FIGS. 14A and 14B). Also, the touch sensor module 252 can further include a control circuit as well. The touch sensor module 252 can further include a tactile layer, and provide a tactile response to a user. The (digital) pen sensor 254 can, for example, be a part of the touch sensor module 252, or include a separate sheet for recognition. The key 256 can, for example, include a physical button, an optical key, or a keypad. The ultrasonic input device 258 can detect an ultrasonic wave generated in an input tool, through a microphone (e.g., microphone 288), and check data equivalent to the detected ultrasonic wave.

The display 260 (e.g., the display 160) may include a panel 262, a hologram unit 264, a projector 266, and/or a control circuit for controlling the same. The panel 262 may be implemented to be, for example, flexible, transparent, or wearable. The panel 262 together with the touch sensor module 252 may be implemented as one or more modules. The hologram unit 264 may display a three-dimensional image in the air by using the interference of light. The projector 266 may display an image by projecting light onto a screen. The screen may be located, for example, inside or outside the electronic device 201.

The control circuit 265 may be electrically connected to the input device 250 and/or the display 260. The control circuit 265 may drive the input device 250 and/or the display 260. For example, the control circuit 265 may apply a driving signal to the input device 250 and/or the display 260, or may receive a driving signal from the input device 250 and/or the display 260. For example, the control circuit 265 may apply a (hiving signal or receive a driving signal to at least one of the touch sensor module 252, the pressure sensor module 253, and the display 260. Alternatively, the control circuit 265 may apply a driving signal or receive a driving signal to at least two or both of the touch sensor module 252, the pressure sensor module 253, and the display 260. For example, the control circuit 265 can sequentially apply a driving signal to the touch sensor module 252, the pressure sensor module 253, and the display 260.

Specifically, the control circuit 265 may apply a transmit signal to one electrode of the touch sensor module 252 and/or the pressure sensor module 253. Alternatively, the control circuit 265 may receive a received signal from one electrode of the touch sensor module 252 and/or the pressure sensor module 253. Alternatively, the control circuit 265 may connect one electrode of the touch sensor module 252 and/or the pressure sensor module 253 to the ground. Alternatively, the control circuit 265 may control the gate of the sub-pixel RGB or apply the sub-pixel RGB video signal to the display 260.

The interface 270 may include various interface circuitry, such as, for example, and without limitation, an HDMI 272, a USB 274, an optical interface 276, or a d-subminiature (D-sub) 278. The interface 270 can, for example, be included in the communication interface 170 illustrated in FIG. 1. Additionally or alternatively, the interface 270 can, for example, include a mobile high-definition link (MHL) interface, an SD card/MMIC interface, or an infrared data association (IrDA) standard interface.

The audio module 280 can, for example, convert a sound and an electric signal interactively. At least some constituent elements of the audio module 280 can, for example, be included in the input output interface 145 illustrated in FIG. 1. The audio module 280 can, for example, process sound information that is inputted or outputted through a speaker 282, a receiver 284, an earphone 286, the microphone 288, etc. The camera module 291 is, for example, a device able to photograph a still image and a video.

According to an embodiment, the camera module 291 can include one or more image sensors (e.g., front sensor or rear sensor), a lens, an image signal processor (ISP), or a flash (e.g., LED, xenon lamp, etc.). The power management module 295 can, for example, manage the electric power of the electronic device 201.

According to an embodiment, the power management module 295 can include a power management integrated circuit (PMIC), a charger IC, or a battery or fuel gauge. The PMIC can, for example, employ a wired and/or wireless charging scheme. The wireless charging scheme can, for example, include a magnetic resonance scheme, a magnetic induction scheme, an electromagnetic wave scheme, etc. And, the wireless charging scheme can further include a supplementary circuit for wireless charging, for example, a coil loop, a resonance circuit, a rectifier, etc. The battery gauge can, for example, measure a level of the battery 296, a voltage being in charge, an electric current or a temperature. The battery 296 can, for example, include a rechargeable battery and/or a solar battery.

The indicator 297 can display a specific state of the electronic device 201 or a part (e.g., processor 210) of the electronic device 201, for example, a booting state, a message state, a charging state, etc. The motor 298 can convert an electric signal into a mechanical vibration, and can generate a vibration, a haptic effect, etc. The electronic device 201 can, for example, include a mobile TV support device (e.g., GPU) capable of processing media data according to the standards of digital multimedia broadcasting (DMB), digital video broadcasting (DVB), mediaFlo™, etc. The constituent elements described in the present disclosure can each include one or more components, and a name of the corresponding constituent element can vary according to the kind of the electronic device. In various embodiments, the electronic device (e.g., electronic device 201) can omit some constituent elements, or further include additional constituent elements, or combine and construct some of the constituent elements as one entity and identically perform before-combination functions of the corresponding constituent elements.

The constituent elements described in the present disclosure can each include of one or more components, and a name of the corresponding constituent element can vary according to the kind of the electronic device. In various embodiments, the electronic device can include at least one of the constituent elements described in the present disclosure, and can omit some constituent elements or further include additional another constituent element. Also, the electronic device according to various embodiments can combine and construct some of the constituent elements as one entity and identically perform before-combination functions of the corresponding constituent elements.

FIG. 2B is a block diagram of an electronic apparatus according to various embodiments of the present disclosure.

Referring to FIG. 213, an electronic device 202 can include, for example, one or more processors 210, a memory 230, a touch sensor module 252, a touch sensor control circuit 265a, a pressure sensor (or a force sensor, interchangeably used hereinafter) module 253, a pressure sensor control circuit 265b, a display 260, a display control circuit 265c, and a haptic actuator 297. In an embodiment, the electronic device 202 can omit at least one of the components or additionally include other component.

The touch sensor module 252 can correspond to the touch sensor module 252 of FIG. 2A. The touch sensor module 252 can include a first electrode 252a and a second electrode 252b. The touch sensor control circuit 265a can apply a transmit signal to the first electrode 252a or the second electrode 252b, and receive a receive signal corresponding to the transmit signal through the first electrode 252a or the second electrode 252b. The touch sensor control circuit 265a can detect two-dimensional coordinates. The touch sensor control circuit 265a can detect a touch location (X, Y) using the touch sensor module 252. The touch sensor control circuit 265a can send the touch location (X, Y) detected by the touch sensor module 252, to the processor 210.

The pressure sensor module 253 can correspond to the pressure sensor module 253 of FIG. 2A. The pressure sensor module 253 can include the second electrode 252b and a third electrode 253a. The pressure sensor control circuit 265b can detect a pressure level of a user touch through the pressure sensor module 253. The pressure sensor control circuit 265b can detect a pressure value Z at the touch location (X, Y). The pressure sensor control circuit 265b can detect a pressure of an external object using the second electrode 252b and the third electrode 253a which are insulated by a dielectric layer. As the second electrode 252b and the third electrode 253a get close to each other due to the pressure of the external object, the pressure sensor control circuit 265b can detect the pressure level based on a capacitance change between the second electrode 252b and the third electrode 253a. For example, according to mutual capacitance, the pressure sensor control circuit 265b can apply a transmit signal to the second electrode 252b or the third electrode 253a, and receive a receive signal corresponding to the transmit signal through the second electrode 252b or the third electrode 253a. Alternatively, according to self capacitance, the pressure sensor control circuit 265b can apply a stimulus signal to one of the second electrode 252b and the third electrode 253a and connect the other of the second electrode 252b and the third electrode 253a to the ground. The pressure sensor control circuit 265b can send the pressure level detected by the pressure sensor module 253, to the processor 210.

The display 260 can correspond to the display 260 of FIG. 2A. The display control circuit 265c can receive image information from the processor 230. Based on the received image information, the display control circuit 265c can send a driving signal for driving the display 260, to the display 260.

At least two of the touch sensor control circuit 265a, the pressure sensor control circuit 265b, and the display control circuit 265c can be combined in the control circuit 265.

The haptic actuator 297 can convert an electric signal to mechanical vibrations and produce vibrations or a haptic effect. When the user applies an input to the electronic device 202, the haptic actuator 297 can provide the sensory response of the input to the user. The haptic actuator 297 can receive haptic information from the processor 210. The haptic actuator 297 can generate the vibrations or the haptic effect according to the received haptic information.

The processor 210 can correspond to the processor 210 of FIG. 2A. The processor 210 can receive a location signal (e.g., coordinates (X, Y)) detected by the touch sensor module 252, from the touch sensor control circuit 265a. The processor 210 can receive a pressure signal (e.g., the pressure coordinates Z or the pressure level Z) detected by the pressure sensor module 253, from the pressure sensor control circuit 265b, The processor 210 can synchronize the location signal of the touch sensor module 252 and the pressure signal of the pressure sensor module 253. While the processor 210 needs to process the touch signal and the pressure signal together, it cannot synchronize the two signals because the touch sensor module 252 and the pressure sensor module 253 separately detect the different signal. For example, the touch signal is detected when the display 260 is touched without the pressure signal. Accordingly, when the pressure signal takes place, the processor 210 can synchronize the touch signal with the pressure signal and thus process them as the single input. Mostly, since the pressure signal is detected when the display 260 is touched and then pressed harder, the pressure signal alone does not occur without the touch signal. However, in a specific situation (e.g., when the user touches with gloves on or when the display 260 is exposed to moister), the processor 210 can determine both of the location and the level of the pressure merely using the pressure signal without the touch signal.

The processor 210 can send the image information to the display control circuit 265c, and the display control circuit 265c can send the driving signal for driving the display 260 to the display 260 according to the image information. The processor 210 can send the haptic information to the haptic actuator 297. For example, based on the received touch signal and/or pressure signal, the processor 210 can send the image information and/or the haptic information. For example, when the received pressure signal indicates a first level, the processor 210 can send first image information (e.g., a menu regarding a touched object) to the display 260 and send first haptic information (e.g., weak vibrations) to the haptic actuator 297. For example, when the received pressure signal indicates a second level which is greater than the first level, the processor 210 can send second image information (e.g., a whole screen regarding a touched object) to the display 260 and send second haptic information (e.g., strong vibrations) to the haptic actuator 297.

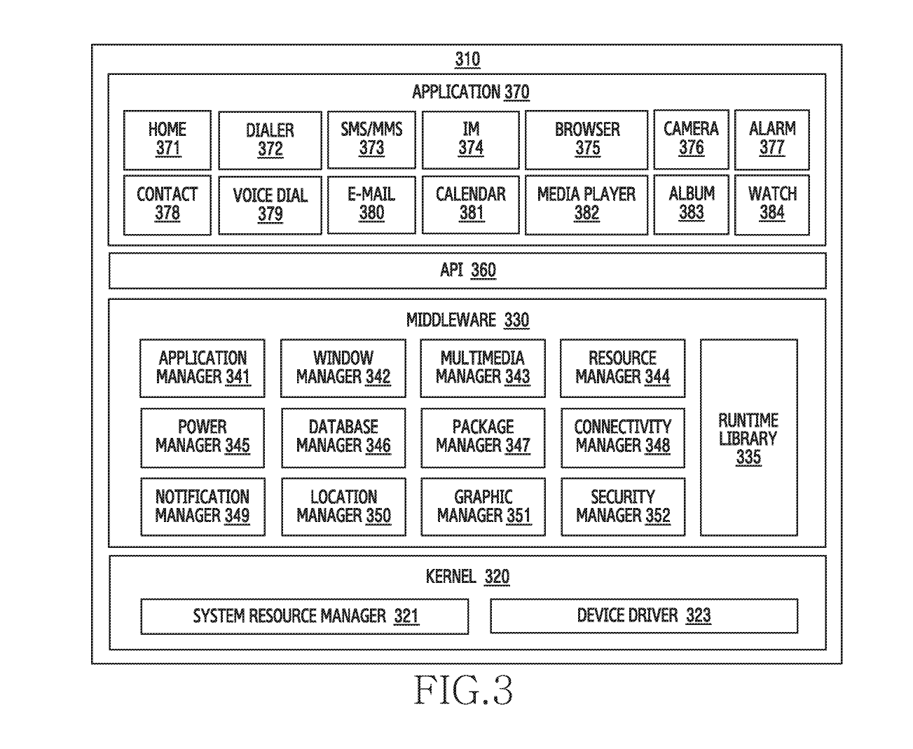

FIG. 3 is a block diagram illustrating an example program module according to various embodiments of the present disclosure. According to an example embodiment, the program module 310 (e.g., program 140) can include an OS controlling resources related to an electronic device (e.g., electronic device 101) and/or various applications (e.g., application program 147) run on the operating system. The operating system can, for example, be Android, iPhone OS (iOS), Windows, Symbian, Tizen, Bada, etc.

The program module 310 can include a kernel 320, a middleware 330, an API 360, and/or an application 370. At least some of the program module 310 can be preloaded onto the electronic device, or can be downloaded from an external electronic device (e.g., electronic device 102, 104, server 106, etc.).

The kernel 320 (e.g., kernel 141) can include a system resource manager 321 and/or a device driver 323. The system resource manager 321 can perform the control, allocation, recovery, etc. of system resources. According to an embodiment, the system resource manager 321 can include a process management unit, a memory management unit, a file system management unit, etc. The device driver 323 can, for example, include a display driver, a camera driver, a Bluetooth driver, a shared memory driver, a USB driver, a keypad driver, a Wi-Fi driver, an audio driver, or an inter-process communication (IPC) driver.

In an embodiment, the display driver can control one or more display driving circuits (e.g., DD1). The display driving circuit can include functions for controlling a screen in response to a request of the application 370.

The middleware 330 can, for example, provide functions that the application 370 commonly needs, or provide various functions to the application 370 through the API 360. So, the application 370 can make efficient use of restricted system resources within the electronic device. According to an embodiment, the middleware 330 (e.g., middleware 143) can include at least one of a runtime library 335, an application manager 341, a window manager 342, a multimedia manager 343, a resource manager 344, a power manager 345, a database manager 346, a package manager 347, a connectivity manager 348, a notification manager 349, a location manager 350, a graphic manager 351, or a security manager 352.

The runtime library 335 can, for example, include a library module that a compiler uses to add a new function through a programming language while the application 370 is executed. The runtime library 335 can perform functions of input output management, memory management, arithmetic function, etc.

The application manager 341 can, for example, manage a life cycle of at least one application among the applications 370. The window manager 342 can manage graphical user interface (GUI) resources that are used in a screen. For example, in case where at least two or more displays 260 are coupled, the window manager 342 can configure or manage the screen differently in accordance with an aspect ratio or an operation of the application 370. The multimedia manager 343 can figure out a format necessary for playing various media files, and perform the encoding or decoding of the media file by a codec adapted to the corresponding format. The resource manager 344 can manage resources such as a source code of at least any one application among the applications 370, a memory, a storage space, etc.

The power manager 345 can, for example, work together with a basic input/output system (BIOS), etc. and manage a battery or power source, and provide electric power information, etc. necessary for an operation of the electronic device. The database manager 346 can generate, search or change a database that will be used in at least one application among the applications 370. The package manager 347 can manage the installation or updating of an application that is distributed in the form of a package file.

The connectivity manager 348 can, for example, manage wireless connectivity such as Bluetooth, etc. The notification manager 349 can display or notify an event such as an arrived message, an appointment, a proximity notification, etc., the way a user is not disturbed. The location manager 350 can manage location information of the electronic device. The graphic manager 351 can manage a graphic effect that will be provided to a user, or a user interface related with this. The security manager 352 can provide a general security function that is necessary for system security, user authentication, etc. According to an embodiment, in case where the electronic device (e.g., electronic device 101) includes a phone function, the middleware 330 can further include a telephony manager for managing a voice or video telephony function of the electronic device.

The middleware 330 can include a middleware module forming a combination of various functions of the aforementioned constituent elements. The middleware 330 can provide a module that is specialized on a per-operating-system-type basis in order to provide a distinctive function. Also, the middleware 330 can dynamically delete some of the existing constituent elements or add new constituent elements.

The API 360 (e.g., API 145), for example, a set of API programming functions, can be provided to have another construction in accordance with an operating system. For example, Android or iOS can provide one API set on a per-platform basis, and Tizen can provide two or more API sets on a per-platform basis.

The application 370 (e.g., application program 147) can, for example, include at least one or more applications capable of performing functions of a home 371, a dialer 372, a short message service (SMS) multimedia message service (MMS) 373, an instant message (IM) 374, a browser 375, a camera 376, an alarm 377, a contact 378, a voice dial 379, an electronic mail (e-mail) 380, a calendar 381, a media player 382, an album 383, a watch 384, health care (e.g., measuring a quantity of motion, a blood sugar, etc.), environment information provision (e.g., providing air pressure, humidity, temperature information, etc.), etc.

According to an embodiment, the application 370 can include an application (hereinafter, referred to as “information exchange application” for description convenience) supporting information exchange between the electronic device (e.g., electronic device 101) and an external electronic device (e.g., electronic device 102, 104). The information exchange application can, for example, include a notification relay application for relaying specific information to the external electronic device, or a device management application for managing the external electronic device.

For example, the notification relay application can include a function of relaying notification information generated in another application (e.g., SMS/MMS application, e-mail application, health care application, environment information application, etc.) of the electronic device, to the external electronic device (e.g., electronic device 102 or 104). Also, the notification relay application can, for example, receive notification information from the external electronic device and provide the received notification information to a user.

The device management application can, for example, manage (e.g., install, delete or update) at least one function of the external electronic device (e.g., electronic device 102 or 104) communicating with the electronic device (e.g., function of turning On/turning Off the external electronic device itself or some constituent components, or adjusting a display brightness or resolution), an application operating in the external electronic device, or a service (e.g., telephony service, message service, etc.) provided in the external electronic device.

According to an embodiment, the application 370 can include an application (e.g., health care application, etc. of a mobile medical instrument) that is designated according to an attribute of the external electronic device (e.g., electronic device 102 or 104). According to an embodiment, the application 370 can include an application that is received from the external electronic device (e.g., server 106 or electronic device 102 or 104). According to an embodiment, the application 370 can include a preloaded application, or a third party application downloadable from a server. Names of the illustrated constituent elements of the program module 310 according to the example embodiment can be varied according to the type of the operating system.

According to various embodiments, at least a part of the program module 310 can be implemented by software, firmware, hardware, or combination of at least two or more of them. At least a part of the program module 310 can, for example, be implemented (i.e., executed) by a processor (e.g., processor 210). The at least part of the program module 310 can include, for example, a module, a program, a routine, sets of instructions, a process, etc. for performing one or more functions.

The term “module” used in the present disclosure may, for example, refer to a unit including one of hardware, software, or firmware, or a combination of two or more of them. The “module” can, for example, be used interchangeably with the terms “unit”, “logic”, “logical block”, “component”, “circuit”, etc. The “module” can be the minimum unit of an integrally constructed component or a part thereof. The “module” can be the minimum unit performing one or more functions or a part thereof as well. The “module” can be implemented mechanically or electronically. For example, the “module” can include at least one of a dedicated processor, a CPU, an application-specific integrated circuit (ASIC) chip performing some operations, a field-programmable gate array (FPGA), or a programmable-logic device, which is well known to the art or will be developed in the future.

At least a part of a device (e.g., modules or functions thereof) or method (e.g., operations) according to various example embodiments can, for example, be implemented by an instruction that is stored in a computer-readable storage media in the form of the program module. In case where the instruction is executed by a processor (e.g., processor 120), the processor can perform a function equivalent to the instruction. The computer-readable storage media can be the memory 130, for example.

The computer-readable recording media can include a hard disk, a floppy disk, a magnetic media (e.g., magnetic tape), an optical media (e.g., compact disc-ROM (CD-ROM), digital versatile disc (DVD), magneto-optical media (e.g., floptical disk)), a hardware device (e.g., ROM, RAM, flash memory, etc.), etc. Also, a program command can include not merely a mechanical language code such as a code made by a compiler, but also a high-level language code that is executable by a computer by using an interpreter, etc. The aforementioned hardware device can be configured to work as one or more software modules in order to perform operations of various embodiments, and vice versa.

The module or program module according to various embodiments can include at least one or more of the aforementioned constituent elements, or omit some of them, or further include additional another constituent element. Operations carried out by the module, program module or another constituent element according to various example embodiments can be executed in a sequential, parallel, repeated or heuristic method. Also, some operations can be executed in another order or can be omitted, or another operation can be added. And, the various embodiment disclosed in the present disclosure is suggested for the explaining and understanding of the technology content disclosed, and does not limit the scope of the technology mentioned in the present disclosure. Accordingly, the scope of the present disclosure should be construed as including all modifications or various other embodiments based on the technological spirit of the present disclosure.

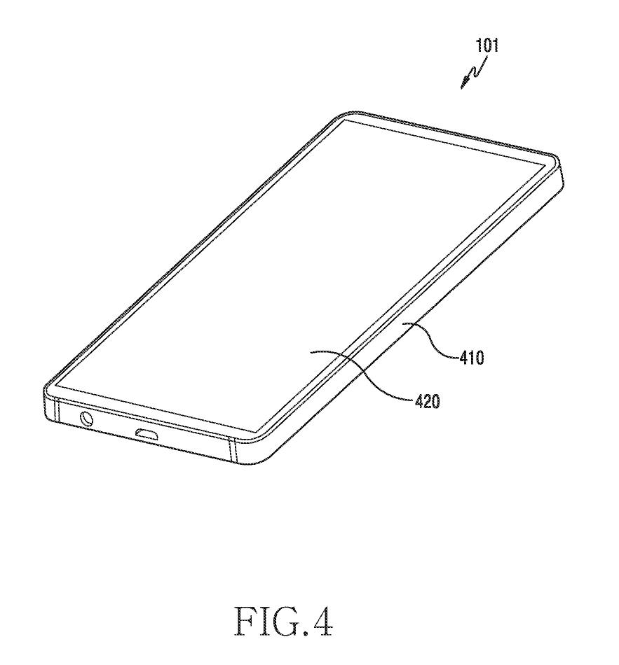

FIG. 4 is a perspective view of an electronic apparatus according to various embodiments of the present disclosure.

Referring to FIG. 4, an electronic device 101 can include a housing 410 including a transparent cover 420. The housing 410 and the transparent cover 420 can form an exterior of the electronic device 101. The housing 410 and the transparent cover 420 can accommodate and protect various components of the electronic device 101. While the electronic device 101 is, but not limited to, a smartphone in FIG. 4, the electronic device 101 can be a combination of one or more of various devices as mentioned above.

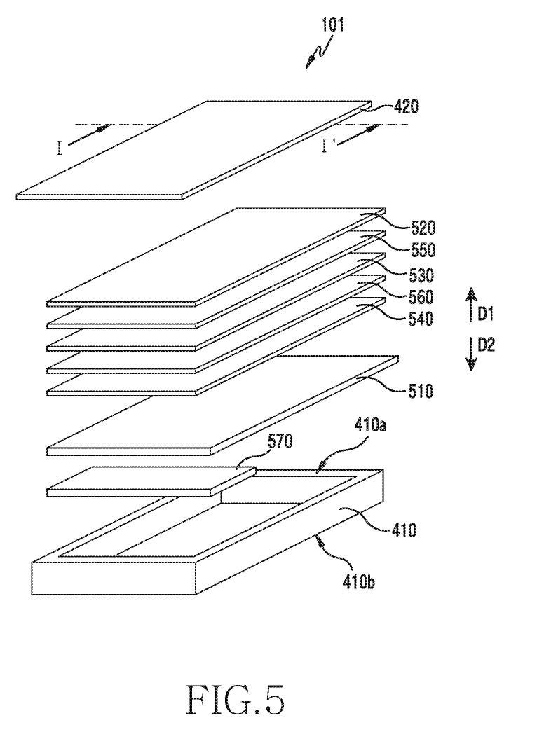

FIG. 5 is an exploded view of an electronic apparatus according to various embodiments of the present disclosure.

Referring to FIG. 5, an electronic device 101 can include a housing 410, a transparent cover 420, a display 510, a first electrode 520, a second electrode 530, a third electrode 540, a first dielectric layer 550, a second dielectric layer 560, and a haptic actuator 570.

According to various embodiments, the housing 410 can include a first surface 410a facing a first direction D1, and a second surface 410b facing a second direction D2 which is opposite to the first direction D1. The housing 410 can accommodate the display 510, the first electrode 520, the second electrode 530, the third electrode 540, the first dielectric layer 550, the second dielectric layer 560, and the haptic actuator 570. The housing 410 can be formed with a metallic or plastic material.

According to various embodiments, the transparent cover 420 can form at least part of the first surface 410a of the housing 410. The transparent cover 420 can form an exterior of the electronic device 101. The transparent cover 420 can be disposed at the top of the electronic device 101. The transparent cover 420 can protect the various components disposed below. The transparent cover 420 can transmit an internal light out of the electronic device 101. For example, the transparent cover 420, which is transparent, can expose the display 510. The transparent cover 420 can transmit an external light from the outside into the electronic device 101.

According to various embodiments, the transparent cover 420 can be formed with a material having good light transmittance, thermal resistance, chemical resistance, and mechanical strength. The transparent cover 420 can include, for example, a transparent film formed with a polymer, or a glass plate. For example, the transparent cover 420 can include a combination of one or two selected from acrylonitrile butadiene styrene (ABS), acryl, polycarbonate (PC), polymethyl methacrylate (PMMA), polyimide (PE), polyethylene terephthalate (PET), polypropylene terephthalate (PPT), amorphous polyethylene terephthalate (APET), polyethylene naphtholate terephthalate (PEN), polyethylene terephthalate glycol (PETG), tri-acetyl-cellulose (TAC), cyclic olefin polymer (COP), cyclic olefin copolymer (COC), poly dicyclopentadiene (DCPD), cyclopentadienyl anions (CPD), polyarylate (PAR), polyethersuifone (PES), poly ether imide (PEI), modified epoxy resin, and acrylic resin. Alternatively, the transparent cover 420 can include various hard films. When the transparent cover 420 is a hard film, its surface can be hard-coated.

According to various embodiments, the display 510 can correspond to the display 160 of FIG. 1 or the display 260 of FIG. 2. The display 510, which is included in the electronic device 101, can perform actual operations in the electronic device 101. The display 510 can display an image. For example, the display 510 can include an OLED display.

According to various embodiments, the first electrode 520, the second electrode 530, the third electrode 540, the first dielectric layer 550, and the second dielectric layer 560 can be interposed between the transparent cover 420 and the display 510. The first electrode 520, the second electrode 530, the third electrode 540, the first dielectric layer 550, and the second dielectric layer 560 can construct the touch sensor module 252 and/or the pressure sensor module 253 of FIG. 2. The touch sensor module 252 and the pressure sensor module 253 can share the second electrode 530. For example, the first electrode 520, the first dielectric layer 550, and the second electrode 530 can construct the touch sensor module 252 and detect a location of a touch input of an external object on the first surface 410a. For doing so, the control circuit 265 of FIGS. 2A and 2B can apply a transmit signal to the first electrode 520 or the second electrode 530, and receive a receive signal corresponding to the transmit signal through the first electrode 520 or the second electrode 530. For example, the control circuit 265 can apply a transmit signal to the second electrode 530, and receive a receive signal corresponding to the transmit signal through the first electrode 520. The control circuit 265 can detect a location of the touch input by detecting a change of mutual capacitance between the first electrode 520 and the second electrode 530 based on the touch of the external object.

According to various embodiments, the second electrode 530, the second dielectric layer 560, and the third electrode 540 can construct the pressure sensor module 253 and detect pressure of the external object on the first surface 410a. For doing so, the control circuit 265 can apply a transmit signal to the second electrode 530 or the third electrode 540, and receive a receive signal corresponding to the transmit signal through the second electrode 530 or the third electrode 540. For example, the control circuit 265 can apply a transmit signal to the second electrode 530, and receive a receive signal corresponding to the transmit signal through the third electrode 540. The control circuit 265 can detect a capacitance change based on a thickness change of the second dielectric layer 560, that is, based on a distance change between the second electrode 530 and the third electrode 540 according to the pressure of the external object.

According to various embodiments, the first electrode 520, the second electrode 530, and the third electrode 540 can include various conductive materials. For example, the first electrode 520, the second electrode 530, and the third electrode 540 can include various materials such as indium tin oxide (ITO), indium zinc oxide (IZO), copper oxide, Poly(3,4-ethylenedioxythiophene) (PEDOT), metal mesh, carbon nano tube (CNT), Ag nanowire, transparent conducting polymer, and graphene. The first electrode 520, the second electrode 530, and the third electrode 540 can include the same material. Alternatively, at least one of the first electrode 520, the second electrode 530, and the third electrode 540 may include a different material from the others.

Although the first electrode 520, the second electrode 530, and the third electrode 540 are deposited in order along, not limited to, the second direction D2, the first electrode 520, the second electrode 530, and the third electrode 540 can be deposited in various orders.

According to various embodiments, the first dielectric layer 550 can be interposed between the first electrode 520 and the second electrode 530. The second dielectric layer 560 can be interposed between the second electrode 530 and the third electrode 540. The first dielectric layer 550 or the second dielectric layer 560, which has elasticity or resilience, can have different lengths according to the pressure of the external object. The first dielectric layer 550 or the second dielectric layer 560 can be different in thickness. For example, the second dielectric layer 560 can be thicker than the first dielectric layer 550.

According to various embodiments, the first dielectric layer 550 and the second dielectric layer 560 can include an insulating material. For example, the first dielectric layer 550 and the second dielectric layer 560 can include a combination of one or more selected from silicon, air, membrane, double-sided adhesive film, pressure sensitive adhesive (PSA), optically clear adhesive (OCA), optical clear resin (OCR), sponge, rubber, ink, acrylonitrile butadiene styrene (ABS), acryl, polycarbonate (PC), polymethyl methacrylate (PMMA), polyimide (PE), polyethylene terephthalate (PET), polypropylene terephthalate (PPT), amorphous polyethylene terephthalate (APET), polyethylene naphthalate terephthalate (PEN), polyethylene terephthalate glycol (PETG), tri-acetyl-cellulose (MC), cyclic olefin polymer (COP), cyclic olefin copolymer (COC), poly dicyclopentadiene (DCPD), cyclopentadienyl anions (CPD), polyarylate (PAR), polyethersulfone (PES), poly ether imide (PEI), modified epoxy resin, and acrylic resin. The second dielectric layer 560 can include at least part of a different material from the first dielectric layer 550.

According to various embodiments, the haptic actuator 570 can be disposed in the second direction D2 from the display 510. The haptic actuator 570 can produce a vibration or haptic effect based on the pressure of the external object. The haptic actuator 570 can produce the vibration or the haptic effect at various levels based on a pressure level. For example, as the pressure of the external object increases, the haptic actuator 570 can produce a greater vibration or haptic effect.

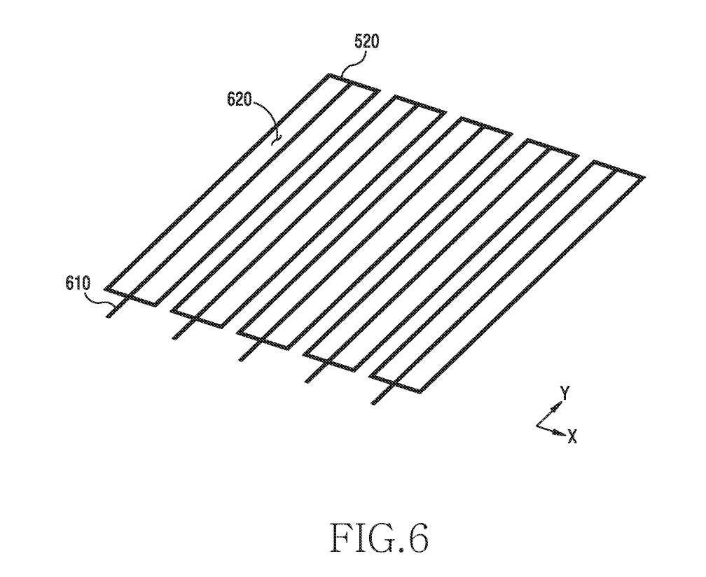

The first electrode 520, the second electrode 530, and the third electrode 540 can have different patterns, to be explained by referring to FIG. 6 through FIG. 9.

FIG. 6 is a perspective view of a first electrode in an electronic apparatus according to various embodiments of the present disclosure.

Referring to FIG. 6, the first electrode 520 can include electrode patterns iteratively arranged along an X-axis. For example, the first electrode 520 can include an electrode pattern which is longitudinally formed along a Y axis. The electrode pattern of the first electrode 520 can include a first opening 620. The electrode pattern of the first electrode 520 can include at least one first opening 620 longitudinally formed along the Y axis. A wiring 610 for electric connections can be formed on a side surface of the first electrode 520. The wiring 610 can be formed with a conductive material having good conductivity. The wiring 610 can be coupled to a printed circuit board (not shown). The first electrode 520 can receive a driving signal through the wiring 610.

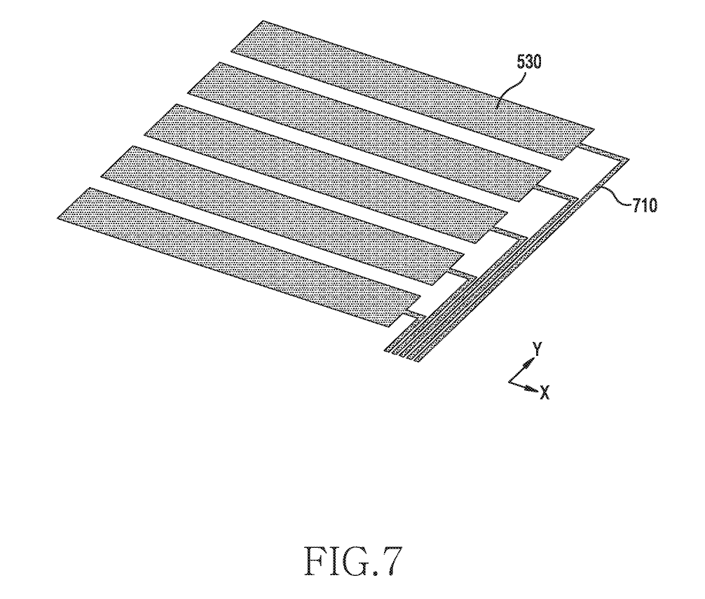

FIG. 7 is a perspective view of a second electrode in an electronic apparatus according to various embodiments of the present disclosure.

Referring to FIG. 7, the second electrode 530 can include electrode patterns iteratively arranged along the Y-axis. For example, the second electrode 530 can include an electrode pattern which is longitudinally formed along the X axis. The electrode pattern of the second electrode 530 can in a bar shape. A wiring 710 for electric connections can be formed on a side surface of the second electrode 530. The wiring 710 can be formed with a conductive material having good conductivity. The wiring 710 can be coupled to a printed circuit board. The second electrode 530 can receive a driving signal through the wiring 710.

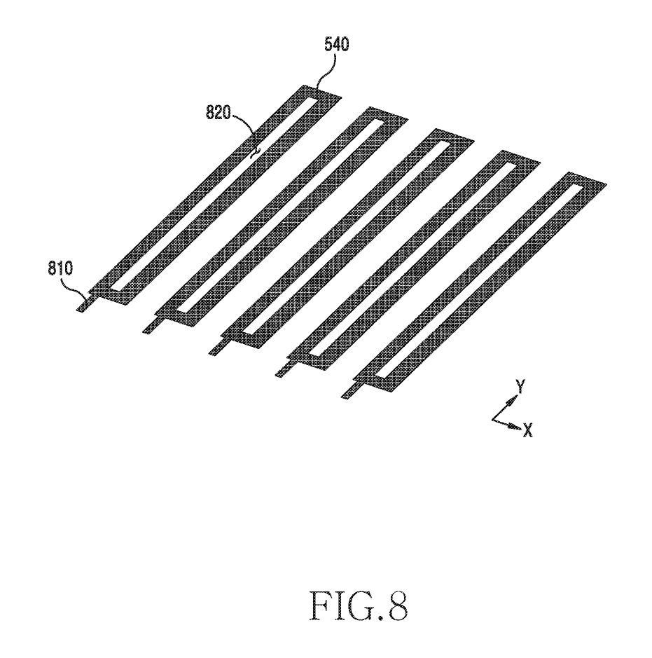

FIG. 8 is a perspective view of a second electrode in an electronic apparatus according to various embodiments of the present disclosure.

Referring to FIG. 8, the third electrode 540 can include electrode patterns iteratively arranged along the X-axis. For example, the third electrode 540 can include an electrode pattern which is longitudinally formed along the Y axis. The electrode pattern of the third electrode 540 can include a second opening 820. The electrode pattern of the third electrode 540 can include at least one second opening 820 longitudinally formed along the Y axis. A wiring 810 for electric connections can be formed on a side surface of the third electrode 540. The wiring 810 can be formed with a conductive material having good conductivity. The wiring 810 can be coupled to a printed circuit board. The third electrode 540 can receive a driving signal through the wiring 810.

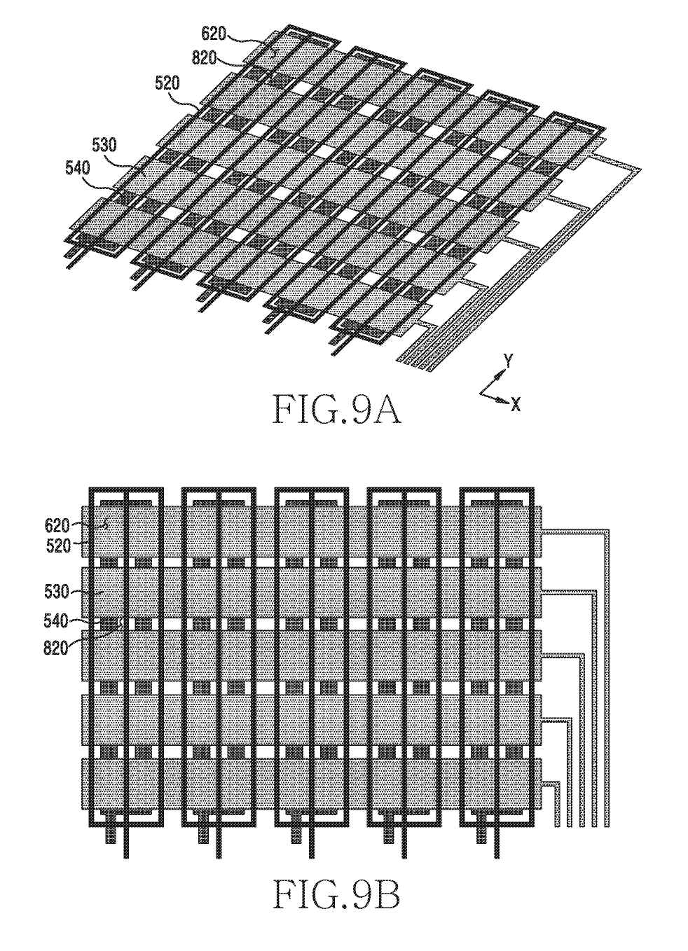

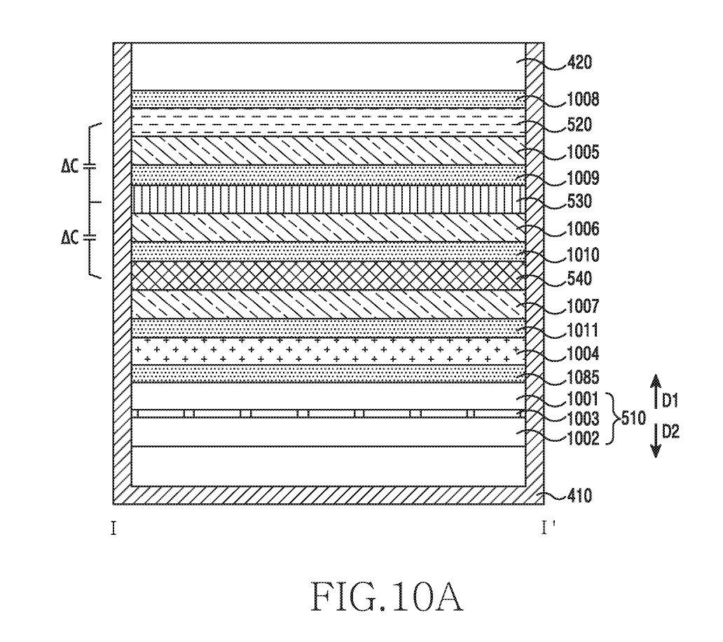

FIG. 9A is a perspective view of a first electrode, a second electrode, and a third electrode in an electronic apparatus according to various embodiments of the present disclosure.

FIG. 9B is a plane view of a first electrode, a second electrode, and a third electrode in an electronic apparatus according to various embodiments of the present disclosure.

Referring to FIGS. 9A and 9B, the first electrode 520 and the third electrode 540 can at least overlap with each other when viewed from above. For example, when viewed from above, the first opening 620 of the first electrode 520 can overlap the third electrode 540. Also, the second opening 820 of the third electrode 540 can overlap the first electrode 520, when viewed from above. Hence, interference between the first electrode 520 and the third electrode 540 can be prevented. That is, as the interference between the first electrode 520 for detecting the touch of the external object and the third electrode 540 for detecting the pressure of the external object is prevented, the touch or pressure detection can improve accuracy.

FIGS. 10A, 10B, 10C, 10D, 10E, 10F, 10G, 10H, and 10I are cross-sectional views taken along I-I′ of FIG. 5 according to various embodiments of the present disclosure.

Referring to FIG. 10A., the first electrode 520, the second electrode 530, and the third electrode 540 can be disposed between the transparent cover 420 and the display 510. The display 510 can include a first substrate 1001, a second substrate 1002, and a display device 1003 (e.g., liquid crystals, an organic light-emitting material, quantum dots, etc.). According to an embodiment, the first substrate 1001 can include an encapsulation layer. For example, the encapsulation layer can block external water or oxygen from flowing into a display material. According to an embodiment, the first substrate 1001 can include a color filter substrate (or a color filter glass). The first substrate 1001 can include a black matrix, a color filter, and so on. For example, a white light from the display device 1003 can pass through the color filter of the first substrate 1001 and change into a certain color. When the light of the certain color is fed from the display device 1003, the first substrate 1001 may not include the color filter. According to various embodiments, the first substrate 1001 can include a plurality of RGB pixels. For example, the RGB pixels can be in the same ratio and/or number or in different ratios (e.g., R:G:B=1:1:0.9) or numbers (e.g., B is two times R or G).

According to various embodiments, the second substrate 1002 can include, for example, a thin film transistor (TFT) substrate (or glass). The second substrate 1002 can include a TFT, a pixel electrode, and a common electrode coupled to the transistor. The display device 1003 can be interposed between the first substrate 1001 and the second substrate 1002. When the display device 1003 is an organic light-emitting material or quantum dots, the second substrate 1002 can change the amount of light by regulating currents applied to the organic light-emitting material. When the display device 1003 is liquid crystals, the second substrate 1002 can change arrangement of the liquid crystals in order to change transmittance of the light fed from a backlight unit (not shown).

According to various embodiments, a polarizing layer 1004 can be interposed between the third electrode 540 and the display 510. The polarizing layer 1004 can vibrate in several directions and produce (i.e., polarize) the incident light oscillating in only one direction. The external light passing through the polarizing layer 1004 can block at least part of a light reflected by a metal layer of the display 510. The external light passing through the polarizing layer 1004 can dissipate at least in part while iteratively reflecting between the polarizing layer 1004 and the metal layer of the display 510. The polarizing layer 1004 can be bonded to the display 510 using a first bonding layer 1085.

According to various embodiments, the first electrode 520 can be formed on a first base material 1005. The second electrode 530 can be formed on a second base material 1006. The third electrode 540 can be formed on a third base material 1007. That is, the first electrode 520, the second electrode 530, and the third electrode 540 can be formed on the different materials. While the first electrode 520, the second electrode 530, and the third electrode 540 each face, but not limited to, the first direction Di on the first base material 1005, the second base material 1006, and the third base material 1007 respectively, they may face the second direction D2 which is opposite to the first direction D1.

According to various embodiments, the transparent cover 420, the first base material 1005 including the first electrode 520, the second base material 1006 including the second electrode 530, the third base material 1007 including the third electrode 540, and the polarizing layer 1004 can be bonded together using bonding layers 1008 through 1011. For example, the transparent cover 420 and the first base material 1005 including the first electrode 520 can be bonded together using the second bonding layer 1008. Alternatively, the first base material 1005 including the first electrode 520 can be bonded to the second base material 1006 including the second electrode 530 using the third bonding layer 1009. Alternatively, the second base material 1006 including the second electrode 530 can be bonded to the third base material 1007 including the third electrode 540 using the fourth bonding layer 1010. Alternatively, the third base material 1007 including the third electrode 540 and the polarizing layer 1004 can be bonded together using the fifth bonding layer 1011. A total transmittance of the transparent cover 420, the first base material 1005 including the first electrode 520, the second base material 1006 including the second electrode 530, and the third base material 1007 including the third electrode 540 which are bonded together can exceed 90%.

According to various embodiments, the first electrode 520, the second electrode 530, and the third electrode 540 which are insulated can be used to detect the touch location and the pressure of the external object. For example, a control circuit (e.g., the control circuit 265 of FIG. 2) can detect a location of the touch based on the capacitance change between the first electrode 520 and the second electrode 530 according to the touch of the external object. For example, as the second electrode 530 and the third electrode 540 get close to each other according to the pressure of the external object, the control circuit 265 can detect the pressure level based on the change of the capacitance between the second electrode 530 and the third electrode 540. The control circuit 265 can detect the capacitance change between the first electrode 520 and the second electrode 530 and/or the capacitance change between the second electrode 530 and the third electrode 540, according to mutual capacitance and/or self-capacitance. Using the mutual capacitance, the control circuit 265 can apply a transmit signal to the second electrode 530 and receive a receive signal corresponding to the transmit signal through the first electrode 520. Using the self-capacitance, the control circuit 265 can apply a stimulus signal to one of the first electrode 520 or the second electrode 530, and connect the other of the first electrode 520 or the second electrode 530 to the ground.

According to various embodiments, at least one of the first base material 1005 and the third bonding layer 1009 can be the first dielectric layer 550 of FIG. 5. That is, the first base material 1005 and/or the third bonding layer 1009 can insulate between the first electrode 520 and the second electrode 530. Alternatively, the first base material 1005 serving as the first dielectric layer 550 can support the first electrode 520. Alternatively, the third bonding layer 1009 serving as the first dielectric layer 550 can bond the first base material 1005 including the first electrode 520 with the second base material 1006 including the second electrode 530.

According to various embodiments, at least one of the second base material 1006 and the fourth bonding layer 1010 can be the second dielectric layer 560 of FIG. 6. That is, the second base material 1006 and/or the fourth bonding layer 1010 can insulate between the second electrode 530 and the third electrode 540. Alternatively, the second base material 1006 serving as the second dielectric layer 560 can support the second electrode 530. Alternatively, the fourth bonding layer 1010 serving as the second dielectric layer 560 can bond the second base material 1006 including the second electrode 530 with the third base material 1007 including the third electrode 540.

According to various embodiments, when the first electrode 520 and the second electrode 530 are used to detect a location of the touch and the second electrode 530 and the third electrode 540 are used to detect the pressure of the touch, the second base material 1006 can include at least part of a different material from the first base material 1005. The second base material 1006 can be, for example, thicker than the first base material 1005. The second base material 1006 can have, for example, greater elasticity or resilience than the first base material 1005. The fourth bonding layer 1010 can include at least part of a different material from the third base material 1007. The fourth bonding layer 1010 can be, for example, thicker than the third base material 1007. The fourth bonding layer 1010 can have, for example, greater elasticity or resilience than the third base material 1007.

Referring to FIG. 1013, the first electrode 520 can be formed directly on the transparent cover 420. That is, the first electrode 520 can be integrated with the transparent cover 420. The first electrode 520 can face the second direction D2 on the transparent cover 420. The second electrode 530 can be formed on a second base material 1012. The third electrode 540 can be formed on a third base material 1014. That is, the first electrode 520, the second electrode 530, and the third electrode 540 can be formed on the different materials. While the second electrode 530 and the third electrode 540 face, but not limited to, the first direction D1 on the second base material 1012 and the third base material 1014 respectively, they may face the second direction D2 which is opposite to the first direction D1.

According to various embodiments, the transparent cover 420 including the first electrode 520, the second base material 1012 including the second electrode 530, the third base material 1014 including the third electrode 540, and the polarizing layer 1004 can be bonded together using bonding layers 1016, 1017 and 1018. For example, the transparent cover 420 including the first base material 1005 can be bonded to the second base material 1012 including the second electrode 530 using the third bonding layer 1016. Alternatively, the second base material 1012 including the second electrode 530 can be bonded to the third base material 1014 including the third electrode 540 using the fourth bonding layer 1017. Alternatively, the third base material 1014 including the third electrode 540 and the polarizing layer 1004 can be bonded together using the fifth bonding layer 1018. As the first electrode 520 is formed directly on the transparent cover 420, the first base material 1005 and the second bonding layer 1008 of FIG. 10A can be omitted and the electronic device 101 reduces its thickness far more.

According to various embodiments, the third bonding layer 1016 can be the first dielectric layer 550 FIG. 5. That is, the third bonding layer 1016 can insulate between the first electrode 520 and the second electrode 530 in order to detect a location of the touch of the external object. Alternatively, the third bonding layer 1016 serving as the first dielectric layer 550 can bond the transparent cover 420 including the first electrode 520 with the second base material 1012 including the second electrode 530.

At least one of the second base material 1012 and the fourth bonding layer 1017 can be the second dielectric layer 560 of FIG. 5. That is, the second base material 1012 and/or the fourth bonding layer 1017 can insulate between the second electrode 530 and the third electrode 540 in order to detect the pressure of the external object. Alternatively, the second base material 1012 serving as the second dielectric layer 560 can support the second electrode 530. Alternatively, the fourth bonding layer 1017 serving as the second dielectric layer 560 can bond the second base material 1012 including the second electrode 530 with the third base material 1014 including the third electrode 540.

According to various embodiments, when the first electrode 520 and the second electrode 530 are used to detect a location of the touch and the second electrode 530 and the third electrode 540 are used to detect the pressure, the fourth bonding layer 1017 can include at least part of a different material from the third bonding layer 1016. The fourth bonding layer 1017 can be, for example, thicker than the third bonding layer 1016. The fourth bonding layer 1017 can have, for example, greater elasticity or resilience than the third bonding layer 1016.

Referring to FIG. 10C, the first electrode 520 and the second electrode 530 can be formed directly on the first base material 1020. The first electrode 520 and the second electrode 530 can be formed on either surface of the first base material 1020. That is, the first electrode 520 can be formed on a first surface 1020a of the first base material 1020, and the second electrode 530 can be formed on a second surface 1020b which is opposite to the first surface 1020a. The third electrode 540 can be formed on a third base material 1022. The first electrode 520 and the second electrode 530 can be formed on the same base material.

According to various embodiments, the transparent cover 420, the first base material 1020 including the first electrode 520 and the second electrode 530, the third base material 1022 including the third electrode 540, and the polarizing layer 1004 can be bonded together using bonding layers 1024, 1026, and 1028. For example, the transparent cover 420 and the first base material 1020 can be bonded together using the second bonding layer 1024. Alternatively, the first base material 1020 and the third base material 1022 can be bonded together using the fourth bonding layer 1026. Alternatively, the third base material 1022 including the third electrode 540 can be bonded to the polarizing layer 1004 using the fifth bonding layer 1028.

According to various embodiments, the first base material 1020 can be the first dielectric layer 550 of FIG. 5. That is, the first base material 1020 can insulate between the first electrode 520 and the second electrode 530. Alternatively, the first base material 1020 serving as the first dielectric layer 550 can support the first electrode 520 and the second electrode 530.

According to various embodiments, the fourth bonding layer 1026 can be the second dielectric layer 560 of FIG. 6. That is, the fourth bonding layer 1026 can insulate between the second electrode 530 and the third electrode 540. Alternatively, the fourth bonding layer 1026 serving as the second dielectric layer 560 can bond the first base material 1020 with the third base material 1022.

According to various embodiments, when the first electrode 520 and the second electrode 530 are used to detect a location of the touch and the second electrode 530 and the third electrode 540 are used to detect the pressure, the fourth bonding layer 1026 can be thicker than the first base material 1020. For example, the fourth bonding layer 1026 can include at least part of a different material from the second bonding layer 1024 or the fifth bonding layer 1028, or be thicker than the second bonding layer 1024 or the fifth bonding layer 1028. The fourth bonding layer 1026 can have, for example, greater elasticity or resilience than the second bonding layer 1024 or the fifth bonding layer 1028.

Referring to FIG. 10D, the first electrode 520 can be formed on a first base material 1030. The second electrode 530 and the third electrode 540 can be formed on a second base material 1032. The second electrode 530 and the third electrode 540 can be formed on either surface of the second base material 1032. That is, the second electrode 530 can be formed on a first surface 1032a of the second base material 1032, and the third electrode 540 can be formed on a second surface 1032b which is opposite to the first surface 1032a. The second electrode 530 and the third electrode 540 can be formed on the same base material.

According to various embodiments, the transparent cover 420, the first base material 1030 including the first electrode 520, the second base material 1032 including the second electrode 530 and the third electrode 540, and the polarizing layer 1004 can be bonded together using bonding layers 1034, 1036, and 1038. For example, the transparent cover 420 and the first base material 1030 can be bonded together using the second bonding layer 1034. Alternatively, the first base material 1030 and the second base material 1032 can be bonded together using the third bonding layer 1036. Alternatively, the second base material 1032 and the polarizing layer 1004 can be bonded using the fourth bonding layer 1038.

According to various embodiments, at least one of the first base material 1030 and the third bonding layer 1036 can be the first dielectric layer 550 of FIG. 5. That is, the first base material 1030 and/or the third bonding layer 1036 can insulate between the first electrode 520 and the second electrode 530. Alternatively, the first base material 1030 serving as the first dielectric layer 550 can support the first electrode 520. Alternatively, the third bonding layer 1036 serving as the first dielectric layer 550 can bond the first base material 1030 with the second base material 1032.

According to various embodiments, the second base material 1032 can be the second dielectric layer 560 of FIG. 6. That is, the second base material 1032 can insulate between the second electrode 530 and the third electrode 540. Alternatively, the second base material 1032 serving as the second dielectric layer 560 can support the second electrode 530 and the third electrode 540.

According to various embodiments, when the first electrode 520 and the second electrode 530 are used to detect location of the touch and the second electrode 530 and the third electrode 540 are used to detect the pressure, the second base material 1032 can include at least part of a different material from the first base material 1030, or be thicker than the first base material 1030. The second base material 1032 can have, for example, greater elasticity or resilience than the first base material 1030.

Referring to FIG. 10E, the first electrode 520 can be formed directly on a first base material 1040. The second electrode 530 can be formed on a second base material 1042. The third electrode 540 can be formed on the polarizing layer 1004. While the third electrode 540 faces, but not limited to, the second direction D2 on the polarizing layer 1004, it can face the first direction D1 which is opposite to the second direction D2.

According to various embodiments, the transparent cover 420, the first base material 1040 including the first electrode 520, the second base material 1042 including the second electrode 530, the polarizing layer 1004 including the third electrode 540, and the display 510 can be bonded together using bonding layers 1044 through 1047. For example, the transparent cover 420 and the first base material 1040 can be bonded together using the second bonding layer 1044. Alternatively, the first base material 1040 and the second base material 1042 can be bonded together using the third bonding layer 1045. Alternatively, the second base material 1042 and the polarizing layer 1004 can be bonded together using the fourth bonding layer 1046. Alternatively, the polarizing layer 1004 and the display 510 can be bonded together using the fifth bonding layer 1047. As the third electrode 540 is formed directly on the polarizing layer 1004, the electronic apparatus can reduce its thickness far more. While, but not limited to, the third electrode 540 is formed on the polarizing layer 1004, the first electrode 520 and/or the second electrode 530 may be formed on the polarizing layer 1004.

According to various embodiments, at least one of the first base material 1040 and the third bonding layer 1045 can be the first dielectric layer 550 of FIG. 5. That is, the first base material 1040 and/or the third bonding layer 1045 can insulate between the first electrode 520 and the second electrode 530 in order to detect a location of the touch of the external object. Alternatively, the first base material 1049 serving as the first dielectric layer 550 can support the first electrode 520. Alternatively, the third bonding layer 1045 serving as the first dielectric layer 550 can bond the first base material 1040 including the first electrode 520 with the second base material 1042 including the second electrode 530.

According to various embodiments, at least one of the second base material 1042, the fourth bonding layer 1046, and the polarizing layer 1004 can be the second dielectric layer 560 of FIG. 6. That is, at least one of the second base material 1042, the fourth bonding layer 1046, and the polarizing layer 1004 can insulate between the second electrode 530 and the third electrode 540 in order to detect the pressure of the external object. Alternatively, the second base material 1042 serving as the second dielectric layer 560 can support the second electrode 530. Alternatively, the polarizing layer 1004 serving as the second dielectric layer 560 can support the third electrode 540. Alternatively, the fourth bonding layer 1046 serving as the second dielectric layer 560 can bond the second base material 1042 including the second electrode 530 with the polarizing layer 1004 including the third electrode 540.

Referring to FIG. 10F, the first electrode 520 and the second electrode 530 can be formed on a first base material 1050. The first electrode 520 and the second electrode 530 can be formed on either surface of the first base material 1050. That is, the first electrode 520 can be formed on a first surface 1050a of the first base material 1050, and the second electrode 530 can be formed on a second surface 1050b which is opposite to the first surface 1050a. The third electrode 540 can be formed on the polarizing layer 1004. While the third electrode 540 faces, but not limited to, the second direction D2 on the polarizing layer 1004, it can face the first direction D1 which is opposite to the second direction D2.

According to various embodiments, the transparent cover 420, a first base material 1050 including a first electrode 520 and the second electrode 530, the polarizing layer 1004 including the third electrode 540, and the display 510 can be bonded together using bonding layers 1052, 1054, and 1056. For example, the transparent cover 420 and the first base material 1050 can be bonded together using the second bonding layer 1052. Alternatively, the first base material 1050 and the polarizing layer 1004 can be bonded together using the third bonding layer 1054. Alternatively, the polarizing layer 1004 and the display 510 can be bonded using the fourth bonding layer 1056.

According to various embodiments, the first base material 1050 can be the first dielectric layer 550 of FIG. 5. That is, the first base material 1050 can insulate between the first electrode 520 and the second electrode 530 in order to detect a location of the touch of the external object. Alternatively, the first base material 1050 serving as the first dielectric layer 550 can support the first electrode 520 and the second electrode 530.

According to various embodiments, at least one of the third bonding layer 1054 and the polarizing layer 1004 can be the second dielectric layer 560 of FIG. 6. That is, the third bonding layer 1054 and/or the polarizing layer 1004 can insulate between the second electrode 530 and the third electrode 540 in order to detect the pressure of the external object. Alternatively, the third bonding layer 1054 serving as the second dielectric layer 560 can bond the first base material 1050 and the polarizing layer 1004 together. Alternatively, the third bonding layer 1054 serving as the second dielectric layer 560 can support the third electrode 540.

Referring to FIG. 10G, the third electrode 540, the second electrode 530, and the first electrode 520 can be arranged along the second direction D2. The third electrode 540 can be formed on a first base material 1060. The second electrode 530 can be formed on a second base material 1062. The first electrode 520 can be formed on the display 510. For example, the first electrode 520 can be formed on the first substrate 1001 of the display 510.

According to various embodiments, the transparent cover 420, the first base material 1060 including the third electrode 540, the second base material 1062 including the second electrode 530, the polarizing layer 1004, and the display 510 including the first electrode 520 can be bonded together using bonding layers 1064 through 1069. For example, the transparent cover 420 can be bonded to the first base material 1070 including the third electrode 540 using the second bonding layer 1064. Alternatively, the first base material 1060 including the third electrode 540 can be bonded to the second base material 1062 including the second electrode 530 using the third bonding layer 1066. Alternatively, the second base material 1062 including the second electrode 530 can be bonded to the polarizing layer 1004 using the fourth bonding layer 1068. Alternatively, the polarizing layer 1004 and the display 510 including the first electrode 520 can be bonded together using the fifth bonding layer 1069.

According to various embodiments, at least one of the second base material 1062, the fourth bonding layer 1068, the polarizing layer 1004, and the fifth bonding layer 1069 can be the first dielectric layer 550 of FIG. 5. That is, at least one of the second base material 1062, the fourth bonding layer 1068, the polarizing layer 1004, and the fifth bonding layer 1069 can insulate between the first electrode 520 and the second electrode 530 in order to detect a location of the touch of the external object. Alternatively, the second base material 1062 serving as the first dielectric layer 550 can support the second electrode 530. Alternatively, the fourth bonding layer 1068 serving as the first dielectric layer 550 can bond the second base material 1062 with the polarizing layer 1004. Alternatively, the fifth bonding layer 1069 serving as the first dielectric layer 550 can bond the polarizing layer 1004 with the display 510 including the first electrode 520.

According to various embodiments, at least one of the first base material 1060 and the third bonding layer 1066 can be the second dielectric layer 560 of FIG. 6. That is, at least one of the first base material 1060 and the third bonding layer 1066 can insulate between the second electrode 530 and the third electrode 540 in order to detect the pressure of the external object. Alternatively, the first base material 1060 serving as the second dielectric layer 560 can support the third electrode 540. Alternatively, the third bonding layer 1066 serving as the second dielectric layer 560 can bond the first base material 1060 including the third electrode 540 with the second base material 1062 including the second electrode 530.

Referring to FIG. 10H, the third electrode 540, the second electrode 530, and the first electrode 520 can be arranged along the second direction D2. The third electrode 540 can be formed on a first base material 1070. The second electrode 530 can be formed on the polarizing layer 1004. The first electrode 520 can be formed on the display 510. For example, the first electrode 520 can be formed on the first substrate 1001 of the display 510.

According to various embodiments, the transparent cover 420, the first base material 1070 including the third electrode 540, the polarizing layer 1004 including the second electrode 530, and the display 510 including the first electrode 520 can be bonded together using bonding layers 1072, 1074, and 1076. For example, the transparent cover 420 can be bonded to the first base material 1070 including the third electrode 540 using the second bonding layer 1072. Alternatively, the first base material 1070 including the third electrode 540 can be bonded to the polarizing layer 1004 including the second electrode 530 using the third bonding layer 1074. Alternatively, the polarizing layer 1004 including the second electrode 530 can be bonded to the display 510 including the first electrode 520 using the fourth bonding layer 1076.

According to various embodiments, the fourth bonding layer 1076 can be the first dielectric layer 550 of FIG. 5. That is, the fourth bonding layer 1076 can insulate between the first electrode 520 and the second electrode 530 in order to detect a location of the touch of the external object. Alternatively, the fourth bonding layer 1076 serving as the first dielectric layer 550 can bond the polarizing layer 1004 including the second electrode 530 with the display 510 including the first electrode 520.

According to various embodiments, at least one of the first base material 1070, the third bonding layer 1074, and the polarizing layer 1004 can be the second dielectric layer 560 of FIG. 6. That is, at least one the first base material 1070, the third bonding layer 1074, and the polarizing layer 1004 can insulate between the second electrode 530 and the third electrode 540 in order to detect the pressure of the external object. Alternatively, the first base material 1070 serving as the second dielectric layer 560 support the third electrode 540. Alternatively, the third bonding layer 1074 serving as the second dielectric layer 560 can bond the first base material 1070 including the third electrode 540 with the polarizing layer 1004 including the second electrode 530. The polarizing layer 1004 serving as the second dielectric layer 560 can support the second electrode 530.

Referring to FIG. 10I, the first electrode 520 can be formed on the transparent cover 420. That is, the first electrode 520 can be integrated with the transparent cover 420. The first electrode 520 can face the second direction D2 on the transparent cover 420. The second electrode 530 can be formed on the polarizing layer 1004. While the second electrode 530 faces, but not limited to, the second direction D2 on the polarizing layer 1004, it can face the first direction D1 which is opposite to the second direction D2. For example, the third electrode 540 can be formed on the first substrate 1001 of the display 510.

According to various embodiments, the transparent cover 420 including the first electrode 520, the polarizing layer 1004 including the second electrode 530, and the display 510 including the third electrode 540 can be bonded together using bonding layers 1080 and 1082. For example, the transparent cover 420 including the first base material 1005 can be bonded to the polarizing layer 1004 including the second electrode 530 using the second bonding layer 1080. Alternatively, the polarizing layer 1004 including the second electrode 530 can be bonded to the display 510 including the third electrode 540 using the third bonding layer 1082.

According to various embodiments, at least one of the second bonding layer 1080 and the polarizing layer 1004 can be the first dielectric layer 550 of FIG. 5. That is, at least one of the second bonding layer 1080 and the polarizing layer 1004 can insulate between the first electrode 520 and the second electrode 530 in order to detect a location of the touch of the external object. Alternatively, the second bonding layer 1080 serving as the first dielectric layer 550 can bond the transparent cover 420 including the first electrode 520 with the polarizing layer 1004 including the second electrode 530. Alternatively, the polarizing layer 1004 serving as the first dielectric layer 550 can support the second electrode 530.

According to various embodiments, the third bonding layer 1082 can be the second dielectric layer 560 of FIG. 6. That is, the third bonding layer 1082 can insulate between the second electrode 530 and the third electrode 540 in order to detect the pressure of the external object. Alternatively, the third bonding layer 1082 serving as the second dielectric layer 560 can bond the polarizing layer 1004 including the second electrode 530 with the display 510 including the third electrode 540.

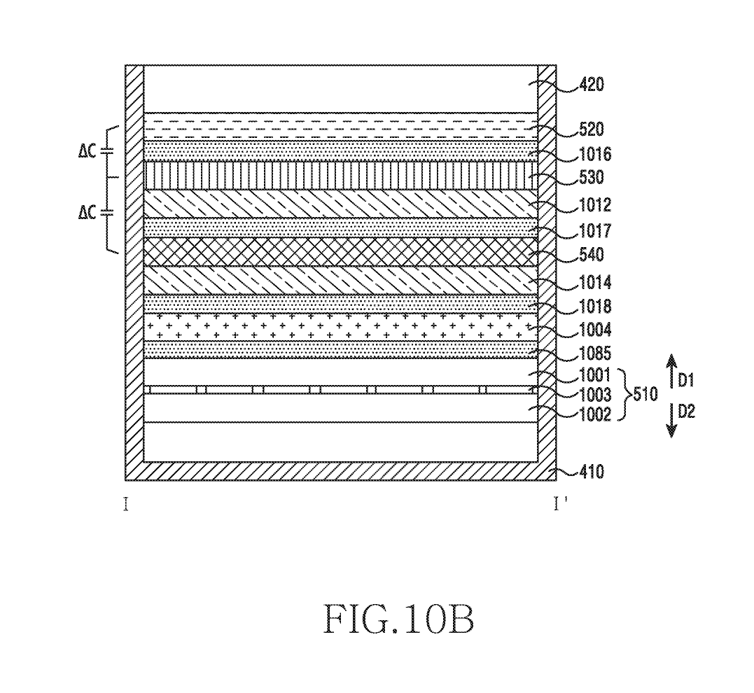

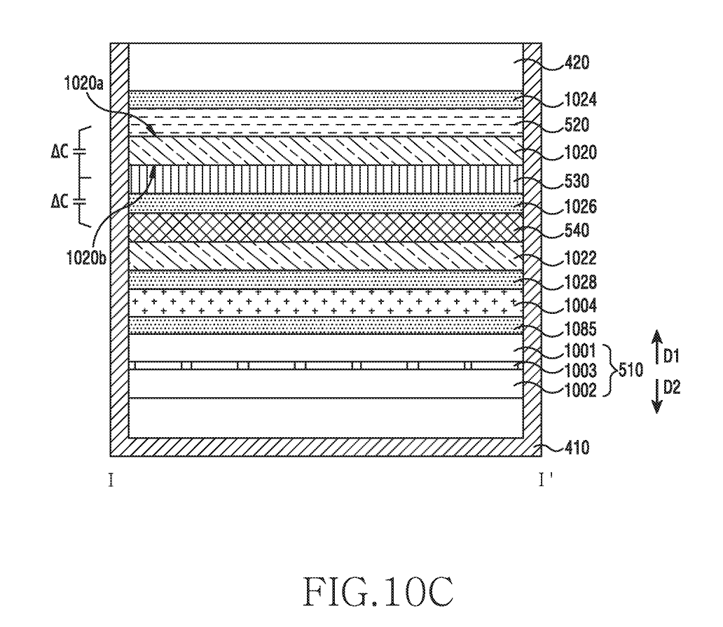

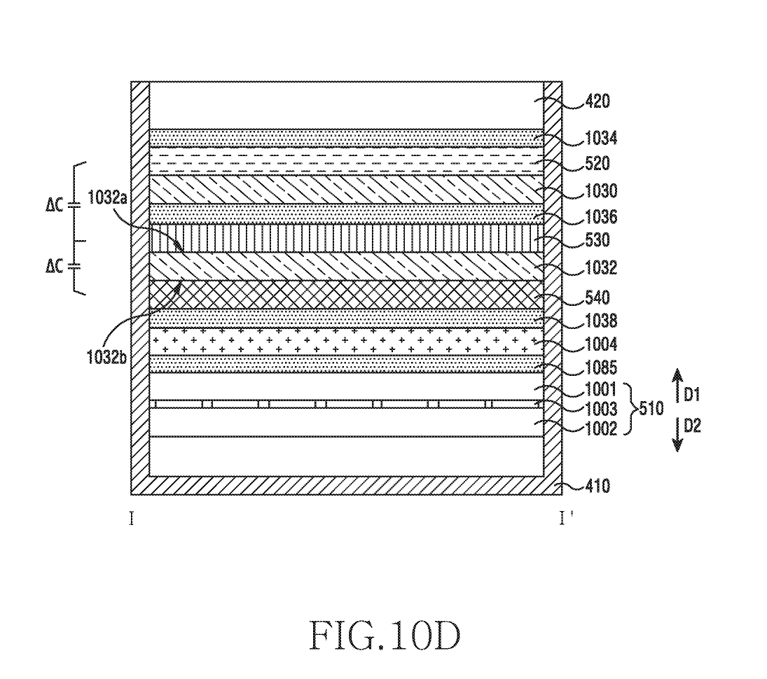

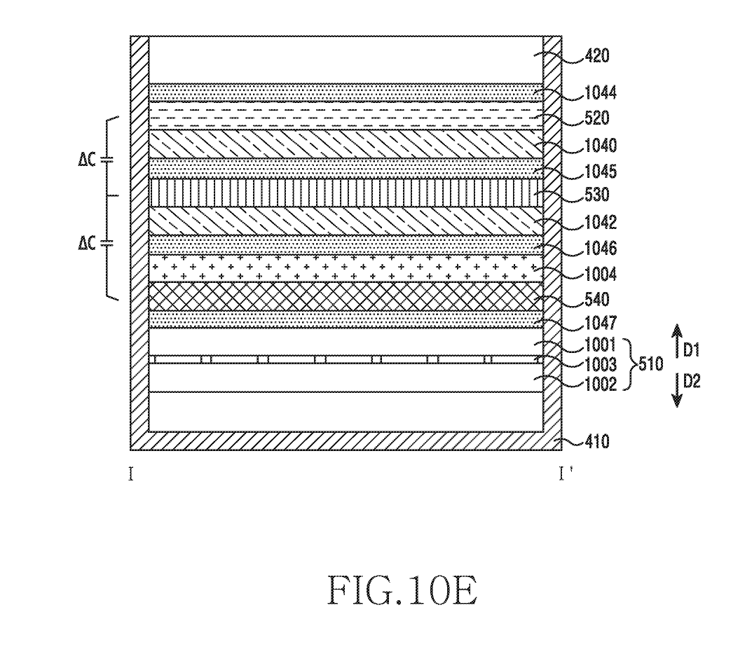

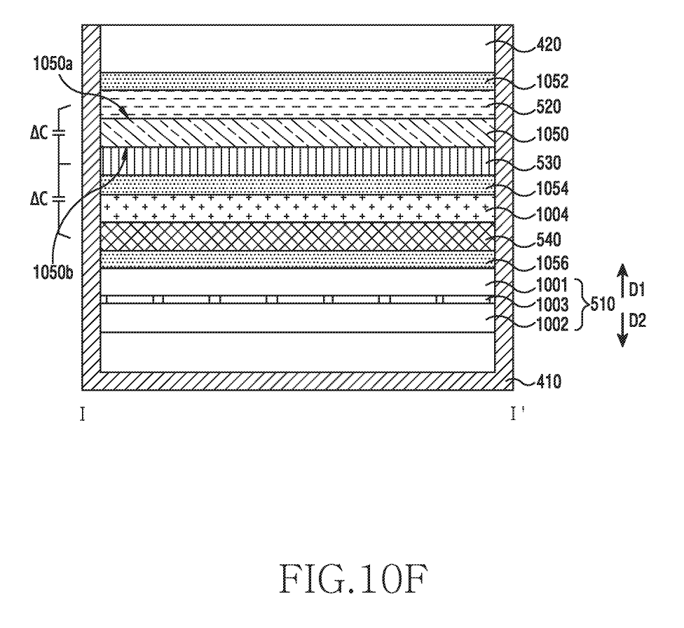

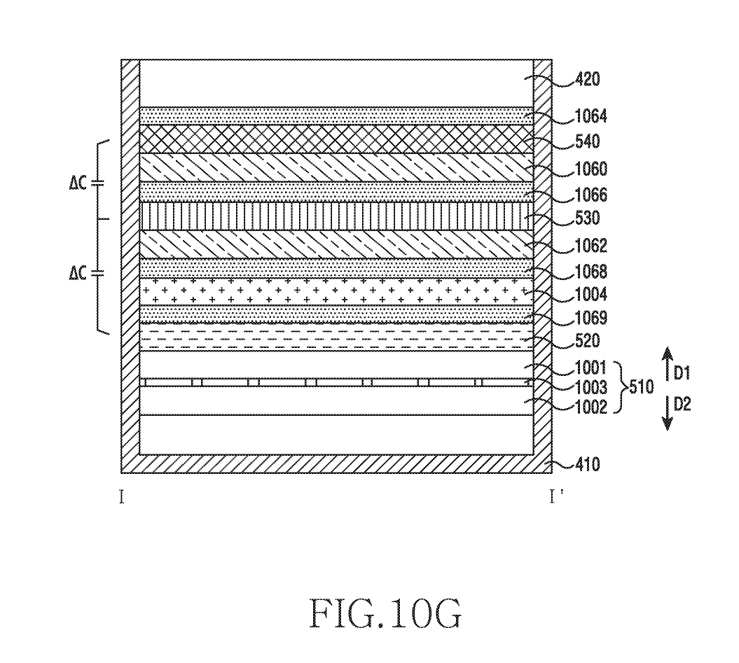

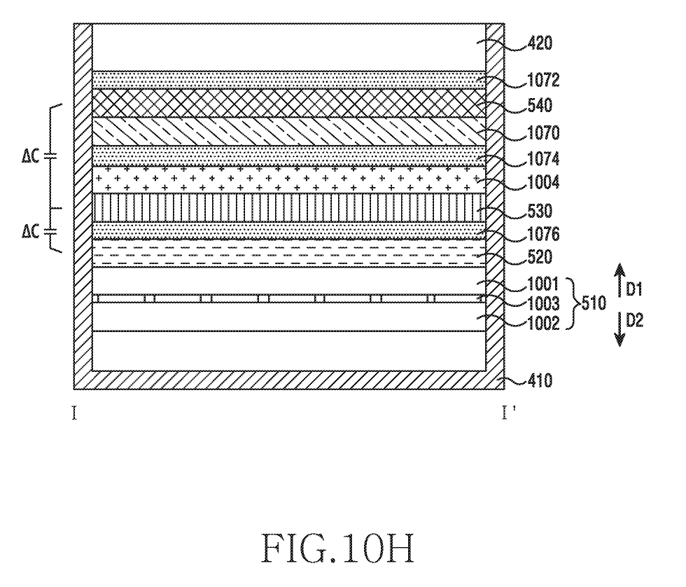

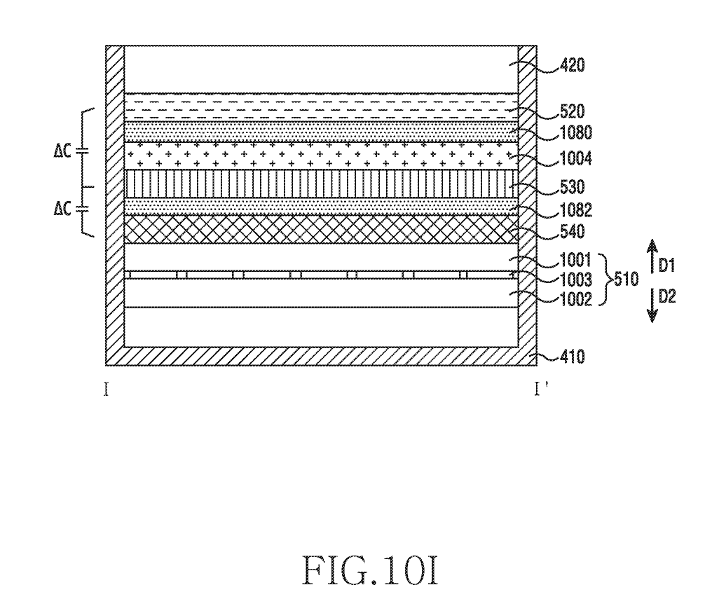

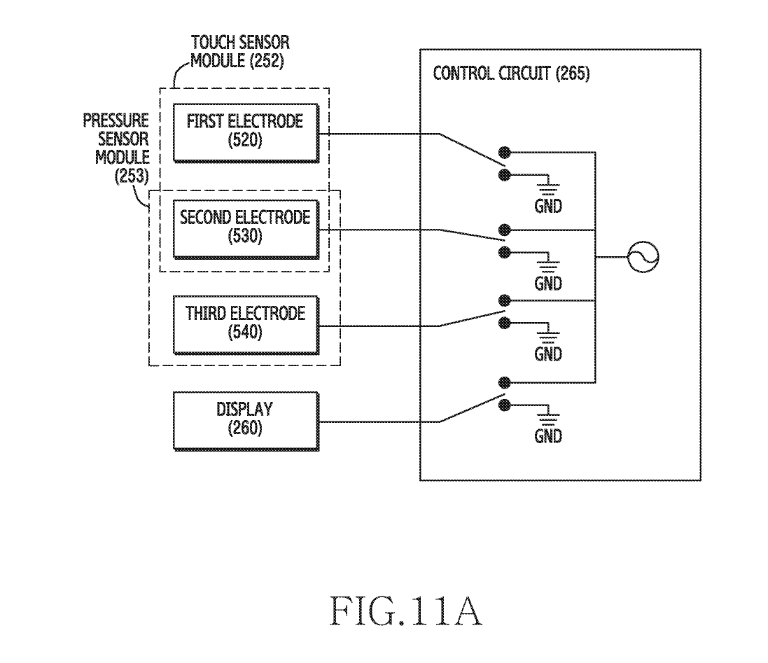

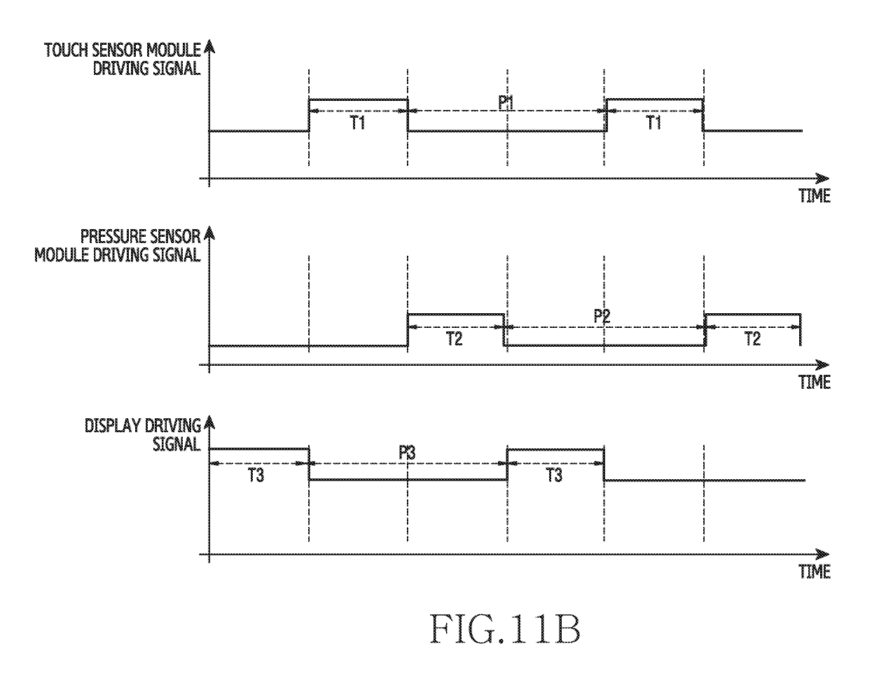

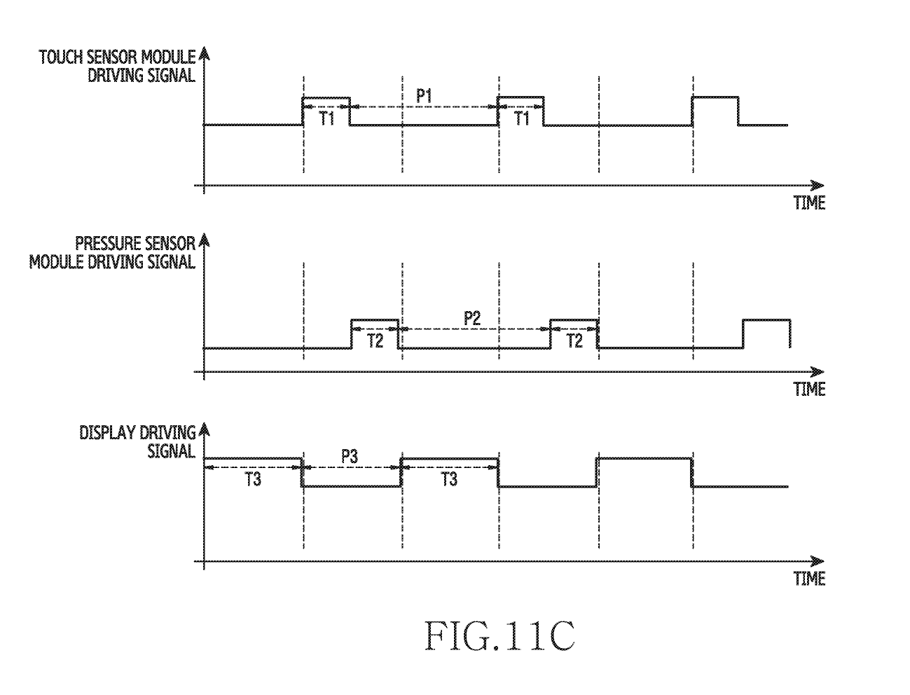

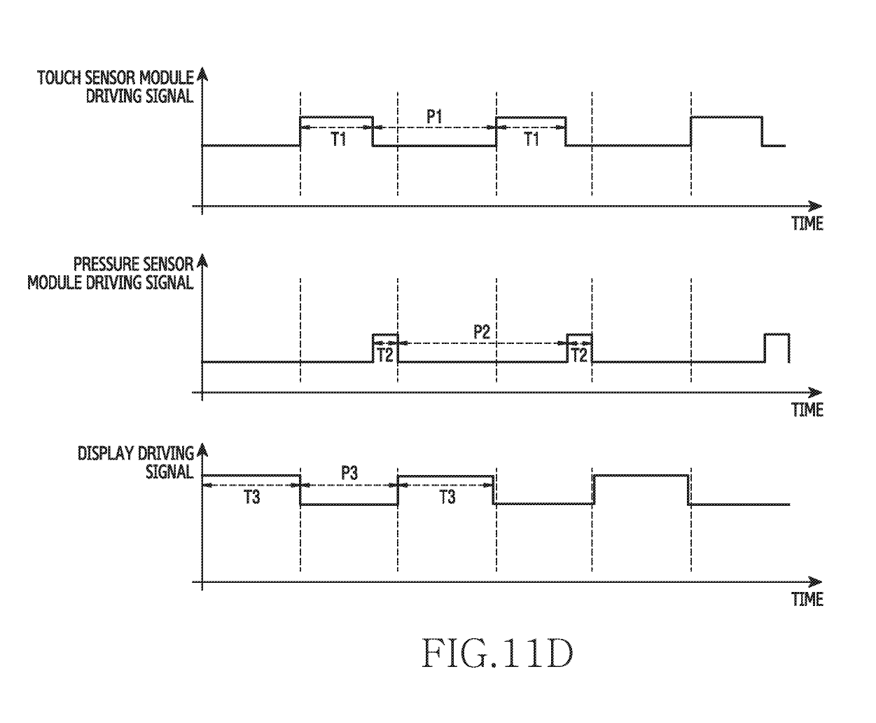

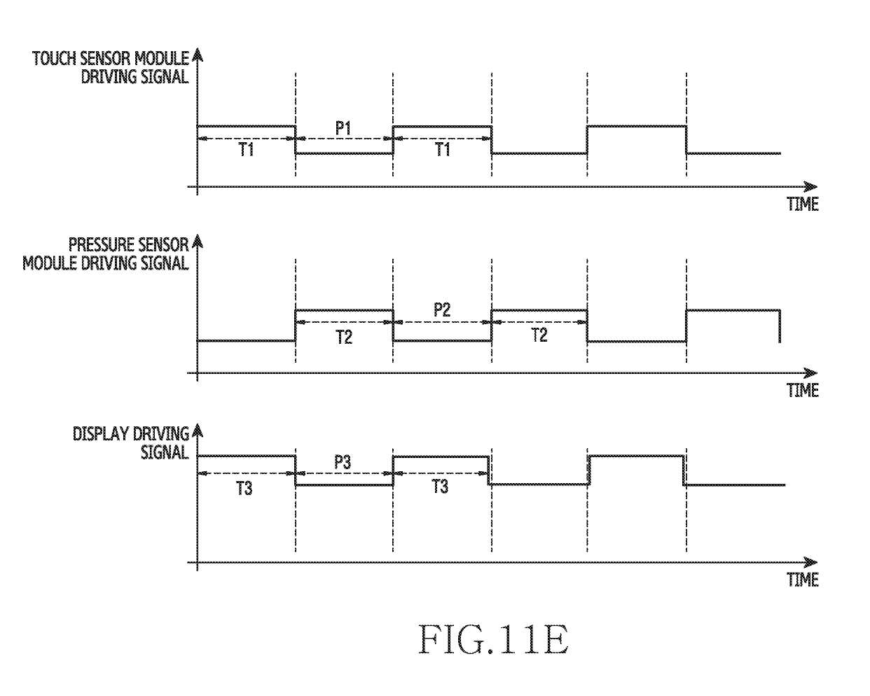

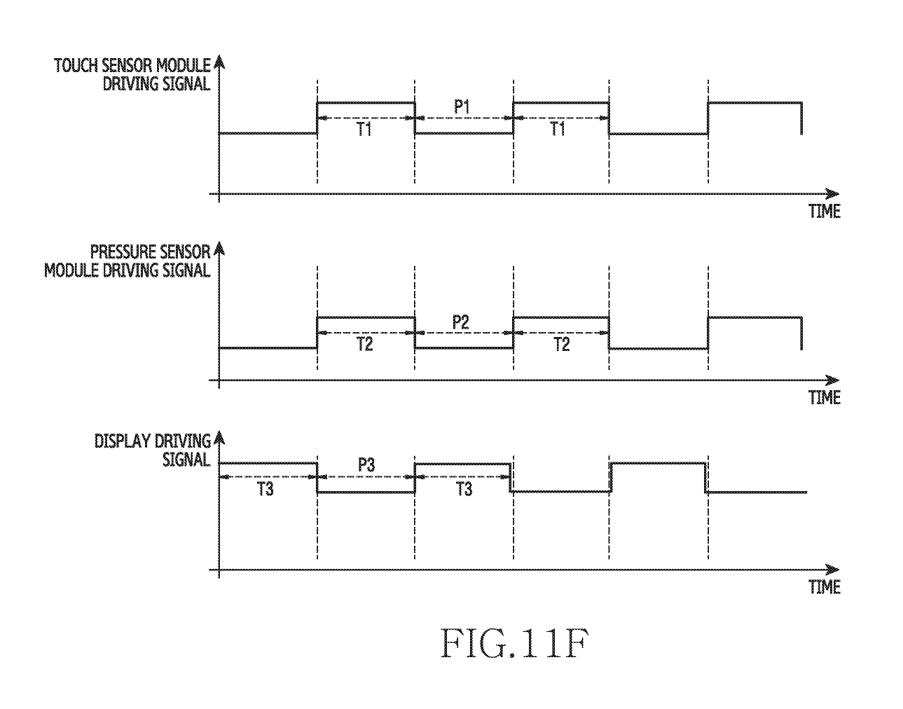

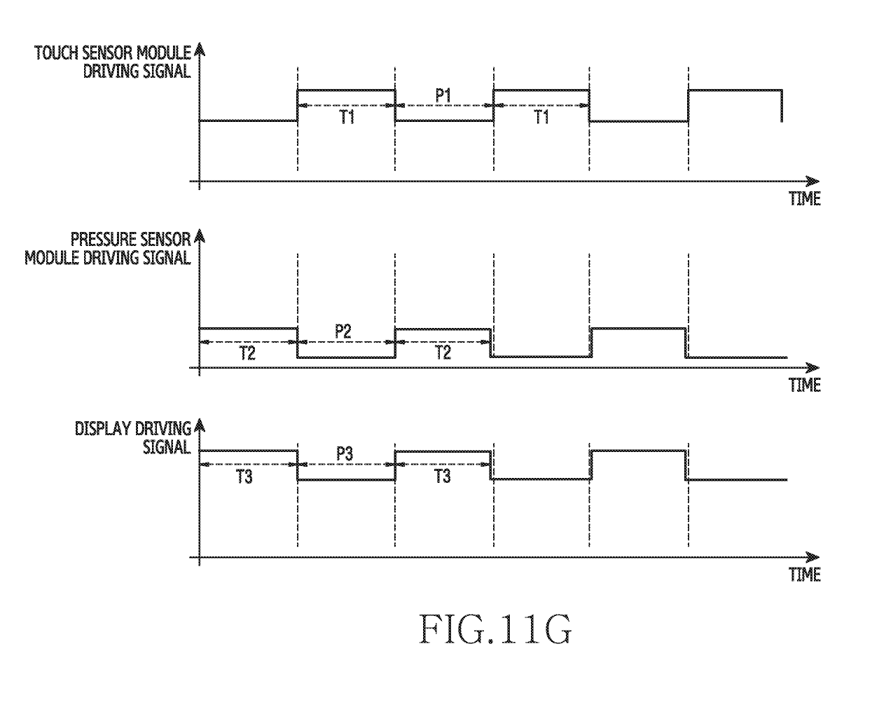

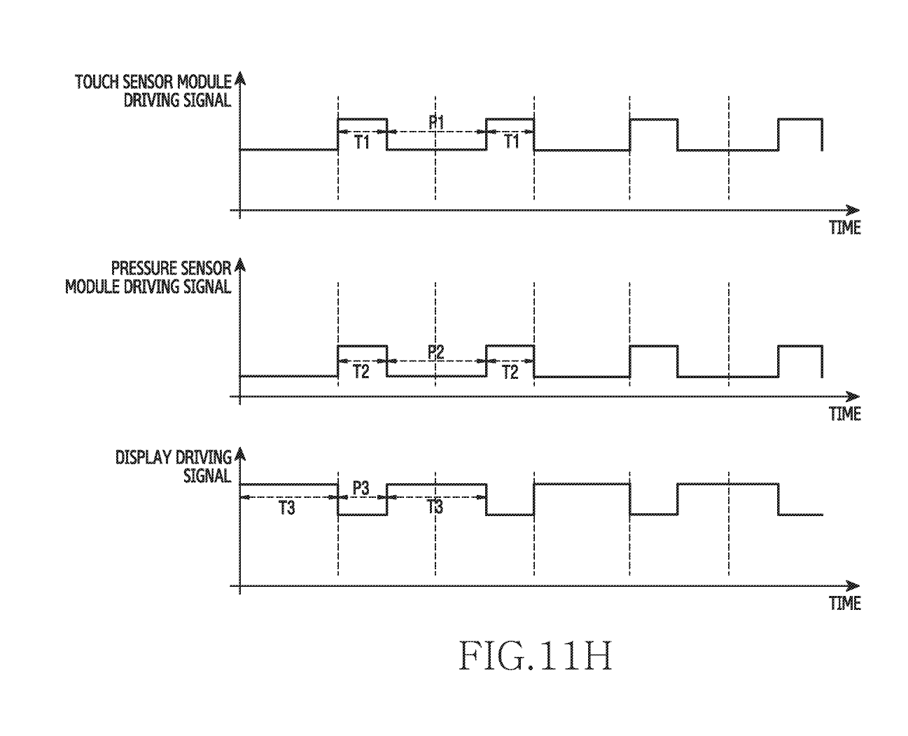

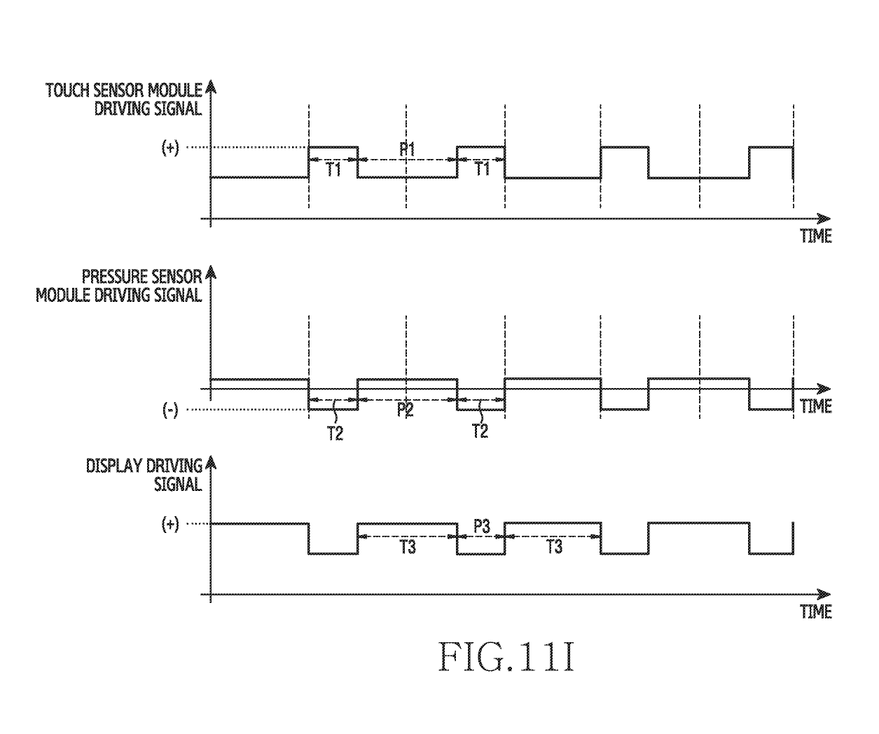

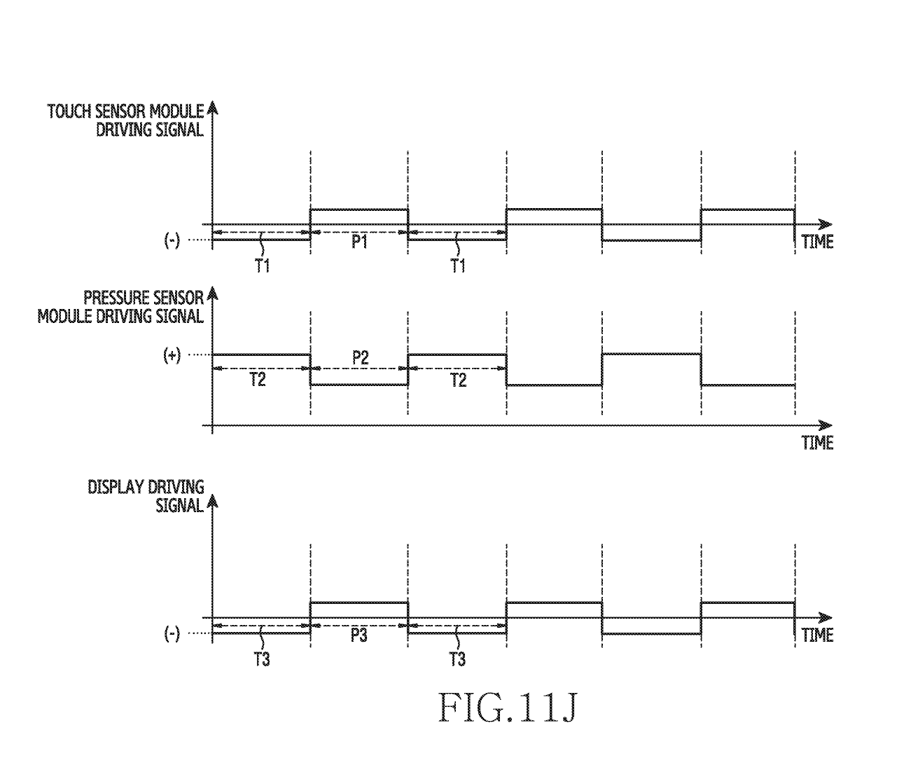

FIG. 11A is a block diagram of an electronic apparatus according to various embodiments of the present disclosure.

FIGS. 11B, 11C, 11D, 11E, 11F, 11G, 11H, 11I, and 11J are graphs illustrating driving of an electronic apparatus according to various embodiments of the present disclosure.

Referring to FIG. 11A, the control circuit 265 can drive at least one of the touch sensor module 252, the pressure sensor module 253, and the display 260 based on time division. For example, the control circuit 265 can include at least two of a control circuit for the touch sensor module 252, a control circuit for the pressure sensor module 253, and a control circuit for the display 260. The control circuit 265 can apply or receive a driving signal to or from at least one of the touch sensor module 252, the pressure sensor module 253, and the display 260. For example, the touch sensor module 252 can include the first electrode 520 and the second electrode 530, and the control circuit 265 can detect a location of the touch of the external object through the first electrode 520 and the second electrode 530. Alternatively, the pressure sensor module 253 can include the second electrode 530 and the third electrode 540, and the control circuit 265 can detect the pressure of the external object through the second electrode 530 and the third electrode 540. Alternatively, the control circuit 265 can drive a driving signal to the display 260 and thus display a screen.

Referring to FIG. 11B, the control circuit 265 can drive the touch sensor module 252 during first time periods T1. For example, the control circuit 265 can receive a receive signal based on the touch location of the external object through the first electrode 520 during the first time periods T1. In the first time periods T1, the control circuit 265 can apply a transmit signal for locating the touch to the second electrode 530 and thus receive a receive signal through the first electrode 520.

According to various embodiments, the control circuit 265 can drive the pressure sensor module 253 during second time periods T2. The second time periods T2 may not overlap at least part of the first time periods T1. For example, the control circuit 265 can receive a receive signal based on the pressure of the external object through the third electrode 540 in the second time periods T2. In the second time periods T2, the control circuit 265 can apply a transmit signal for detecting the pressure to the second electrode 530 and thus receive a receive signal through the third electrode 540.

According to various embodiments, the control circuit 265 can drive the display 260 during third time periods T3. The third time periods T3 may not overlap at least part of the first time periods T1 and/or the second time periods T2. For example, the control circuit 265 can display the screen on the display 260 in the third time periods T3.

According to various embodiments, the first time periods T1, the second time periods T2, and the third time periods T3 can have the same interval.

According to various embodiments, the first time periods T1 can have a first period P1, the second time periods T2 can have a second period P2, and the third time periods T3 can have a third period P3. The first time periods T1 can repeat according to the first period P1. The second time periods T2 can repeat according to the second period P2. The third time periods T3 can repeat according to the third period P3.

Referring to FIG. 1113, the first period P1, the second period P2, and the third period P3 can have the same interval.

According to various embodiments, the control circuit 265 can sequentially drive the touch sensor module 252, the pressure sensor module 253, and the display 260 based on the time division. Also, the control circuit 265 can apply the same interval of the driving time to the touch sensor module 252, the pressure sensor module 253, and the display 260. Alternatively, the control circuit 265 can apply the same interval of the driving period to the touch sensor module 252, the pressure sensor module 253, and the display 260.

Referring to FIG. 11C, at least one of the first time periods T1, the second time periods T2, and the third time periods T3 can be different in the interval. For example, the first time periods T1 and the second time periods T2 can have the same interval, and the interval of the third time periods T3 can be different from the interval of the first time periods T1 and the second time periods T2. The interval of the first time periods T1 and the second time periods T2 can be smaller than the interval of the third time periods T3. For example, the interval of the first time periods T1 and the second time periods T2 can be 1/6 through 1/12 of the interval of the third time periods T3. The interval of the first time periods T1 and the second time periods T2 can range from 1.39 ms to 2.78 ms.

According to various embodiments, at least one of the first period P1, the second period P2, and the third period P3 can differ in the interval. For example, the first period P1 and the second period P2 can have the same interval, and the interval of the third period P3 can be different from the interval of the first period P1 and the second period P2. The interval of the first period P1 and the second period P2 can be greater than the interval of the third period P3.

According to various embodiments, the control circuit 265 can sequentially drive the touch sensor module 252, the pressure sensor module 253, and the display 260 based on the time division. The control circuit 265 can asymmetrically drive the touch sensor module 252, the pressure sensor module 253, and the display 260 based on the time division. That is, the control circuit 265 can apply a different interval of the driving time to at least one of the touch sensor module 252, the pressure sensor module 253, and the display 260. Alternatively, the control circuit 265 can apply a different interval of the driving period to at least one of the touch sensor module 252, the pressure sensor module 253, and the display 260.

Referring to FIG. 11D, at least one of the first time periods T1, the second time periods T2, and the third time periods T3 can be different in the interval. For example, the first time periods T1, the second time periods T2, and the third time periods T3 can be different from each other in the interval. The interval can reduce in order of the third time periods T3, the first time periods T1, and the second time periods T2.

According to various embodiments, at least one of the first period P1, the second period P2, and the third period P3 can be different in the interval. For example, the first period P1, the second period P2, and the third period P3 can have different intervals from each other. The interval can reduce in order of the second period P2, the first period P1, and the third period P3.

According to various embodiments, the control circuit 265 can sequentially drive the touch sensor module 252, the pressure sensor module 253, and the display 260 based on the time division. The control circuit 265 can asymmetrically drive the touch sensor module 252, the pressure sensor module 253, and the display 260 based on the time division. That is, the control circuit 265 can apply different intervals of the driving time to the touch sensor module 252, the pressure sensor module 253, and the display 260. Alternatively, the control circuit 265 can apply different intervals of the driving period to the touch sensor module 252, the pressure sensor module 253, and the display 260.

Referring to FIG. 11E, the control circuit 265 can drive only two of the touch sensor module 252, the pressure sensor module 253, and the display 260 at the same time. At least some of the first time periods T1, the second time periods T2, and the third time periods T3 can overlap. For example, the first time periods T1 and the third time periods T3 can overlap. The first period P1 and the third period P3 can be the same. That is, the control circuit 265 can simultaneously drive the touch sensor module 252 and the display 260. The control circuit 265 can drive the touch sensor module 252 and the display 260 in the same time periods at the same period. The control circuit 265 can drive the pressure sensor module 253 in the second time periods T2 which do not overlap the first time periods T1 and the third time periods T3. The first time periods T1, the second time periods T2, and the third time periods T3 can have the same interval. The first period P1, the second period P2, and the third period P3 can have the same interval.

Referring to FIG. 11F, the control circuit 265 can drive only two of the touch sensor module 252, the pressure sensor module 253, and the display 260 at the same time. At least some of the first time periods T1, the second time periods T2, and the third time periods T3 can overlap. For example, the first time periods T1 and the second time periods T2 can overlap. The first period P1 and the second period P2 can be the same. That is, the control circuit 265 can simultaneously drive the touch sensor module 252 and the pressure sensor module 253. The control circuit 265 can drive the touch sensor module 252 and the pressure sensor module 253 in the same time periods at the same period. The control circuit 265 can drive the display 260 in the third time periods T3 which do not overlap the first time periods T1 and the second time periods 12. The first time periods T1, the second time periods T2, and the third time periods T3 can have the same interval. The first period P1, the second period P2, and the third period P3 can have the same interval.

Referring to FIG. 11G, the control circuit 265 can drive only two of the touch sensor module 252, the pressure sensor module 253, and the display 260 at the same time. At least some of the first time periods T1, the second time periods T2, and the third time periods T3 can overlap. For example, the second time periods T2 and the third time periods T3 can overlap. The second period P2 and the third period P3 can be the same. That is, the control circuit 265 can simultaneously drive the pressure sensor module 253 and the display 260. The control circuit 265 can drive the pressure sensor module 253 and the display 260 in the same time periods at the same period. The control circuit 265 can drive the touch sensor module 252 in the first time periods T1 which do not overlap the second time periods T2 and the third time periods T3. The first time periods T1, the second time periods T2, and the third time periods T3 can have the same interval. The first period P1, the second period P2, and the third period P3 can have the same interval.

Referring to FIG. 11H, the control circuit 265 can drive only two of the touch sensor module 252, the pressure sensor module 253, and the display 260 at the same time. At least some of the first time periods the second time periods T2, and the third time periods T3 can overlap. For example, the first time periods T1 and the second time periods T2 can overlap. That is, the control circuit 265 can simultaneously drive the touch sensor module 252 and the pressure sensor module 253.

The control circuit 265 can asymmetrically drive at least one of the touch sensor module 252, the pressure sensor module 253, and the display 260 based on the time division. At least one of the first time periods T1, the second time periods 12, and the third time periods T3 can have a different interval. That is, the control circuit 265 can apply a different interval of the driving time to at least one of the touch sensor module 252, the pressure sensor module 253, and the display 260. For example, the third time periods T3 can differ from the first time periods T1 and the second time periods T2. The first time periods T1 and the second time periods T2 can have the same interval, and the interval of the third time periods T3 can be greater than the interval of the first time periods T1 and the second time periods T2. That is, the control circuit 265 can apply the greater driving time to the display 260 than the driving time of the touch sensor module 252 and the pressure sensor module 253.

At least one of the first period P1, the second period P2, and the third period P3 can have a different interval. For example, the first period P1 and the second period P2 can have the same interval, and the interval of the third period P3 can be greater than the interval of the first period P1 and the second period P2.

FIG. 11I, the control circuit 265 can invert and apply a driving signal to at least one of the touch sensor module 252, the pressure sensor module 253, and the display 260. For example, the control circuit 265 can apply the inverted signal to the pressure sensor module 253. That is, the control circuit 265 can apply the inverted signal of a reference signal to the pressure sensor module 253.

According to various embodiments, the control circuit 265 can drive only two of the touch sensor module 252, the pressure sensor module 253, and the display 260 at the same time. At least some of the first time periods T1, the second time periods T2, and the third time periods T3 can overlap. For example, the first time periods T1 and the second time periods T2 can overlap. The first period P1 and the second period P2 can be the same. That is, the control circuit 265 can simultaneously drive the touch sensor module 252 and the pressure sensor module 253. The control circuit 265 can simultaneously drive the touch sensor module 252 and the pressure sensor module 253, and apply the inverted driving signal to the pressure sensor module 253. The control circuit 265 can drive the touch sensor module 252 and the pressure sensor module 253 in the same time periods at the same period. The control circuit 265 can drive the display 260 in the third time periods T3 which do not overlap the first time periods T1 and the second time periods T2.

At least one of the first period P1, the second period P2, and the third period P3 can have a different interval. For example, the first period P1 and the second period P2 can have the same interval, and the interval of the third period P3 can be smaller than the interval of the first period P1 and the second period

Referring to FIG. 11J, the control circuit 265 can invert and apply a driving signal to at least one of the touch sensor module 252, the pressure sensor module 253, and the display 260. For example, the control circuit 265 can apply the inverted signal to the touch sensor module 252 and the display 260. That is, the control circuit 265 can apply the inverted signal of a reference signal to the touch sensor module 252 and the display 260.

The control circuit 265 can drive the touch sensor module 252, the pressure sensor module 253, and the display 260 at the same time. The first time periods T1, the second time periods T2, and the third time periods T3 can overlap. Alternatively, the first period P1, the second period P2, and the third period P3 can be the same. The control circuit 265 can simultaneously drive the touch sensor module 252, the pressure sensor module 253, and the display 260, and apply the inverted driving signal to the touch sensor module 252 and the display 260.

Signal interference between the touch sensor module 252, the pressure sensor module 253, and the display 260 can be prevented, and driving efficiency can be improved.

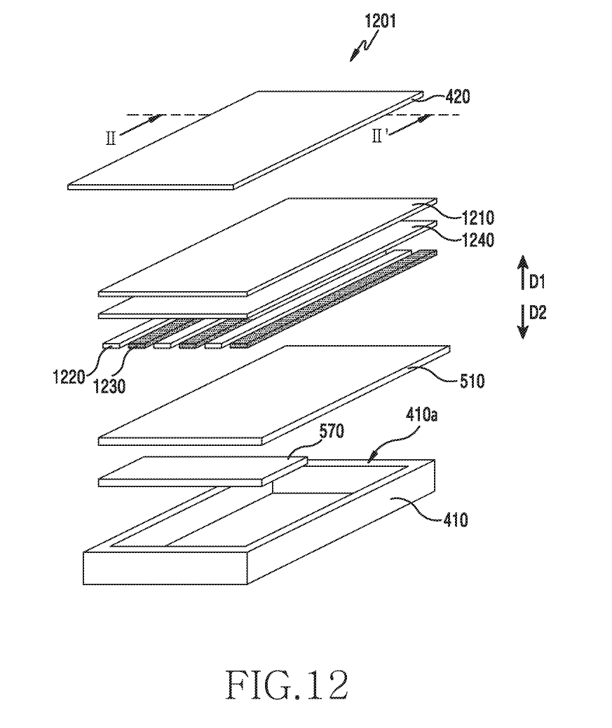

FIG. 12 is an exploded view of an electronic apparatus according to various embodiments of the present disclosure.

Referring to FIG. 12, an electronic apparatus 1201 can include a housing 410, a transparent cover 420, a display 510, a first electrode 1210, a second electrode 1220, a third electrode 1230, a first dielectric layer 1240, a second dielectric layer 1310 of FIGS. 13A and 13B, and a haptic actuator 570. The same or similar components to those shown in FIG. 5 shall be omitted here.

The first electrode 1210, the second electrode 1220, the third electrode 1230, the first dielectric layer 1240, and the second dielectric layer 1310 can be disposed between the transparent cover 420 and the display 510. The first electrode 1210, the second electrode 1220, the third electrode 1230, the first dielectric layer 1240, and the second dielectric layer 1310 can construct the touch sensor module 252 and/or the pressure sensor module 253 of FIGS. 2A and 2B. The touch sensor module 252 and the pressure sensor module 253 can share the first electrode 1210. For example, the first electrode 1210, the first dielectric layer 1240, and the second electrode 1220 can construct the pressure sensor module 253 and thus detect pressure of an external object on a first surface 410a. For doing so, a control circuit 265 can apply a transmit signal to the first electrode 1210 or the second electrode 1220, and receive a receive signal corresponding to the transmit signal through the first electrode 1210 or the second electrode 1220. For example, the control circuit 265 can apply a transmit signal to the first electrode 1210, and receive a receive signal corresponding to the transmit signal through the second electrode 1220. The control circuit 265 can detect a capacitance change based on a thickness change of the first dielectric layer 1240, that is, based on a distance change between the first electrode 1210 and the second electrode 1220 according to the pressure of the external object.

According to various embodiments, the first electrode 1210, the first dielectric layer 1240, and the third electrode 1230 can construct the touch sensor module 252 and thus detect a location of the touch of the external object on the first surface 410a. For doing so, the control circuit 265 of FIGS. 2A and 2B can apply a transmit signal to the first electrode 1210 or the third electrode 1230, and receive a receive signal corresponding to the transmit signal through the first electrode 1210 or the third electrode 1230. For example, the control circuit 265 can apply a transmit signal to the first electrode 1210, and receive a receive signal corresponding to the transmit signal through the third electrode 1230. The control circuit 265 can detect a location of the touch by detecting the capacitance change between the first electrode 1210 and the third electrode 1230 according to the touch of the external object.

According to various embodiments, the second electrode 1220 can be disposed between the first electrode 1210 and the display 510. The third electrode 1230 can be disposed between the first electrode 1210 and the display 510. The second electrode 1220 and the third electrode 1230 can be disposed on the substantially same plane.

According to various embodiments, the first dielectric layer 1240 can be disposed between the first electrode 1210 and the second electrode 1220. The second dielectric layer 1310 can be disposed between the second electrode 1220 and the third electrode 1230. The second dielectric layer 1310 can be substantially copular with the second electrode 1220 and the third electrode 1230. The first dielectric layer 1240, which has the elasticity or the resilience, can change in thickness according to the pressure of the external object.

According to various embodiments, at least one of the first electrode 1210, the second electrode 1220, and the third electrode 1230 can have different patterns, to be explained by referring to FIGS. 13A and 13B.

FIG. 13A is a plane view of a first electrode in an electronic apparatus according to various embodiments of the present disclosure.

FIG. 13B is a plane view of a second electrode and a third electrode in an electronic apparatus according to various embodiments of the present disclosure.

FIG. 13A, the first electrode 1210 can include electrode patterns iterated along the X axis. For example, the first electrode 1210 can include one electrode pattern longitudinally formed along the Y axis. The one electrode pattern of the first electrode 1210 can include various shapes such as a diamond, a triangle, a rectangle, a pentagon, a polygon, a circle, a bar, or a mesh.

Referring to FIG. 13B, the second electrode 1220 can cross the first electrode 1210. The second electrode 1220 can include electrode patterns iterating along the X axis. For example, the second electrode 1220 can include one electrode pattern longitudinally formed along the Y axis. The one electrode pattern of the second electrode 1220 can include various shapes such as a diamond, a triangle, a rectangle, a pentagon, a polygon, a circle, a bar, or a mesh.

According to various embodiments, the third electrode 1230 can be substantially coplanar with the second electrode 1220. The third electrode 1230 can cross the second electrode 1220. The third electrode 1230 can include electrode patterns iterating along the Y axis. For example, the third electrode 1230 can include one electrode pattern longitudinally formed along the X axis. The one electrode pattern of the third electrode 1230 can include various shapes such as a diamond, a triangle, a rectangle, a pentagon, a polygon, a circle, a bar, or a mesh.

According to various embodiments, the second dielectric layer 1310 can be disposed between the second electrode 1220 and the third electrode 1230. The second dielectric layer 1310 may not overlap the second electrode 1220 and the third electrode 1230. The second dielectric layer 1310 can prevent an electric short by insulting between the second electrode 1220 and the third electrode 1230.

FIG. 14A is a perspective view of a first electrode, a second electrode, and a third electrode in an electronic apparatus according to various embodiments of the present disclosure.

FIG. 14B is a plane view of a first electrode, a second electrode, and a third electrode in an electronic apparatus according to various embodiments of the present disclosure.

Referring to FIGS. 14A and 14B, when viewed from above, an overlapping region of the first electrode 1210 and the second electrode 1220 can be greater than an overlapping region of the first electrode 1210 and the third electrode 1230. That is, the overlapping region of the first electrode 1210 and the second electrode 1220 which construct the pressure sensor module 253 can be greater than the overlapping region of the first electrode 1210 and the third electrode 1230 which construct the touch sensor module 252.

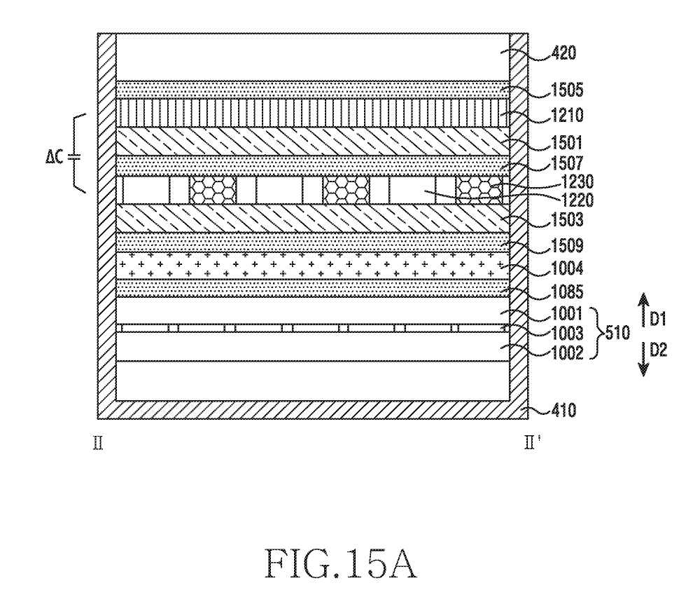

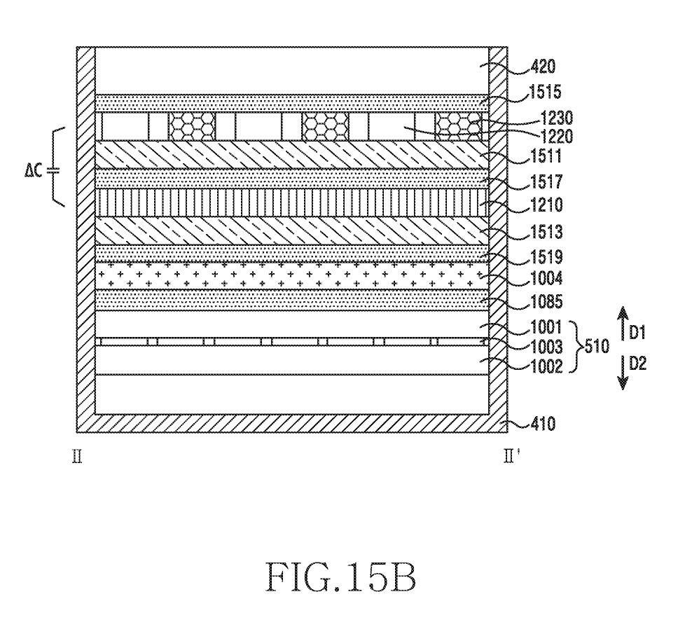

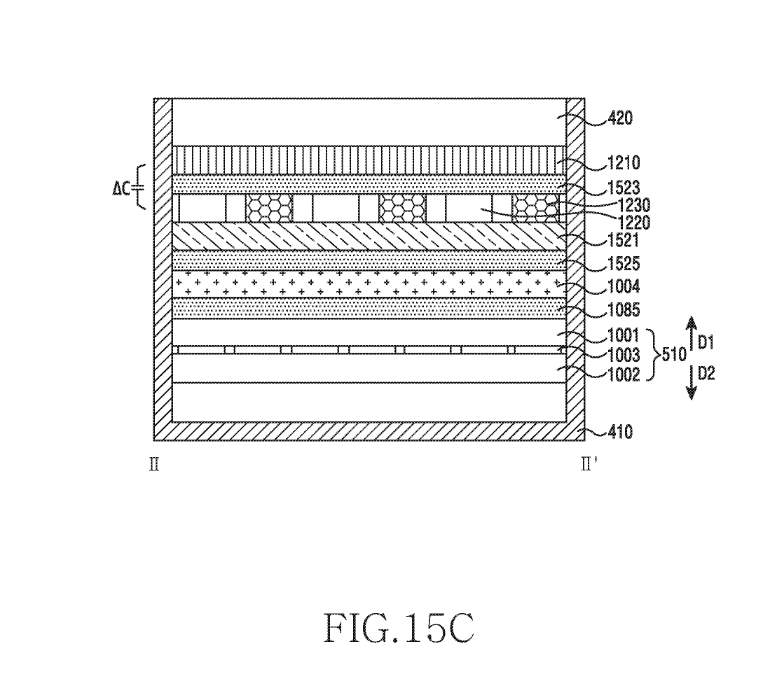

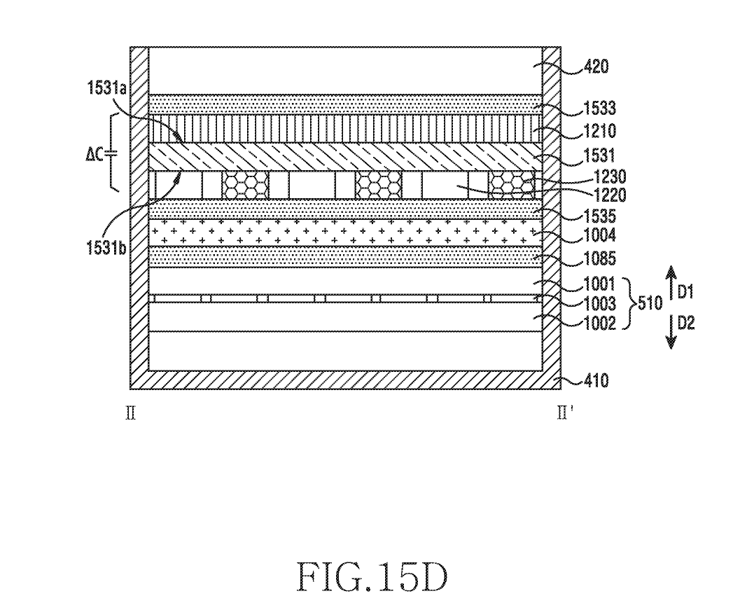

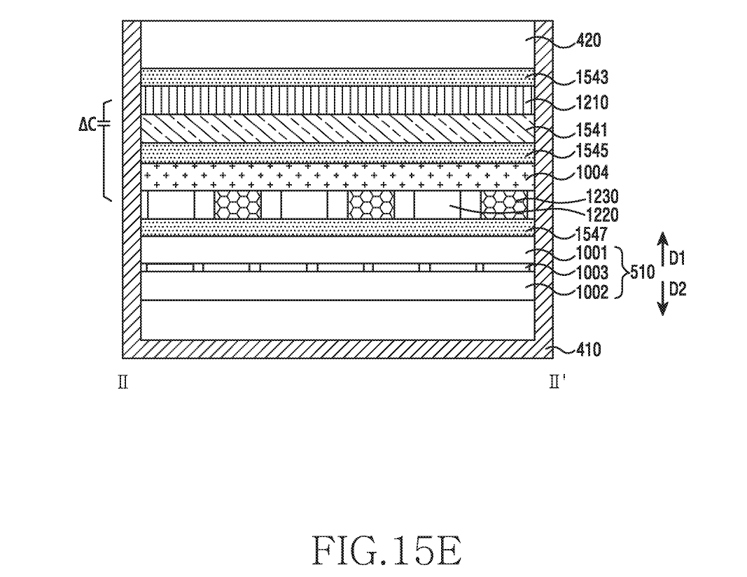

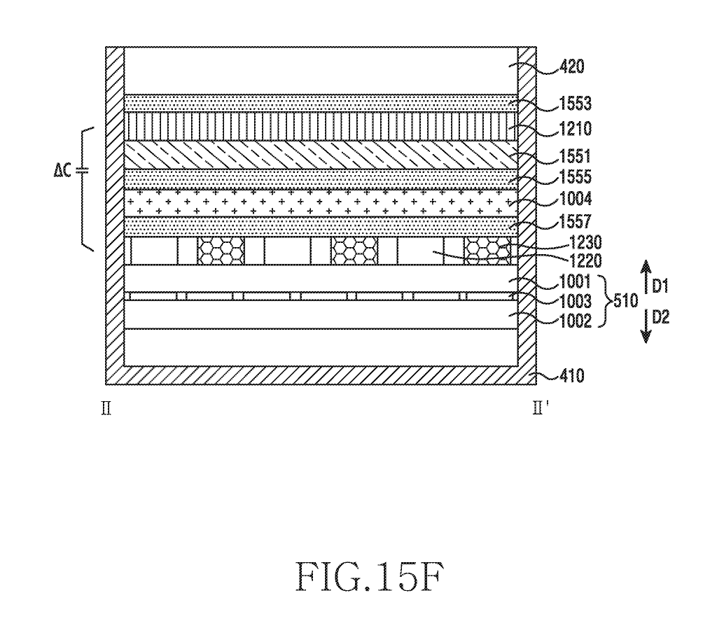

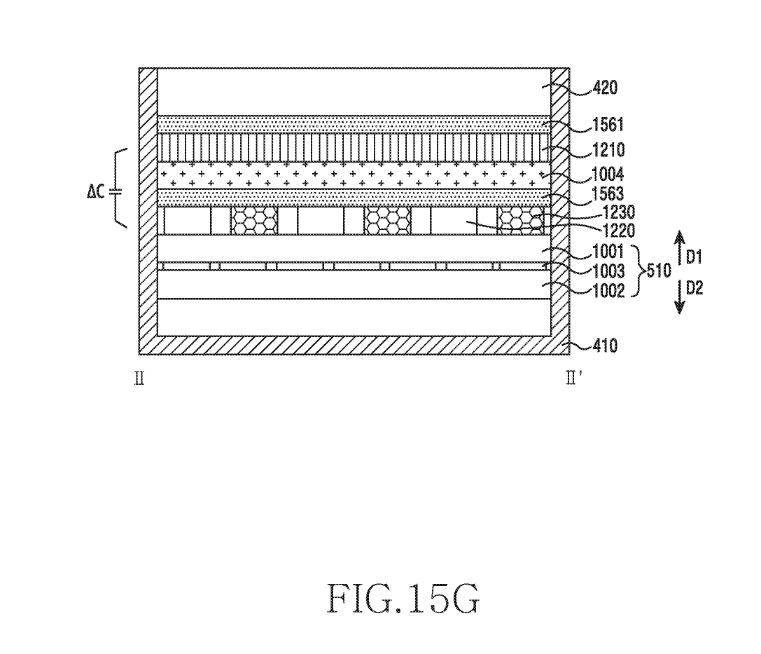

FIGS. 15A, 15B, 15C, 15D, 15E, 15F, and 15G are cross-sectional views taken along of FIG. 12 according to various embodiments of the present disclosure.

Referring to FIG. 15A, the first electrode 1210, the second electrode 1220, and the third electrode 1230 can be disposed between the transparent cover 420 and the display 510. The display 510 can include the first substrate 1001, the second substrate 1002, and the liquid crystals 1003.

According to various embodiments, the first electrode 1210 can be formed on a first base material 1501. The second electrode 1220 and the third electrode 1230 can be formed on a second base material 1503. The second electrode 1220 and the third electrode 1230 can be disposed between the first electrode 1210 and the display 510. Although the first electrode 1210 faces, but not limited to, the first direction D1 on the first base material 1501, it may face the second direction D2 which is opposite to the first direction D1. Alternatively, although the second electrode 1220 and the third electrode 1230 face, but not limited to, the first direction D1 on the second base material 1503, they may face the second direction D2 which is opposite to the first direction D1.

According to various embodiments, the transparent cover 420, the first base material 1501 including the first electrode 1210, the second base material 1503 including the second electrode 1220 and the third electrode 1230, and the polarizing layer 1004 can be bonded together using bonding layers 1505, 1507, and 1509. For example, the transparent cover 420 and the first base material 1501 including the first electrode 1210 can be bonded together using the first bonding layer 1505. Alternatively, the first base material 1501 and the second base material 1503 can be bonded together using the second bonding layer 1507. Alternatively, the second base material 1503 including the second electrode 1220 and the third electrode 1230 can be bonded to the polarizing layer 1004 using the third bonding layer 1509.

According to various embodiments, at least one of the first base material 1501 and the second bonding layer 1507 can be the first dielectric layer 1240 of FIG. 12. That is, the first base material 1501 and/or the second bonding layer 1507 can insulate between the first electrode 1210 and the second electrode 1220 in order to detect the pressure of the external object. Alternatively, the first base material 1501 and/or the second bonding layer 1507 can insulate between the first electrode 1210 and the third electrode 1230 to detect a location of the touch of the external object. The first base material 1501 serving as the first dielectric layer 1240 can support the first electrode 1210. Alternatively, the second bonding layer 1507 serving as the first dielectric layer 1240 can bond the first base material 1501 with the second base material 1503. The second bonding layer 1507 can include at least part of a different material from the first bonding layer 1505 or the third bonding layer 1509. Alternatively, the second bonding layer 1507 can be thicker than the first bonding layer 1505 or the third bonding layer 1509,

Referring to FIG. 15B, the second electrode 1220 and the third electrode 1230 can he formed on a first base material 1511. The first electrode 1210 can be formed on a second base material 1513. The first electrode 1210 can be disposed between the second electrode 1220 and the display 510.

According to various embodiments, the transparent cover 420, the first base material 1511 including the second electrode 1220 and the third electrode 1230, the second base material 1513 including the first electrode 1210, and the polarizing layer 1004 can be bonded together using bonding layers 1515, 1517, and 1519. For example, the transparent cover 420 and the first base material 1511 can be bonded together using the first bonding layer 1515. Alternatively, the first base material 1511 and the second base material 1513 can be bonded together using the second bonding layer 1517. Alternatively, the second base material 1513 including the first electrode 1210 can be bonded to the polarizing layer 1004 using the third bonding layer 1519.

According to various embodiments, at least one of the first base material 1511 and the second bonding layer 1517 can be the first dielectric layer 1240 of FIG. 12. That is, the first base material 1511 and/or the second bonding layer 1517 can insulate between the first electrode 1210 and the second electrode 1220 in order to detect the pressure of the external object. Alternatively, the first base material 1511 and/or the second bonding layer 1517 can insulate between the first electrode 1210 and the third electrode 1230 in order to detect a location of the touch of the external object. The first base material 1511 serving as the first dielectric layer 1240 can support the second electrode 1220 and the third electrode 1230. Alternatively, the second bonding layer 1517 serving as the first dielectric layer 1240 can bond the first base material 1511 with the second base material 1513. The second bonding layer 1517 can include at least part of a different material from the first bonding layer 1515 or the third bonding layer 1519. Alternatively, the second bonding layer 1517 can be thicker than the first bonding layer 1515 or the third bonding layer 1519.

Referring to FIG. 15C, the first electrode 1210 can be formed on the transparent cover 420. That is, the first electrode 1210 can be integrated with the transparent cover 420. The first electrode 1210 can face the second direction D2 on the transparent cover 420. The second electrode 1220 and the third electrode 1230 can be formed on a first base material 1521. The second electrode 1220 and the third electrode 1230 can be disposed between the first electrode 1210 and the display 510.

According to various embodiments, the transparent cover 420 including the first electrode 1210, the first base material 1521 including the second electrode 1220 and the third electrode 1230, and the polarizing layer 1004 can be bonded together using bonding layers 1523 and 1525. For example, the transparent cover 420 including the first electrode 1210 can be bonded to the first base material 1521 using the first bonding layer 1523. Alternatively, the first base material 1521 including the second electrode 1220 and the third electrode 1230 can be bonded to the polarizing layer 1004 using the second bonding layer 1525.

According to various embodiments, the first bonding layer 1523 can be the first dielectric layer 1240 of FIG. 12. That is, the first base material 1523 can insulate between the first electrode 1210 and the second electrode 1220 in order to detect the pressure of the external object. Alternatively, the first base material 1523 serving as the first dielectric layer 1240 can insulate between the first electrode 1210 and the third electrode 1230 in order to detect a location of the touch of the external object. The first bonding layer 1523 serving as the first dielectric layer 1240 can bond the transparent cover 420 with the first base material 1521. The first bonding layer 1523 can include at least part of a different material from the second bonding layer 1525. Alternatively, the first bonding layer 1523 can be thicker than the second bonding layer 1525.

Referring to FIG. 15D, the first electrode 1210, the second electrode 1220, and the third electrode 1230 can be formed on a first base material 1531. The first electrode 1210, the second electrode 1220, and the third electrode 1230 can be formed on either surface of the first base material 1531. That is, the first electrode 1210 can be formed on a first surface 1531a of the first base material 1531, and the second electrode 1220 and the third electrode 1230 can be formed on a second surface 1531b which is opposite to the first surface 1531a. The first electrode 1210, the second electrode 1220, and the third electrode 1230 can be formed on the same base material.

According to various embodiments, the transparent cover 420, the first base material 1531, and the polarizing layer 1004 can be bonded together using bonding layers 1533 and 1535. For example, the transparent cover 420 and the first base material 1531 can be bonded together using the first bonding layer 1533. Alternatively, the first base material 1531 can be bonded to the polarizing layer 1004 using the second bonding layer 1535.

According to various embodiments, the first base material 1531 can be the first dielectric layer 1240 of FIG. 12. That is, the first base material 1531 can insulate between the first electrode 1210 and the second electrode 1220 in order to detect the pressure of the external object. Alternatively, the first base material 1531 can insulate between the first electrode 1210 and the second electrode 1220 in order to detect a location of the touch of the external object. The first base material 1531 serving as the first dielectric layer 1240 can support the first electrode 1210, the second electrode 1220, and the third electrode 1230.

Referring to FIG. 15E, the first electrode 1210 can be formed on a first base material 1541. The second electrode 1220 and the third electrode 1230 can be formed on the polarizing layer 1004. The second electrode 1220 and the third electrode 1230 can be interposed between the first electrode 1210 and the display 510. While the first electrode 1210 faces, but not limited to, the first direction D1 on the first base material 1541, it can face the second direction D2 which is opposite to the first direction D1. Alternatively, while the second electrode 1220 and the third electrode 1230 face, but not limited to, the second direction D2 on the polarizing layer 1004, they may face the first direction D1 which is opposite to the second direction D2.

According to various embodiments, the transparent cover 420, the first base material 1541 including the first electrode 1210, the polarizing layer 1004 including the second electrode 1220 and the third electrode 1230, and the display 510 can be bonded together using bonding layers 1543, 1545, and 1547. For example, the transparent cover 420 and the first base material 1541 including the first electrode 1210 can be bonded together using the first bonding layer 1543. Alternatively, the first base material 1541 and the polarizing layer 1004 can be bonded together using the second bonding layer 1545. Alternatively, the polarizing layer 1004 and the display 510 can be bonded together using the third bonding layer 1547.

According to various embodiments, at least one of the first base material 1541, the second bonding layer 1545, and the polarizing layer 1004 can be the first dielectric layer 1240 of FIG. 12. That is, at least one of the first base material 1541, the second bonding layer 1545, and the polarizing layer 1004 can insulate between the first electrode 1210 and the second electrode 1220 in order to detect the pressure of the external object. Alternatively, at least one of the first base material 1541, the second bonding layer 1545, and the polarizing layer 1004 can insulate between the first electrode 1210 and the third electrode 1230 in order to detect a location of the touch of the external object.

Referring to FIG. 15F, the first electrode 1210 can be formed on a first base material 1551. The second electrode 1220 and the third electrode 1230 can be formed on the display 510. For example, the second electrode 1220 and the third electrode 1230 can be formed on the first substrate 1001 of the display 510.

According to various embodiments, the transparent cover 420, the first base material 1551 including the first electrode 1210, the polarizing layer 1004, and the display 510 can be bonded together using bonding layers 1553, 1555, and 1557. For example, the transparent cover 420 and the first base material 1551 including the first electrode 1210 can be bonded together using the first bonding layer 1553. Alternatively, the first base material 1551 and the polarizing layer 1004 can be bonded together using the second bonding layer 1555. Alternatively, the polarizing layer 1004 can be bonded to the display 510 including the second electrode 1220 and the third electrode 1230 using the third bonding layer 1557.

According to various embodiments, at least one of the first base material 1551, the second bonding layer 1555, the polarizing layer 1004, and the third bonding layer 1557 can be the first dielectric layer 1240 of FIG. 12. That is, at least one of the first base material 1551, the second bonding layer 1555, the polarizing layer 1004, and the third bonding layer 1557 can insulate between the first electrode 1210 and the second electrode 1220 in order to detect the pressure of the external object. Alternatively, at least one of the first base material 1551, the second bonding layer 1555, the polarizing layer 1004, and the third bonding layer 1557 can insulate between the first electrode 1210 and the third electrode 1230 in order to detect a location of the touch of the external object.

Referring to FIG. 15G, the first electrode 1210 can be formed on the polarizing layer 1004. The second electrode 1220 and the third electrode 1230 can be formed on the display 510. For example, the second electrode 1220 and the third electrode 1230 can be formed on the first substrate 1001 of the display 510.

According to various embodiments, the transparent cover 420, the polarizing layer 1004 including the first electrode 1210, and the display 510 can be bonded together using bonding layers 1561 and 1563. For example, the transparent cover 420 can be bonded to the polarizing layer 1004 including the first electrode 1210 using the first bonding layer 1561. Alternatively, the polarizing layer 1004 and the display 510 can be bonded together using the second bonding layer 1563.

According to various embodiments, at least one of the polarizing layer 1004 and the second bonding layer 1563 can be the first dielectric layer 1240 of FIG. 12. That is, the polarizing layer 1004 and/or the second bonding layer 1563 can insulate between the first electrode 1210 and the second electrode 1220 in order to detect the pressure of the external object. Alternatively, the polarizing layer 1004 and/or the second bonding layer 1563 can insulate between the first electrode 1210 and the third electrode 1230 in order to detect a location of the touch of the external object.

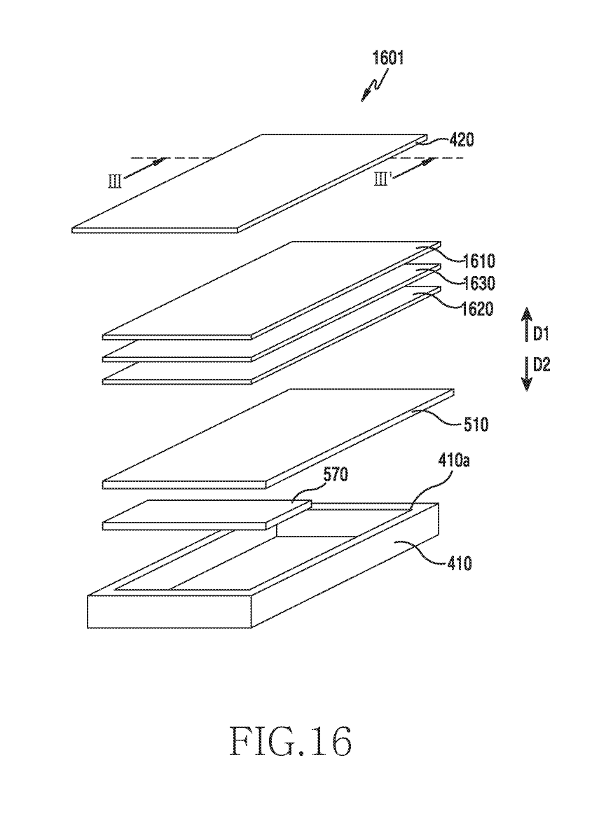

FIG. 16 is an exploded view of an electronic apparatus according to various embodiments of the present disclosure.

Referring to FIG. 16, an electronic apparatus 1601 can include a housing 410, a transparent cover 420, a display 510, a first electrode 1610, a second electrode 1620, a first dielectric layer 1630, and a haptic actuator 570. The same or similar components to those shown in FIG. 5 shall be omitted.

According to various embodiments, the first electrode 1610, the first dielectric layer 1630, and the second electrode 1620 can be disposed between the transparent cover 420 and the display 510. The first electrode 1610, the first dielectric layer 1630, and the second electrode 1620 can construct the touch sensor module 252 and/or the pressure sensor module 253 of FIGS. 2A and 2B. For example, the first electrode 1610, the first dielectric layer 1630, and the second electrode 1620 can construct the touch sensor module 252 and thus detect a location of the touch of the external object on the first surface 410a. For doing so, the control circuit 265 can apply a transmit signal to the first electrode 1610 and connect the second electrode 1620 to the ground (GND). The control circuit 265 can detect a capacitance change of each individual electrode of the first electrode 1610 according to the touch of the external object.

According to various embodiments, the first electrode 1610, the first dielectric layer 1630, and the second electrode 1620 can construct the pressure sensor module 253 and thus detect the pressure of the external object on the first surface 410a. For doing so, the control circuit 265 can apply a transmit signal to the second electrode 1620 and connect the first electrode 1610 to the GND. The control circuit 265 can detect a capacitance change of each individual electrode of the second electrode 1620 based on a thickness change of the first dielectric layer 1630, that is, based on a distance change between the first electrode 1610 and the second electrode 1620 according to the pressure of the external object.

Although the first electrode 1610 and the second electrode 1620 are sequentially deposited in, but not limited to, the second direction D2, the first electrode 1610 and the second electrode 1620 can be deposited in various orders.

According to various embodiments, the first dielectric layer 1630 can be interposed between the first electrode 1610 and the second electrode 1620. The first dielectric layer 1630, which has elasticity or resilience, can change in thickness according to the pressure of the external object. The first dielectric layer 1630 can include an insulating material.

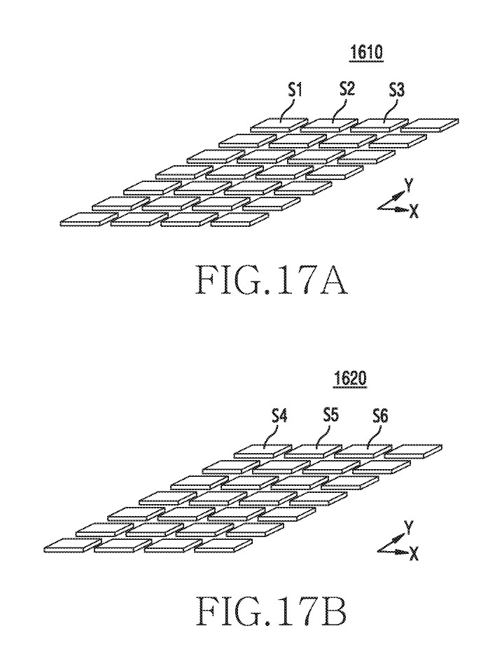

The first electrode 1610 and the second electrode 1620 can include individual electrodes, to be explained by referring to FIGS. 17A and 17B.

FIG. 17A is a perspective view of a first electrode in an electronic apparatus according to various embodiments of the present disclosure.

FIG. 17B is a perspective view of a second electrode in an electronic apparatus according to various embodiments of the present disclosure.

Referring to FIG. 17A, the first electrode 1610 can include individual electrodes S1, S2, and S3. The individual electrodes S1, S2, and S3 can be repeatedly arranged along the X axis and the Y axis. The individual electrodes S1, S2, and S3 can adopt various shapes such as a diamond, a triangle, a rectangle, a pentagon, a polygon, a circle, a bar, or a mesh. The number and the shape of the individual electrodes S1, S2, and S3 can vary.

Referring to FIG. 17B, the second electrode 1620 can include individual electrodes S4, S5, and S6. The individual electrodes S4, S5, and S6 can be repeatedly arranged along the X axis and the Y axis. The individual electrodes S4, S5, and S6 can adopt various shapes such as a diamond, a triangle, a rectangle, a pentagon, a polygon, a circle, a bar, or a mesh. The number and the shape of the individual electrodes S4, S5, and S6 can vary.

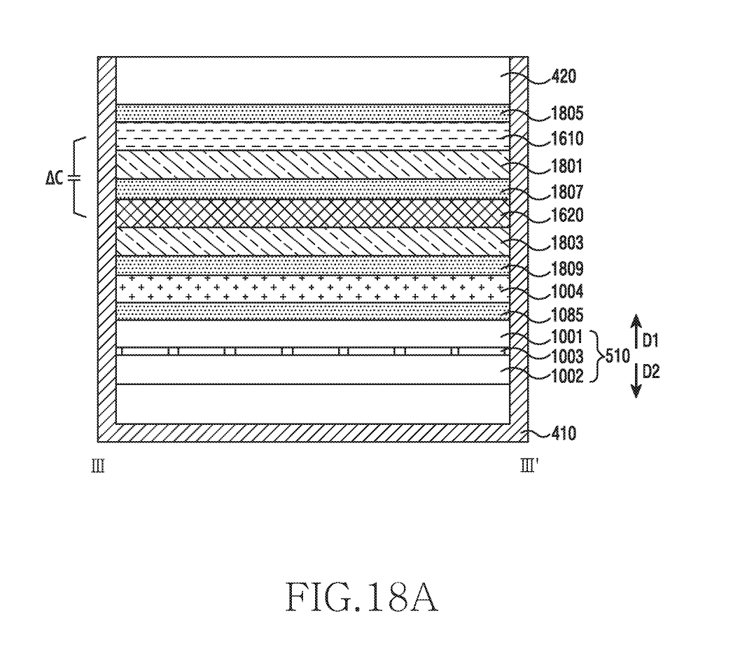

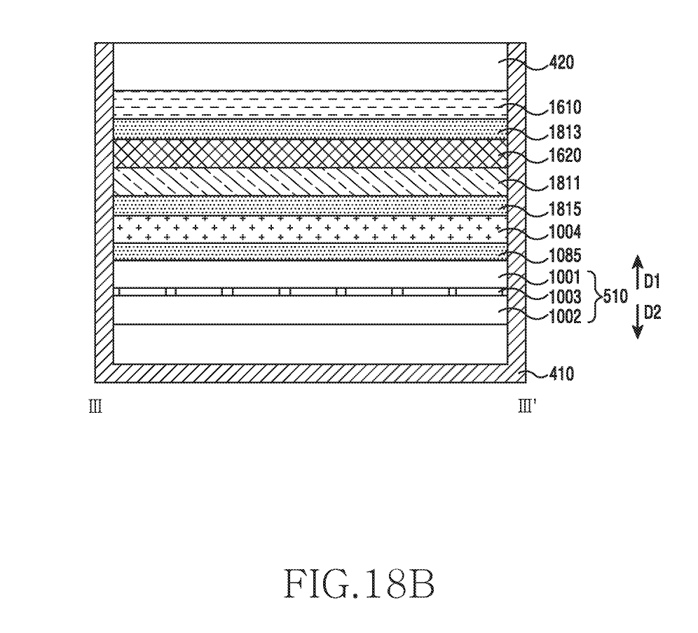

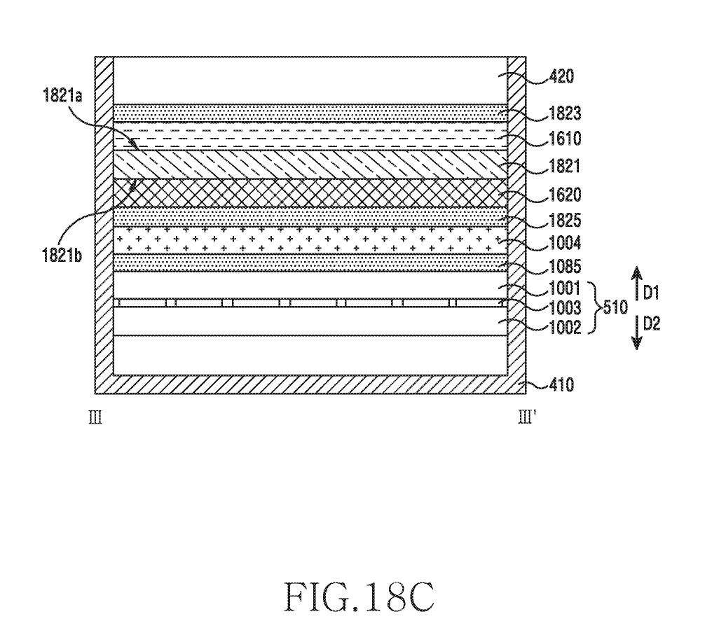

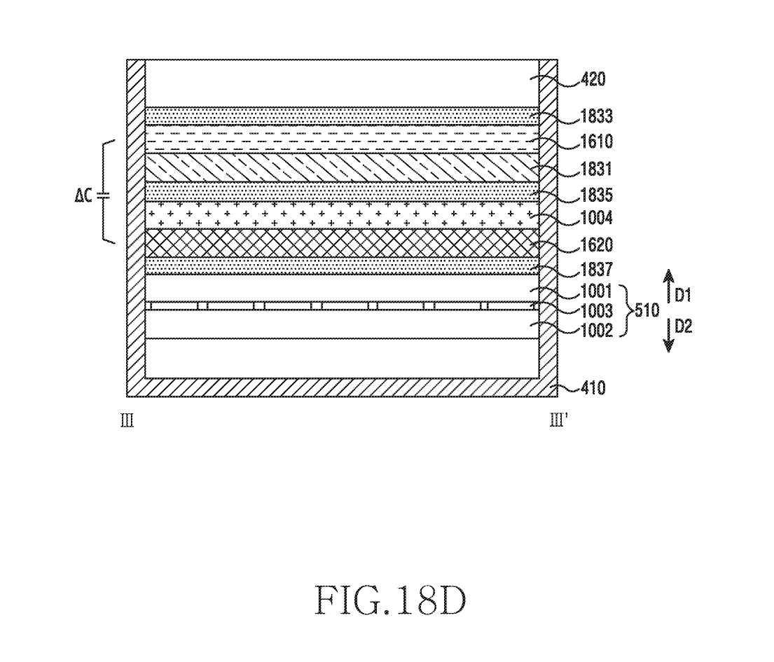

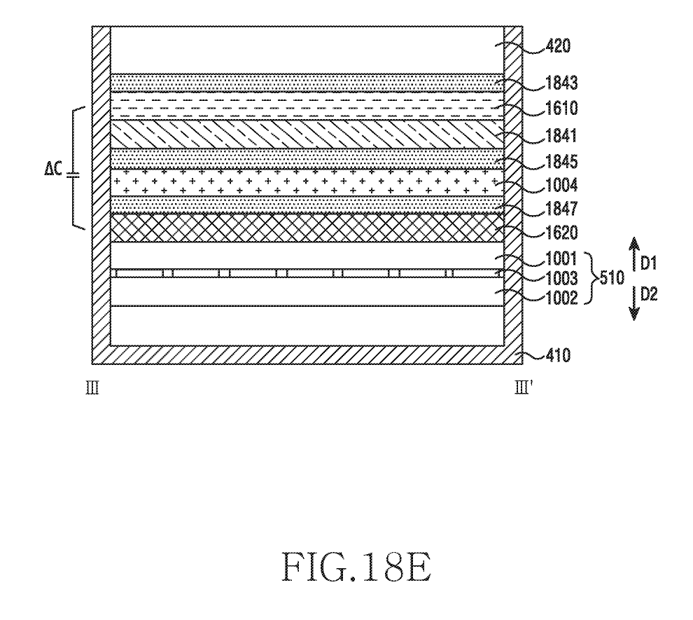

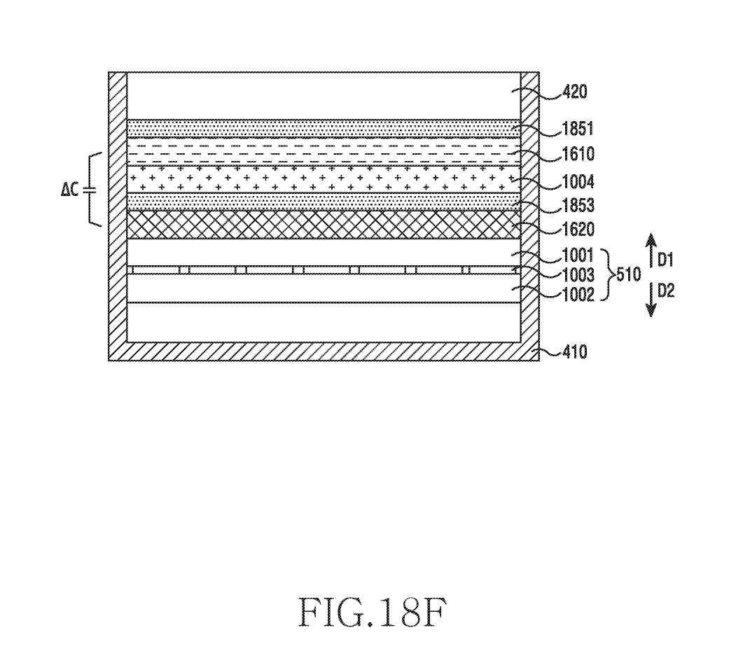

FIGS. 18A, 18B, 18C, 18D, 18E, and 18F are cross-sectional views taken along III-III′ of FIG. 16 according to various embodiments of the present disclosure.

Referring to FIG. 18A, the first electrode 1610 and the second electrode 1620 can be disposed between the transparent cover 420 and the display 510. The display 510 can include a first substrate 1001, a second substrate 1002, and liquid crystals 1003.

According to various embodiments, the first electrode 1610 can be formed on a first base material 1801. The second electrode 1620 can be formed on a second base material 1803. While the first electrode 1610 faces, but not limited to, the first direction D1 on the first base material 1801, it may face the second direction D2 which is opposite to the first direction D1. Alternatively, while the second electrode 1620 faces, but not limited to, the first direction D1 on the second base material 1803, it may face the second direction D2 which is opposite to the first direction D1.

According to various embodiments, the transparent cover 420, a first base material 1801 including the first electrode 1610, a second base material 1803 including the second electrode 1620, and the polarizing layer 1004 can be bonded together using bonding layers 1805, 1807, and 1809. For example, the transparent cover 420 and the first base material 1801 including the first electrode 1610 can be bonded together using the first bonding layer 1805. Alternatively, the first base material 1801 and the second base material 1803 can be bonded together using the second bonding layer 1807. Alternatively, the second base material 1803 including the second electrode 1620 can be bonded to the polarizing layer 1004 using the third bonding layer 1807.

According to various embodiments, at least one of the first base material 1801 and the second bonding layer 1807 can be the first dielectric layer 1630 of FIG. 16. That is, the first base material 1801 and/or second third bonding layer 1807 can insulate between the first electrode 1610 and the second electrode 1620 to detect a location of the touch of the external object. Alternatively, the first base material 1801 and/or second third bonding layer 1807 can insulate between the first electrode 1610 and the second electrode 1620 in order to detect the pressure of the external object. The first base material 1801 serving as the first dielectric layer 1240 can support the first electrode 1610. Alternatively, the second bonding layer 1807 serving as the first dielectric layer 1240 can bond the first base material 1801 with the second base material 1803. The second bonding layer 1807 can include at least part of a different material from the first bonding layer 1805 or the third base material 1809. Alternatively, the second bonding layer 1807 can be, for example, thicker than the third first bonding layer 1805 or the third base material 1809.

Referring to FIG. 18B, the first electrode 1610 can be formed on the transparent cover 420. That is, the first electrode 1610 can be integrated with the transparent cover 420. The first electrode 1610 can face the second direction D2 on the transparent cover 420. The second electrode 1620 can be formed on the first base material 1811.

According to various embodiments, the transparent cover 420 including the first electrode 1610, the first base material 1811 including the second electrode 1620, and the polarizing layer 1004 can be bonded together using bonding layers 1813 and 1815. For example, the transparent cover 420 including the first electrode 1610 can be bonded to the first base material 1811 including the second electrode 1620 using the first bonding layer 1813. Alternatively, the first base material 1811 including the second electrode 1620 can be bonded to the polarizing layer 1004 using the second bonding layer 1815,

According to various embodiments, the first bonding layer 1813 can be the first dielectric layer 1630 of FIG. 16. That is, the first bonding layer 1813 can insulate between the first electrode 1610 and the second electrode 1620 in order to detect a location of the touch of the external object. Alternatively, the first bonding layer 1813 serving as the first dielectric layer 1240 can insulate between the first electrode 1610 and the second electrode 1620 in order to detect the pressure of the external object. Alternatively, the first bonding layer 1813 serving as the first dielectric layer 1240 can bond the transparent cover 420 and the first base material 1811. The first bonding layer 1813 can include at least part of a different material from the second bonding layer 1815. Alternatively, the first bonding layer 1813 can be, for example, thicker than the second bonding layer 1815.

Referring to FIG. 18C, the first electrode 1610 and the second electrode 1620 can be formed on a first base material 1821. The first electrode 1610 and the second electrode 1620 can be formed on either surface of the first base material 1821. That is, the first electrode 1610 can be formed on a first surface 1821a of the first base material 1821, and the second electrode 1620 can be formed on a second surface 1821b which is opposite to the first surface 1821a. The first electrode 1610 and the second electrode 1620 can be formed on the same base material.

According to various embodiments, the transparent cover 420, the first base material 1821, and the polarizing layer 1004 can be bonded together using bonding layers 1823 and 1825. For example, the transparent cover 420 and the first base material 1821 can be bonded together using the first bonding layer 1823. Alternatively, the first base material 1821 and the polarizing layer 1004 can be bonded together using the second bonding layer 1825.

According to various embodiments, the first bonding layer 1821 can be the first dielectric layer 1630 of FIG. 16. That is, the first bonding layer 1821 can insulate between the first electrode 1610 and the second electrode 1620 in order to detect a location of the touch of the external object. Alternatively, the first bonding layer 1821 can insulate between the first electrode 1610 and the second electrode 1620 in order to detect the pressure of the external object. Alternatively, the first bonding layer 1821 serving as the first dielectric layer 1240 can support the first electrode 1610 and the second electrode 1620.

Referring to FIG. 18D, the first electrode 1610 can be formed on a first base material 1831. The second electrode 1620 can be formed on the polarizing layer 1004. While the first electrode 1610 faces, but not limited to, the first direction D1 on the first base material 1831, it may face the second direction D2 which is opposite to the first direction D1. Alternatively, while the second electrode 1620 faces, but not limited to, the second direction D2 on the polarizing layer 1004, it may face the first direction D1 which is opposite to the second direction D2.

According to various embodiments, the transparent cover 420, the first base material 1831 including the first electrode 1610, the polarizing layer 1004 including the second electrode 1620, and the display 510 can be bonded together using bonding layers 1833, 1835, and 1837. For example, the transparent cover 420 can be bonded to the first base material 1831 including the first electrode 1610 using the first bonding layer 1833. Alternatively, the first base material 1831 and the polarizing layer 1004 can be bonded together using the second bonding layer 1835. Alternatively, the polarizing layer 1004 and the display 510 can be bonded together using the third bonding layer 1837.

According to various embodiments, at least one of the first base material 1831, the second bonding layer 1835, and the polarizing layer 1004 can be the first dielectric layer 1630 of FIG. 16. That is, at least one of the first base material 1831, the second bonding layer 1835, and the polarizing layer 1004 can insulate between the first electrode 1610 and the second electrode 1620 to detect a location of the touch of the external object. Alternatively, at least one of the first base material 1831, the second bonding layer 1835, and the polarizing layer 1004 can insulate between the first electrode 1610 and the second electrode 1620 in order to detect the pressure of the external object.

Referring to FIG. 18E, the first electrode 1610 can be formed on a first base material 1841. The second electrode 1620 can be formed on the display 510. For example, the second electrode 1620 can be formed on the first substrate 1001 of the display 510.

According to various embodiments, the transparent cover 420, the first base material 1841 including the first electrode 1610, the polarizing layer 1004, and the display 510 can be bonded together using bonding layers 1843, 1845, and 1847. For example, the transparent cover 420 can be bonded to the first base material 1841 including the first electrode 1610 using the first bonding layer 1843. Alternatively, the first base material 1841 and the polarizing layer 1004 can be bonded together using the second bonding layer 1845. Alternatively, the polarizing layer 1004 and the display 510 including the second electrode 1620 can be bonded together using the third bonding layer 1847.

According to various embodiments, at least one of the first base material 1841, the second bonding layer 1845, the polarizing layer 1004, and the third bonding layer 1847 can be the first dielectric layer 1630 of FIG. 16. That is, at least one of the first base material 1841, the second bonding layer 1845, the polarizing layer 1004, and the third bonding layer 1847 can insulate between the first electrode 1610 and the second electrode 1620 to detect a location of the touch of the external object. Alternatively, at least one of the first base material 1841, the second bonding layer 1845, the polarizing layer 1004, and the third bonding layer 1847 can insulate between the first electrode 1610 and the second electrode 1620 in order to detect the pressure of the external object.

Referring to FIG. 18F, the first electrode 1610 can be formed on the polarizing layer 1004. The second electrode 1620 can be formed on the display 510. For example, the second electrode 1620 can be formed on the first substrate 1001 of the display 510.

According to various embodiments, the transparent cover 420, the polarizing layer 1004 including the first electrode 1610, and the display 510 can be bonded together using bonding layers 1851 and 1853. For example, the transparent cover 420 can be bonded to the polarizing layer 1004 including the first electrode 1610 using the first bonding layer 1851. Alternatively, the polarizing layer 1004 and the display 510 can be bonded together using the second bonding layer 1853.

According to various embodiments, at least one of the polarizing layer 1004 and the second bonding layer 1853 can be the first dielectric layer 1630 of FIG. 16. That is, the polarizing layer 1004 and/or the second bonding layer 1853 can insulate between the first electrode 1610 and the second electrode 1620 to detect a location of the touch of the external object. Alternatively, the polarizing layer 1004 and/or the second bonding layer 1853 can insulate between the first electrode 1610 and the second electrode 1620 in order to detect the pressure of the external object.

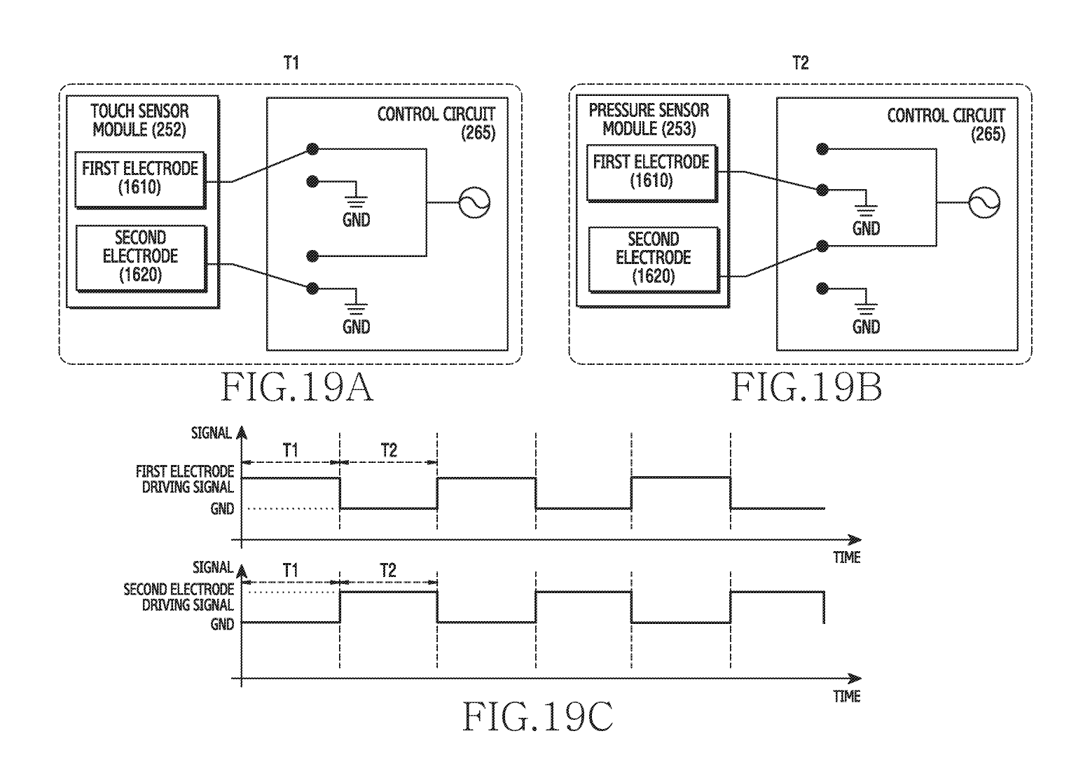

FIGS. 19A and 19B are block diagrams of an electronic apparatus according to various embodiments of the present disclosure.

FIG. 19C is graphs illustrating driving of an electronic apparatus according to various embodiments of the present disclosure.

Referring to FIG. 19A, the control circuit 265 can drive the first electrode 1610 and the second electrode 1620 as the touch sensor module 252 for first time periods T1. In the first time periods T1, the control circuit 265 can apply a driving signal to the first electrode 1610 and connect the second electrode 1620 to the GND. In the first time periods T1, the control circuit 265 can detect a capacitance change of each individual electrode of the first electrode 1610 according to the touch of the external object.

Referring to FIG. 19B, the control circuit 265 can drive the first electrode 1610 and the second electrode 1620 as the pressure sensor module 253 for second time periods T2. In the second time periods T2, the control circuit 265 can apply a driving signal to the second electrode 1620 and connect the first electrode 1610 to the GND. In the second time periods T2, the control circuit 265 can detect a capacitance change of each individual electrode of the second electrode 1620 according to a distance change between the first electrode 1610 and the second electrode 1620 based on the pressure of the external object.

Referring to FIG. 19C, the control circuit 265 can drive the touch sensor module 252 and the pressure sensor module 253 based on time division. The control circuit 265 can drive the first electrode 1610 and the second electrode 1620 based on the time division. The control circuit 265 can apply a driving signal to the first electrode 1610 and the second electrode 1620 in sequence. The control circuit 265 can sequentially connect the first electrode 1610 and the second electrode 1620 to the GND. For example, in the first time periods T1, the control circuit 265 can apply a driving signal to the first electrode 1610 and connect the second electrode 1620 to the GND. In the first time periods T1, the control circuit 265 can receive a receive signal based on the touch location of the external object through the first electrode 1610. Alternatively, in the second time periods T2, the control circuit 265 can apply the driving signal to the first electrode 1610 and connect the first electrode 1610 to the GND. In the second time periods T2, the control circuit 265 can receive a receive signal based on the pressure of the external object through the second electrode 1620. The second time periods T2 may not overlap at least part of the first time periods T1.

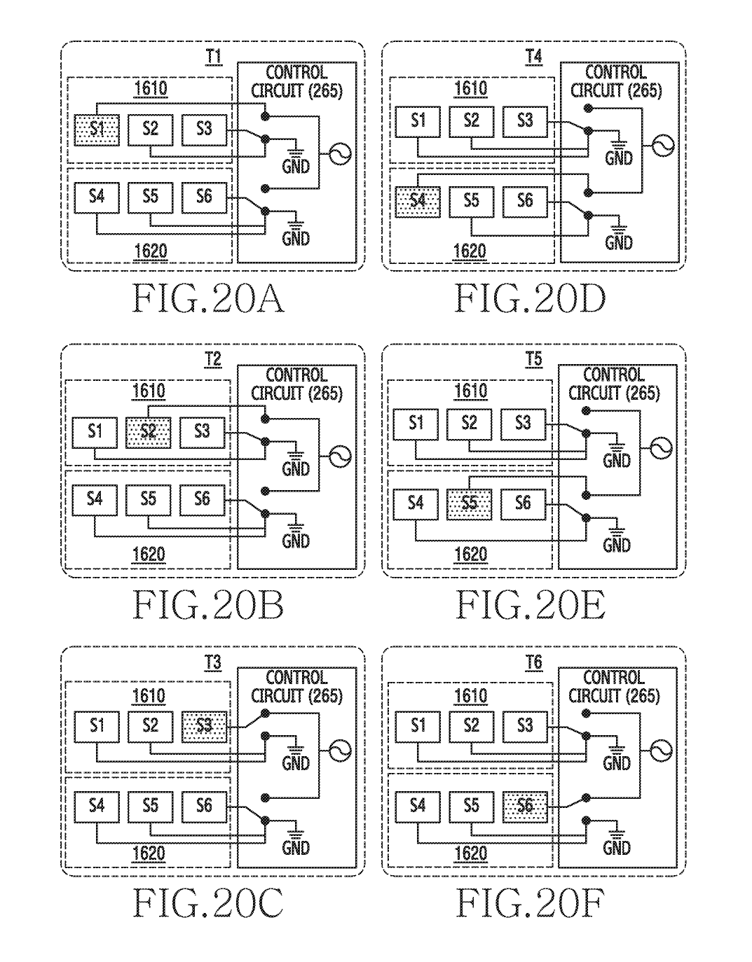

FIGS. 20A, 20B, 20C, 20D, 20E, and 20F are block diagrams of an electronic apparatus according to various embodiments of the present disclosure.

Referring to FIG. 20A, the control circuit 265 can drive individual electrodes S1, S2, and S3 of the first electrode 1610 and individual electrodes S4, S5, and S6 of the second electrode 1620. The control circuit 265 can apply a driving signal to at least one of the individual electrodes S1, S2, and S3 of the first electrode 1610 and the individual electrodes S4, S5, and S6 of the second electrode 1620, and connect the other electrodes to the GND. The control circuit 265 can drive the individual electrodes S1, S2, and S3 of the first electrode 1610 and the individual electrodes S4, S5, and S6 of the second electrode 1620 based on the time division. The control circuit 265 can sequentially apply the driving signal to the individual electrodes S1, S2, and S3 of the first electrode 1610 and the individual electrodes S4, S5, and 56 of the second electrode 1620. For example, in first time periods T1, the control circuit 265 can apply the driving signal to the first individual electrode S1 of the first electrode 1610 and connect the other electrodes S2 through S6 to the GND.

Referring to FIG. 2013, in second time periods T2, the control circuit 265 can apply the driving signal to the second individual electrode S2 of the first electrode 1610 and connect the other electrodes S1 and S3 through S6 to the GND. The second time periods T2 may not overlap at least part of the first time periods T1,

Referring to FIG. 20C, in third second periods T3, the control circuit 265 can apply the driving signal to the third individual electrode S3 of the first electrode 1610 and connect the other electrodes S1, S2, S4, S5 and S6 to the GND. The third time periods T3 may not overlap at least part of the second time periods T2.

Referring to FIG. 20D, in fourth second periods T4, the control circuit 265 can apply the driving signal to the fourth individual electrode S4 of the second electrode 1620 and connect the other electrodes S1, S2, S3, S5 and S6 to the GND. The fourth time periods T4 may not overlap at least part of the third time periods T3.

Referring to FIG. 20E, in fifth second periods T5, the control circuit 265 can apply the driving signal to the fifth individual electrode S5 of the second electrode 1620 and connect the other electrodes S1, S2, S3, S4 and S6 to the GND. The fifth time periods T5 may not overlap at least part of the fourth time periods T1.

Referring to FIG. 20F, in sixth second periods T6, the control circuit 265 can apply the driving signal to the sixth individual electrode S6 of the second electrode 1620 and connect the other electrodes S1 through S5 to the GND. The sixth time periods T6 may not overlap at least part of the fifth time periods T5.

While the control circuit 265 applies the driving signal to, but not limited to, each of the individual electrodes in FIGS. 20A through 20F, the control circuit 265 may group the individual electrodes of the first electrode 1610 and the second electrode 1620, apply the driving signal to the groups in sequence, and connect the other groups to the GND.

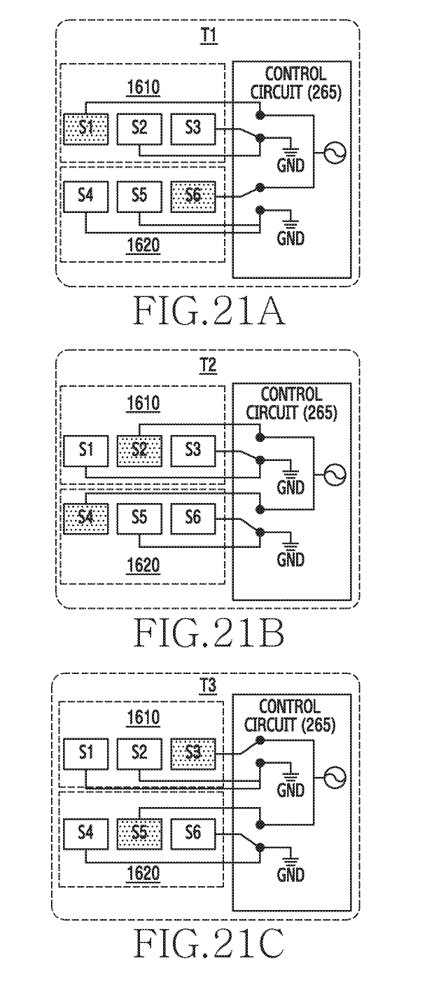

FIGS. 21A, 21B, and 21C are block diagrams of an electronic apparatus according to various embodiments of the present disclosure.

Referring to FIG. 21A, the control circuit 265 can drive individual electrodes S1, S2, and S3 of the first electrode 1610 and individual electrodes S4, S5, and S6 of the second electrode 1620. The control circuit 265 can apply a driving signal to at least two of the individual electrodes S1, S2, and S3 of the first electrode 1610 and the individual electrodes S4, S5, and S6 of the second electrode 1620, and connect the other electrodes to the GND. The control circuit 265 can apply a driving signal to any one of the individual electrodes S1, S2, and S3 of the first electrode 1610 and any one of the individual electrodes S4, S5, and S6 of the second electrode 1620, and connect the other electrodes to the GND. For example, in first time periods the control circuit 265 can apply the driving signal to the first individual electrode S1 of the first electrode 1610 and the sixth individual electrode SO of the second electrode 1620, and connect the other electrodes S2 through S5 to the GND.

Referring to FIG. 21B, in second time periods T2, the control circuit 265 can apply the driving signal to the second individual electrode S2 of the first electrode 1610 and the fourth individual electrode S4 of the second electrode 1620, and connect the other electrodes S1, S3, S5, and S6 to the GND. The second time periods T2 may not overlap at least part of the first time periods T1.

Referring to FIG. 21C, in third second periods T3, the control circuit 265 can apply the driving signal to the third individual electrode S3 of the first electrode 1610 and the fifth individual electrode S5 of the second electrode 1620, and connect the other electrodes S1, S2, S4, and S6 to the GND. The third time periods T3 may not overlap at least part of the second time periods T2.

While the control circuit 265 applies the driving signal to, but not limited to, each of the individual electrodes in FIGS. 21A, 21B, and 21C, the control circuit 265 may group the individual electrodes of the first electrode 1610 and the second electrode 1620, apply the driving signal to the groups in sequence, and connect the other groups to the GNU.

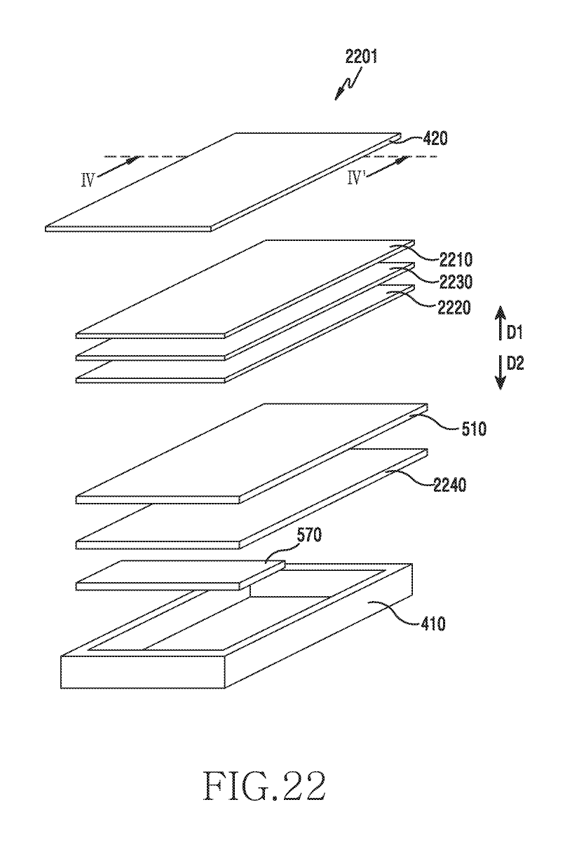

FIG. 22 is an exploded view of an electronic apparatus according to various embodiments of the present disclosure.

Referring to FIG. 22, an electronic device 2201 can include a housing 410, a transparent cover 420, a display 510, a first electrode 2210, a second electrode 2220, a first dielectric layer 2230, a third electrode 2240, and a haptic actuator 570. The same or similar components to those shown in FIG. 5 shall be omitted here.

According to various embodiments, the first electrode 2210, the first dielectric layer 2230, and the second electrode 2220 can be disposed between the transparent cover 420 and the display 510. The first electrode 2210 and the second electrode 2220 can include individual electrodes. For example, the first electrode 2210 and the second electrode 2220 can include the plurality of the individual electrodes as described in FIGS. 17A and 17B.

According to various embodiments, a third electrode 2240 can be disposed in a second direction D2 of the display 510. As the display 510 is interposed between the second electrode 2220 and the third electrode 2240, the display 510 can serve as a dielectric layer for detecting the pressure.

According to various embodiments, the first electrode 2210 and the third electrode 2240 can construct the touch sensor module 252 and thus detect a location of the touch of the external object on the first surface 410a. For doing so, the control circuit 265 can apply a transmit signal to the first electrode 2210 and connect the third electrode 2240 to the GM). The control circuit 265 can detect a capacitance change of each individual electrode of the first electrode 2210 according to the touch of the external object.

According to various embodiments, the second electrode 2220 and the third electrode 2240 can construct the pressure sensor module 253 and thus detect the pressure of the external object on the first surface 410a. For doing so, the control circuit 265 can apply a transmit signal to the second electrode 2220 and connect the third electrode 2240 to the GND. The control circuit 265 can detect a capacitance change of each individual electrode of the second electrode 2220 based on a distance change between the second electrode 2220 and the third electrode 2240 according to the pressure of the external object.

Although the first electrode 2210 and the second electrode 2220 are sequentially deposited in, but not limited to, the second direction D2, the first electrode 2210 and the second electrode 2220 can be deposited in various orders.

FIGS, 23A, 23B, 23C, 23D, 23E, and 23F are cross-sectional views taken along IV-VI′ of FIG. 22 according to various embodiments of the present disclosure.

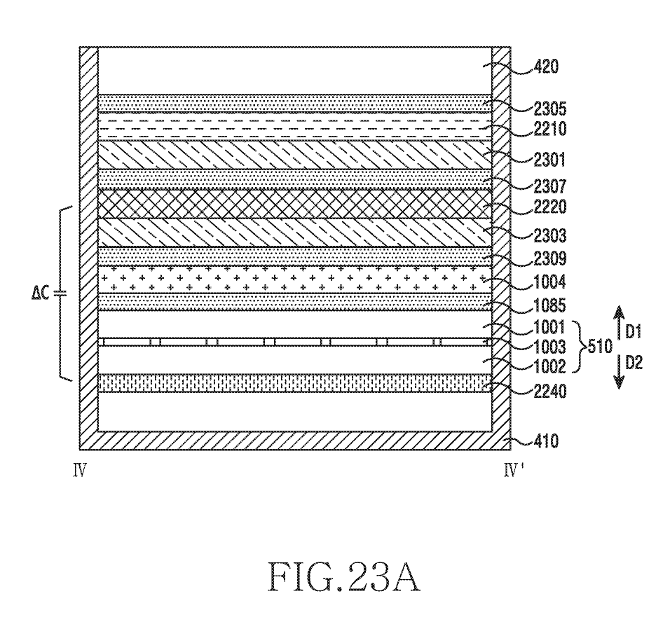

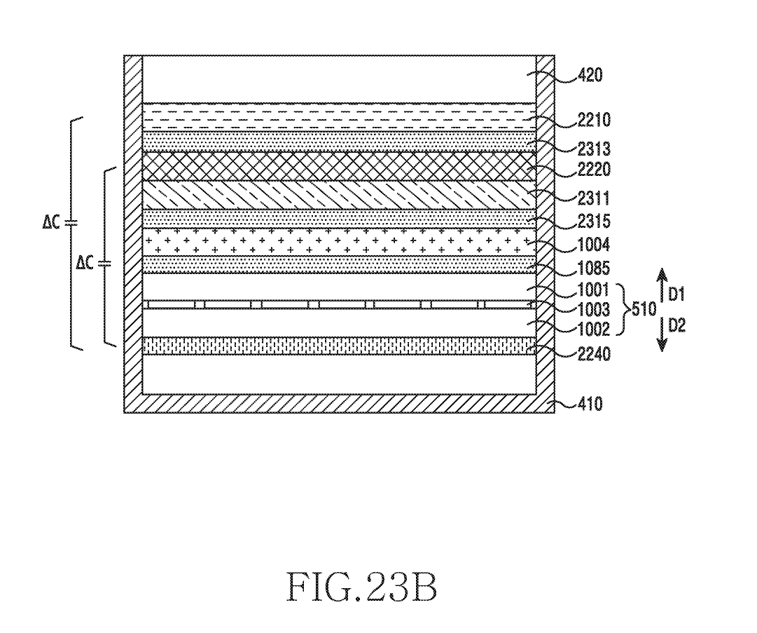

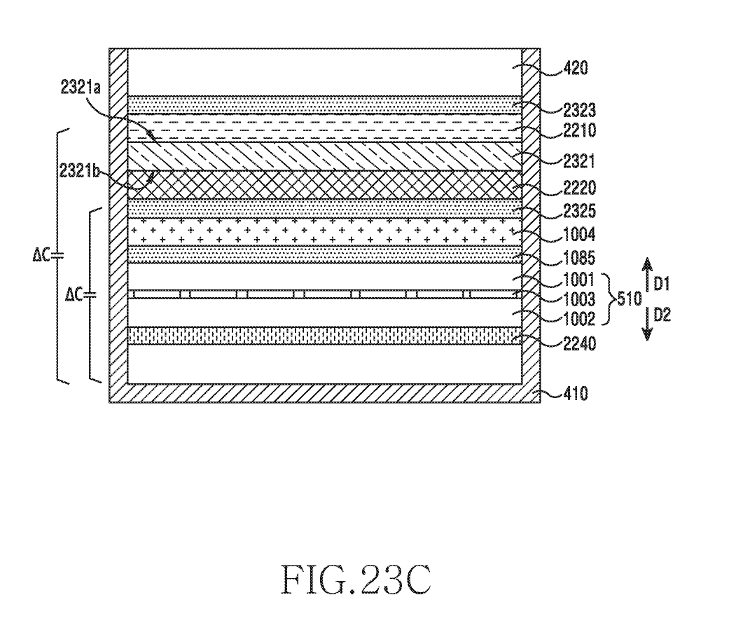

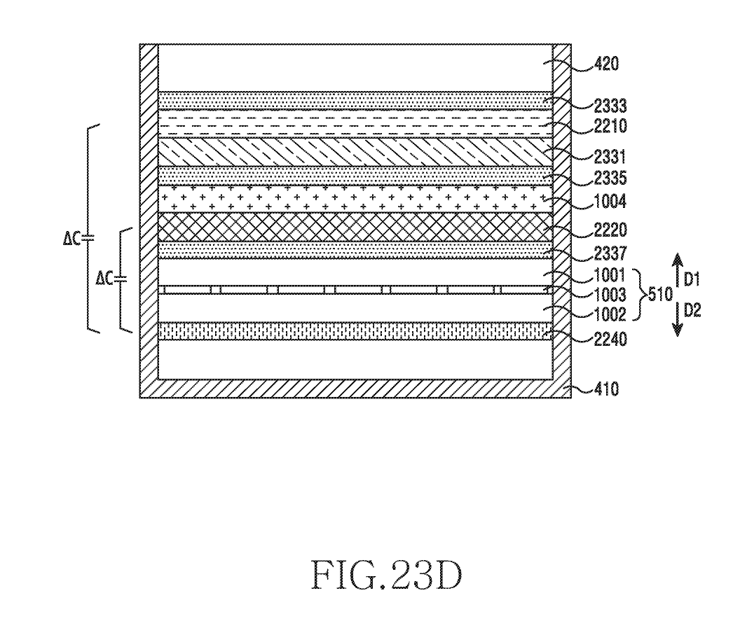

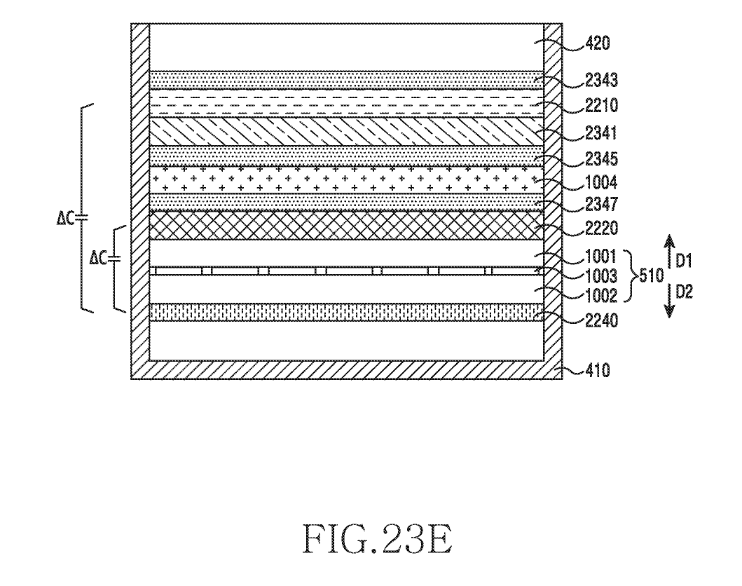

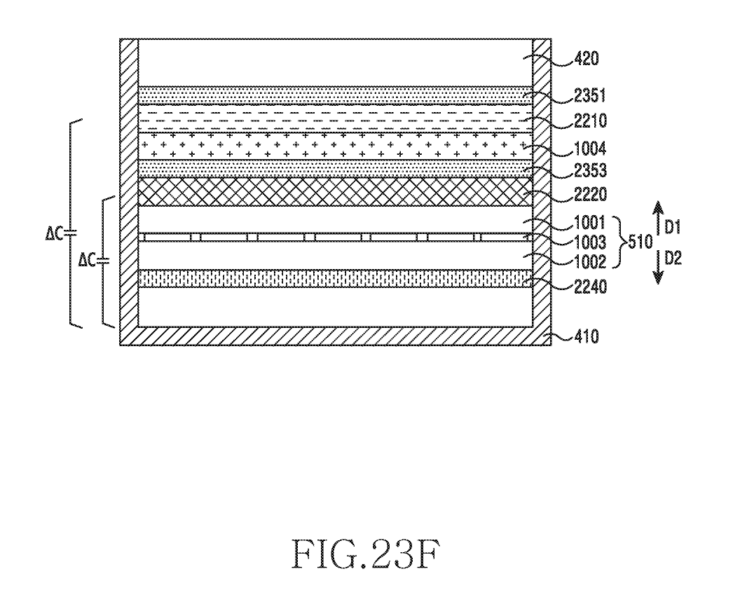

Referring to FIG. 23A, the first electrode 2210 and the second electrode 2220 can be disposed between the transparent cover 420 and the display 510. The display 510 can include a first substrate 1001, a second substrate 1002, and liquid crystals 1003.

According to various embodiments, the first electrode 2210 can be formed on a first base material 2301. The second electrode 2220 can be formed on a second base material 2303. The third electrode 2240 can be formed on the display 510. For example, the third electrode 2240 can be formed on the second substrate 1002 of the display 510. Although the first electrode 2210 faces, but not limited to, the first direction D1 on the first base material 2301, it may face the second direction D2 which is opposite to the first direction D1. Alternatively, although the second electrode 2220 faces, but not limited to, the first direction D1 on the second base material 2303, it may face the second direction D2 which is opposite to the first direction D1.

According to various embodiments, the transparent cover 420, the first base material 2301 including the first electrode 2210, the second base material 2303 including the second electrode 2220, and the polarizing layer 1004 can be bonded together using bonding layers 2305, 2307, and 2309. For example, the transparent cover 420 and the first base material 2301 including the first electrode 2210 can be bonded together using the first bonding layer 2305. Alternatively, the first base material 2301 including the first electrode 2210 can be bonded to the second base material 2303 including the second electrode 2220 using the second bonding layer 2307. Alternatively, the second base material 2303 including the second electrode 2220 can be bonded to the polarizing layer 1004 using the third bonding layer 2309.

According to various embodiments, at least one of the first base material 2301 and the second bonding layer 2307 can be the first dielectric layer 2230 of FIG. 22. That is, the first base material 2301 and/or the second bonding layer 2307 can insulate between the first electrode 2210 and the second electrode 2220. At least one of the second base material 2303, the third bonding layer 2309, the polarizing layer 1004, and the display 510 can serve as a dielectric layer for detecting the pressure of the second electrode 2220 and the third electrode 2240.

Referring to FIG. 23B, the first electrode 2210 can be formed on the transparent cover 420. That is, the first electrode 2210 can be integrated with the transparent cover 420. The first electrode 2210 can face the second direction D2 on the transparent cover 420. The second electrode 2220 can be formed on a first base material 2311. The third electrode 2240 can be formed on the display 510. For example, the third electrode 2240 can be formed on the second substrate 1002 of the display 510.

According to various embodiments, the transparent cover 420 including the first electrode 2210, the first base material 2311 including the second electrode 2220, and the polarizing layer 1004 can be bonded together using bonding layers 2313 and 2315. For example, the transparent cover 420 including the first electrode 2210 can be bonded to the first base material 2311 including the second electrode 2220 using the first bonding layer 2313. Alternatively, the first base material 2311 including the second electrode 2220 can be bonded to the polarizing layer 1004 using the second bonding layer 2315.

According to various embodiments, the first bonding layer 2313 can be the first dielectric layer 2230 of FIG. 22. That is, the first bonding layer 2313 can insulate between the first electrode 2210 and the second electrode 2220. The first bonding layer 2313 serving as the first dielectric layer 2230 can bond the transparent cover 420 and the first base material 2311. At least one of the first base material 2311, the second bonding layer 2315, the polarizing layer 1004, and the display 510 can serve as a dielectric layer for detecting the pressure of the second electrode 2220 and the third electrode 2240.

Referring to FIG. 23C, the first electrode 2210 and the second electrode 2220 can be formed on a first base material 2321. The first electrode 2210 and the second electrode 2220 can be formed on either surface of the first base material 2321. That is, the first electrode 2210 can be formed on a first surface 2321a of the first base material 2321, and the second electrode 2220 can be formed on a second surface 2321b which is opposite to the first surface 2321a. The first electrode 2210 and the second electrode 2220 can be formed on the same base material. For example, the third electrode 2240 can be formed on the second substrate 1002 of the display 510.

According to various embodiments, the transparent cover 420, the first base material 2321, and the polarizing layer 1004 can be bonded together using bonding layers 2323 and 2325. For example, the transparent cover 420 and the first base material 2321 can be bonded together using the first bonding layer 2323. Alternatively, the first base material 2321 and the polarizing layer 1004 can be bonded together using the second bonding layer 2325.

According to various embodiments, the first bonding layer 2321 can be the first dielectric layer 2230 of FIG. 22. That is, the first bonding layer 2321 can insulate between the first electrode 2210 and the second electrode 2220. The first bonding layer 2321 serving as the first dielectric layer 2230 can support the first electrode 2210 and the second electrode 2220. At least one of the second bonding layer 2325, the polarizing layer 1004, and the display 510 can serve as a dielectric layer for detecting the pressure between the second electrode 2220 and the third electrode 2240.

Referring to FIG. 23D, the first electrode 2210 can be formed on a first base material 2331. The second electrode 2220 can be formed on the polarizing layer 1004. The third electrode 2240 can be formed on the display 510. For example, the third electrode 2240 can be formed on the second substrate 1002 of the display 510. While the first electrode 2210 faces, but not limited to, the first direction D1 on the first base material 2331, it may face the second direction D2 which is opposite to the first direction D1. Alternatively, while the second electrode 2220 faces, but not limited to, the second direction D2 on the polarizing layer 1004, it may face the first direction D1 which is opposite to the second direction D2.

According to various embodiments, the transparent cover 420, the first base material 2331 including the first electrode 2210, the polarizing layer 1004 including the second electrode 2220, and the display 510 can be bonded together using bonding layers 2333, 2335, and 2337. For example, the transparent cover 420 can be bonded to the first base material 2331 including the first electrode 2210 using the first bonding layer 2333. Alternatively, the first base material 2331 and the polarizing layer 1004 can be bonded together using the second bonding layer 2335. Alternatively, the polarizing layer 1004 and the display 510 can be bonded together using the third bonding layer 2337.

According to various embodiments, at least one of the first base material 2331, the second bonding layer 2335, and the polarizing layer 1004 can be the first dielectric layer 2230 of FIG. 22. That is, at least one of the first base material 2331, the second bonding layer 2335, and the polarizing layer 1004 can insulate between the first electrode 2210 and the second electrode 2220. Alternatively, at least one of the third bonding layer 2337 and the display 510 can serve as a dielectric layer for detecting the pressure between the second electrode 2220 and the third electrode 2240.

Referring to FIG. 23E, the first electrode 2210 can be formed on a first base material 2341. The second electrode 2220 can be formed on the display 510. For example, the second electrode 2220 can be formed on the first substrate 1001 of the display 510. The third electrode 2240 can be formed on the display 510. For example, the third electrode 2240 can be formed on the second substrate 1002 of the display 510.

According to various embodiments, the transparent cover 420, the first base material 2341 including the first electrode 2210, the polarizing layer 1004, and the display 510 can be bonded together using bonding layers 2343, 2345, and 2347. For example, the transparent cover 420 can be bonded to the first base material 2341 including the first electrode 2210 using the first bonding layer 2343. Alternatively, the first base material 2341 and the polarizing layer 1004 can be bonded together using the second bonding layer 2345. Alternatively, the polarizing layer 1004 can be bonded to the display 510 including the second electrode 2220 and the third electrode 2240 can be bonded together using the third bonding layer 2347.

According to various embodiments, at least one of the first base material 2341, the second bonding layer 2345, the polarizing layer 1004, and the third bonding layer 2347 can be the first dielectric layer 2230 of FIG. 22. That is, at least one of the first base material 2341, the second bonding layer 2345, the polarizing layer 1004, and the third bonding layer 2347 can insulate between the first electrode 2210 and the second electrode 2220. Alternatively, the display 510 can serve as a dielectric layer for detecting the pressure between the second electrode 2220 and the third electrode 2240.

Referring to FIG. 23F, the first electrode 2210 can he formed on the polarizing layer 1004. The second electrode 2220 can be formed on the display 510. For example, the second electrode 2220 can be formed on the first substrate 1001 of the display 510. The third electrode 2240 can be formed on the display 510. For example, the third electrode 2240 can be formed on the second substrate 1002 of the display 510.

According to various embodiments, the transparent cover 420, the polarizing layer 1004 including the first electrode 2210, and the display 510 can be bonded together using bonding layers 2351 and 2353. For example, the transparent cover 420 can be bonded to the polarizing layer 1004 including the first electrode 2210 using the first bonding layer 2351. Alternatively, the polarizing layer 1004 and the display 510 can be bonded together using the second bonding layer 2353.

According to various embodiments, at least one of the polarizing layer 1004 and the second bonding layer 2353 can be the first dielectric layer 2230 of FIG. 22. That is, the polarizing layer 1004 and/or the second bonding layer 2353 can insulate between the first electrode 2210 and the second electrode 2220. Alternatively, the display 510 can serve as a dielectric layer for detecting the pressure between the second electrode 2220 and the third electrode 2240.

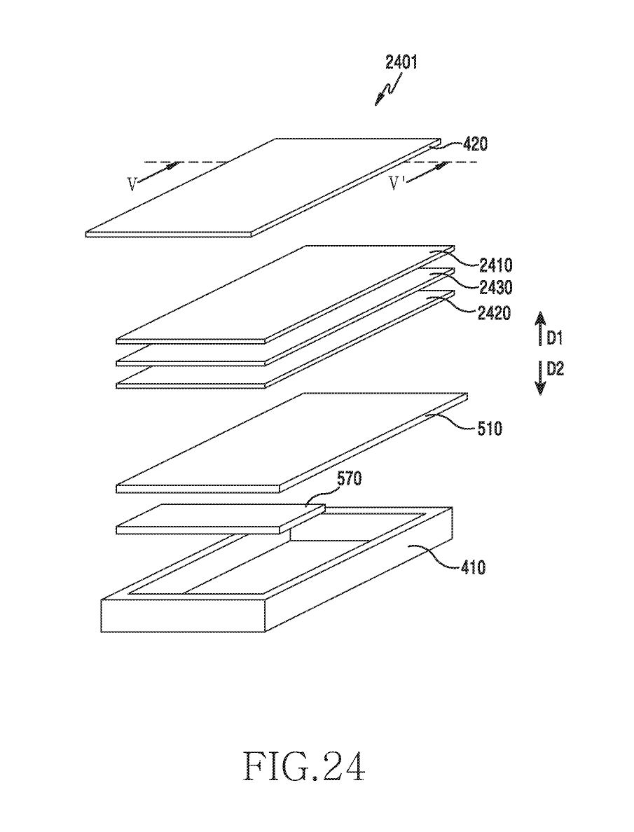

FIG. 24 is an exploded view of an electronic apparatus according to various embodiments of the present disclosure.

Referring to FIG. 24, an electronic device 2401 can include a housing 410, a transparent cover 420, a display 510, a first electrode 2410, a second electrode 2420, a first dielectric layer 2430, and a haptic actuator 570. The same or similar components to those shown in FIG. 5 shall be omitted here.

According to various embodiments, the first electrode 2410, the first dielectric layer 2430, and the second electrode 2420 can be disposed between the transparent cover 420 and the display 510. The first electrode 2410, the first dielectric layer 2430, and the second electrode 2420 can construct the touch sensor module 252 and/or the pressure sensor module 253 of FIG. 2. For example, the first electrode 2410, the first dielectric layer 2430, and the second electrode 2420 can construct the touch sensor module 252 and thus detect a location of a touch of an external object on a first surface 410a. For doing so, a control circuit 265 can apply a transmit signal for locating the touch to the first electrode 2410 and receive a receive signal corresponding to the transmit signal through the second electrode 2420. Alternatively, the control circuit 265 can apply a transmit signal for locating the touch to the second electrode 2420 and receive a receive signal corresponding to the transmit signal through the first electrode 2410. The control circuit 265 can detect a location of the touch by detecting a capacitance change between the first electrode 2410 and the second electrode 2420 according to the touch of the external object.

According to various embodiments, the first electrode 2410, the first dielectric layer 2430, and the second electrode 2420 can construct the pressure sensor module 253 and thus detect pressure of the external object on the first surface 410a. For doing so, the control circuit 265 can apply a transmit signal for detecting the pressure to the first electrode 2410, and receive a receive signal corresponding to the transmit signal through the second electrode 2420. Alternatively, the control circuit 265 can apply a transmit signal for detecting the pressure to the second electrode 2420 and receive a receive signal corresponding to the transmit signal through the first electrode 2410. The control circuit 265 can detect a capacitance change based on a thickness change of the first dielectric layer 2430, that is, based on a distance change between the first electrode 2410 and the second electrode 2420 according to the pressure of the external object.

Although the first electrode 2410 and the second electrode 2420 are sequentially deposited in, but not limited to, the second direction D2, the first electrode 2410 and the second electrode 2420 can be deposited in various orders.

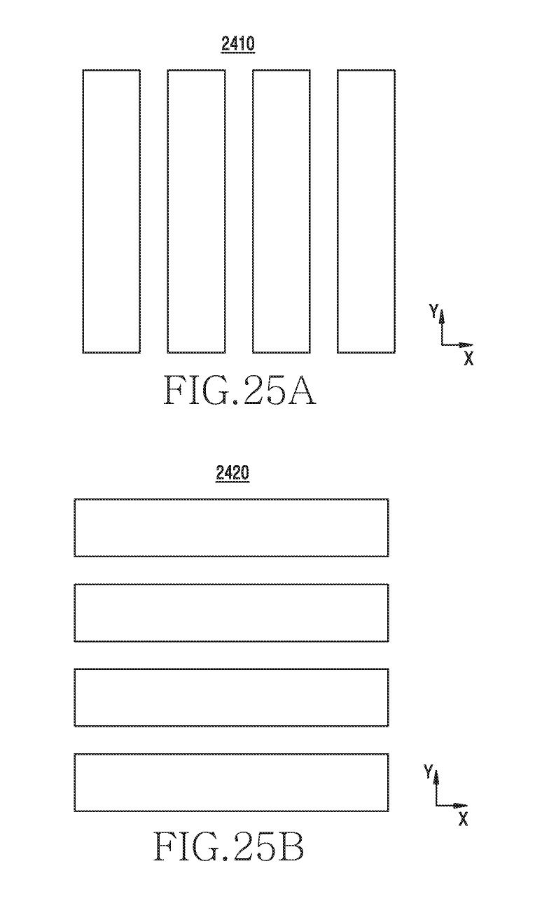

Meanwhile, the first electrode 2410 and the second electrode 2420 can have different patterns, to be explained by referring to FIG. 25.

FIG. 25A is a front view of a first electrode in an electronic apparatus according to various embodiments of the present disclosure.

FIG. 25B is a front view of a second electrode in an electronic apparatus according to various embodiments of the present disclosure.

Referring to FIG. 25A, the first electrode 2410 can include electrode patterns repeated along the X axis. For example, the first electrode 2410 can include one electrode pattern longitudinally formed along the Y axis. The one electrode pattern of the first electrode 2410 can include various shapes such as a diamond, a triangle, a rectangle, a pentagon, a polygon, a circle, a bar, or a mesh. The first electrode 2410 can include the one electrode pattern in various numbers and shapes.

Referring FIG. 25B, the second electrode 2420 can cross the first electrode 2410. The second electrode 2420 can include electrode patterns repeated along the Y axis. For example, the second electrode 2420 can include one electrode pattern longitudinally formed along the X axis. The one electrode pattern of the second electrode 2420 can include various shapes such as a diamond, a triangle, a rectangle, a pentagon, a polygon, a circle, a bar, or a mesh. The second electrode 2420 can include the one electrode pattern in various numbers and shapes.

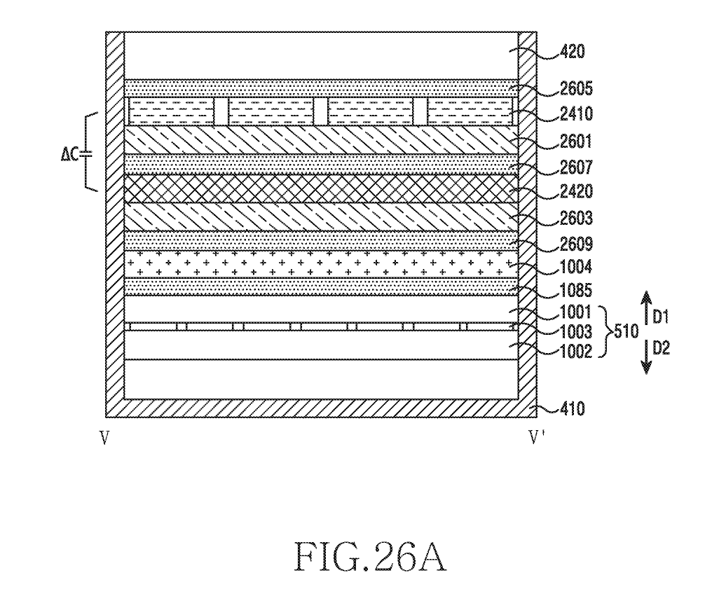

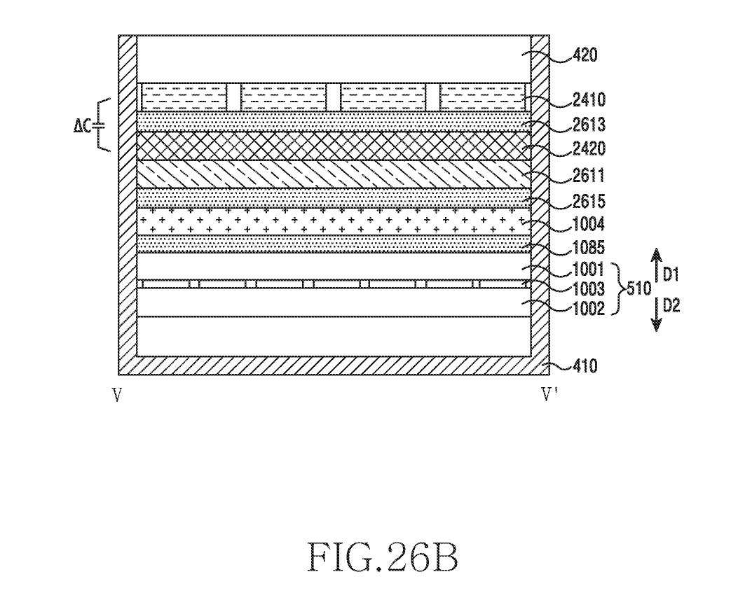

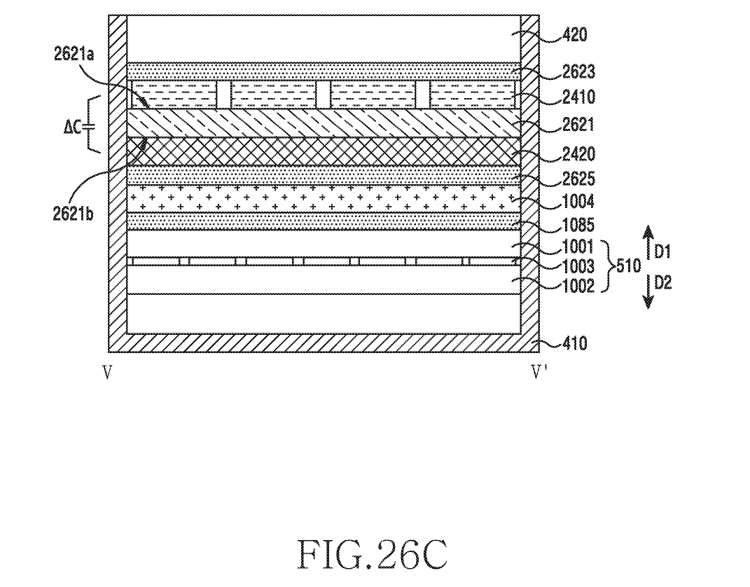

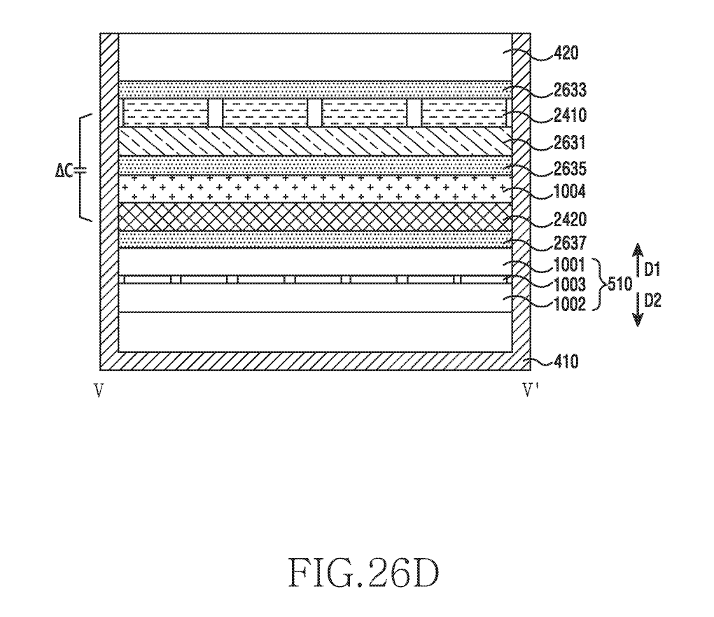

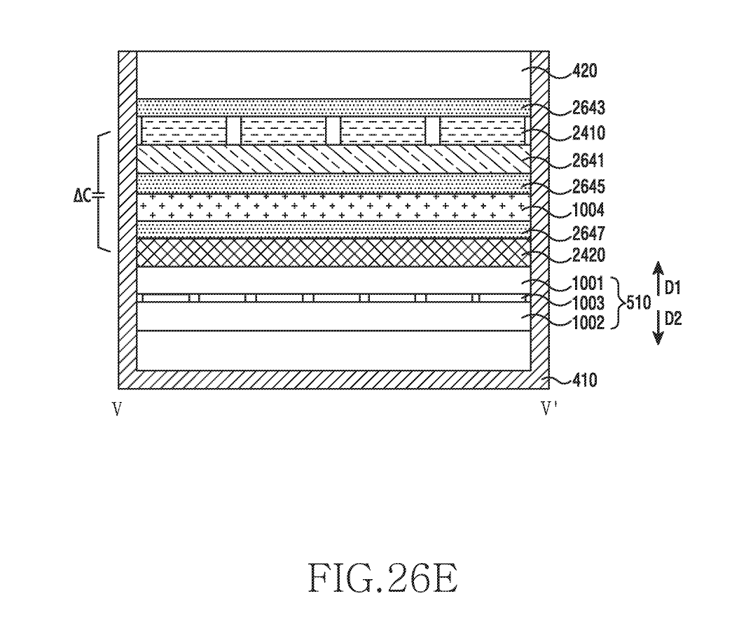

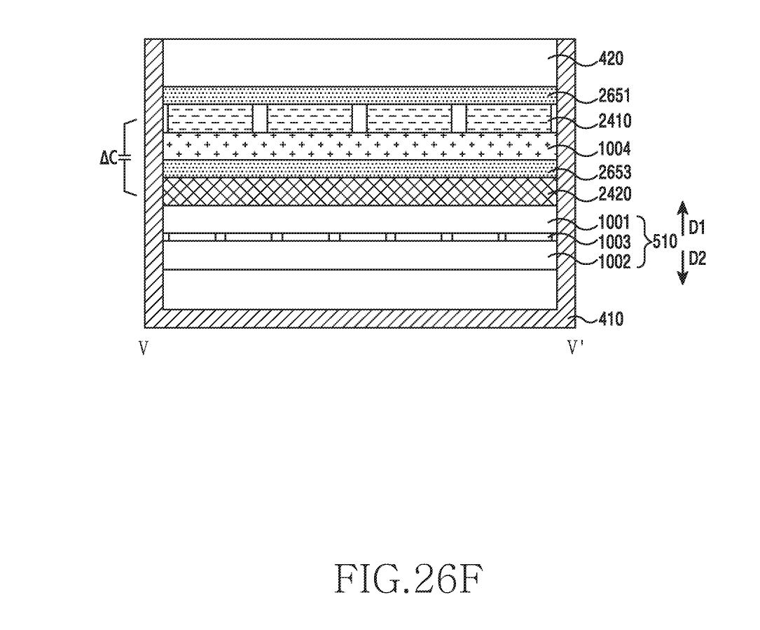

FIGS. 26A, 26B, 26C, 26D, 26E, and 26F are cross-sectional views taken along V-V′ of FIG. 24 according to various embodiments of the present disclosure.

Referring to FIG. 26A, the first electrode 2410 and the second electrode 2420 can be disposed between the transparent cover 420 and the display 510. The display 510 can include a first substrate 1001, a second substrate 1002, and liquid crystals 1003.

According to various embodiments, the first electrode 2410 can be formed on a first base material 2601. The second electrode 2420 can be formed on a second base material 2603. Although the first electrode 2410 faces, but not limited to, a first direction D1 on the first base material 2601, it may face a second direction D2 which is opposite to the first direction D1. Alternatively, although the second electrode 2420 faces, but not limited to, the first direction D1 on the second base material 2603, it may face the second direction D2 which is opposite to the first direction D1.

According to various embodiments, the transparent cover 420, the first base material 2601 including the first electrode 2410, the second base material 2603 including the second electrode 2420, and the polarizing layer 1004 can be bonded together using bonding layers 2605, 2607, and 2609. For example, the transparent cover 420 and the first base material 2601 including the first electrode 2410 can be bonded together using the first bonding layer 2605. Alternatively, the first base material 2601 can be bonded to the second base material 2603 using the second bonding layer 2607. Alternatively, the second base material 2603 including the second electrode 2420 can be bonded to the polarizing layer 1004 using the third bonding layer 2609.

According to various embodiments, at least one of the first base material 2601 and the second bonding layer 2607 can be the first dielectric layer 2430 of FIG. 24. That is, the first base material 2601 and/or the second bonding layer 2607 can insulate between the first electrode 2410 and the second electrode 2420 to detect a location of a touch of the external object. Alternatively, the first base material 2601 and/or the second bonding layer 2607 can insulate between the first electrode 2410 and the second electrode 2420 to detect pressure of the external object. The first base material 2601 serving as the first dielectric layer 2430 can support the first electrode 2410. Alternatively, the second bonding layer 2607 serving as the first dielectric layer 2430 can bond the first base material 2601 with the second base material 2603. The second bonding layer 2607 can include at least part of a different material from the first bonding layer 2605 or the third bonding layer 2609. Alternatively, the second bonding layer 2607 can be thicker than the first bonding layer 2605 or the third bonding layer 2609.

Referring to FIG. 26B, the first electrode 2410 can be formed on the transparent cover 420. That is, the first electrode 2410 can be integrated with the transparent cover 420. The first electrode 2410 can face the second direction D2 on the transparent cover 420. The second electrode 2420 can be formed on a first base material 2611.

According to various embodiments, the transparent cover 420 including the first electrode 2410, the first base material 2611 including the second electrode 2420, and the polarizing layer 1004 can be bonded together using bonding layers 2613 and 2615. For example, the transparent cover 420 including the first electrode 2410 can be bonded to the first base material 2611 including the second electrode 2420 using the first bonding layer 2613. Alternatively, the first base material 2611 including the second electrode 2420 can be bonded to the polarizing layer 1004 using the second bonding layer 2615.

According to various embodiments, the first bonding layer 2613 can be the first dielectric layer 2430 of FIG. 24. That is, the first bonding layer 2613 can insulate between the first electrode 2410 and the second electrode 2420 to detect a location of the touch of the external object. Alternatively, the first bonding layer 2613 serving as the first dielectric layer 2430 can insulate between the first electrode 2410 and the second electrode 2420 to detect the pressure of the external object. The first bonding layer 2613 serving as the first dielectric layer 2430 can bond the transparent cover 420 with the first base material 2611. The first bonding layer 2613 can include at least part of a different material from the second bonding layer 2615. Alternatively, the first bonding layer 2613 can be thicker than the second bonding layer 2615.

Referring to FIG. 26C, the first electrode 2410 and the second electrode 2420 can be formed on a first base material 2621. The first electrode 2410 and the second electrode 2420 can be formed on either surface of the first base material 2621. That is, the first electrode 2410 can be formed on a first surface 2621a of the first base material 2621, and the second electrode 2420 can be formed on a second surface 2621b which is opposite to the first surface 2621a. The first electrode 2410 and the second electrode 2420 can be formed on the same base material.

According to various embodiments, the transparent cover 420, the first base material 2621, and the polarizing layer 1004 can be bonded together using bonding layers 2623 and 2625. For example, the transparent cover 420 and the first base material 2621 can be bonded together using the first bonding layer 2623. Alternatively, the first base material 2621 and the polarizing layer 1004 can be bonded together using the second bonding layer 2625.

According to various embodiments, the first bonding layer 2621 can be the first dielectric layer 2430 of FIG. 24. That is, the first bonding layer 2621 can insulate between the first electrode 2410 and the second electrode 2420 to detect a location of the touch of the external object. Alternatively, the first bonding layer 2621 can insulate between the first electrode 2410 and the second electrode 2420 to detect the pressure of the external object. The first bonding layer 2621 serving the first dielectric layer 2430 can support the first electrode 2410 and the second electrode 2420.

Referring to FIG. 26D, the first electrode 2410 can be formed on a first base material 2631. The second electrode 2420 can be formed on the polarizing layer 1004. While the first electrode 2410 faces, but not limited to, the first direction D1 on the first base material 2631, it may face the second direction D2 which is opposite to the first direction D1. Alternatively, while the second electrode 2420 faces, but not limited to, the second direction D2 on the polarizing layer 1004, it may face the first direction D1 which is opposite to the second direction D2.

According to various embodiments, the transparent cover 420, the first base material 2631 including the first electrode 2410, the polarizing layer 1004 including the second electrode 2420, and the display 510 can be bonded together using bonding layers 2633, 2635, and 2637. For example, the transparent cover 420 can be bonded to the first base material 2631 including the first electrode 2410 using the first bonding layer 2633. Alternatively, the first base material 2631 and the polarizing layer 1004 can be bonded together using the second bonding layer 2635. Alternatively, the polarizing layer 1004 and the display 510 can be bonded together using the third bonding layer 2637.

According to various embodiments, at least one of the first base material 2631, the second bonding layer 2635, and the polarizing layer 1004 can be the first dielectric layer 2430 of FIG. 24. That is, at least one of the first base material 2631, the second bonding layer 2635, and the polarizing layer 1004 can insulate between the first electrode 2410 and the second electrode 2420 to detect a location of the touch of the external object. Alternatively, at least one of the first base material 2631, the second bonding layer 2635, and the polarizing layer 1004 can insulate between the first electrode 2410 and the second electrode 2420 to detect the pressure of the external object.

Referring to FIG. 26E, the first electrode 2410 can be formed on a first base material 2641. The second electrode 2420 can be formed on the display 510. For example, the second electrode 2420 can be formed on the first substrate 1001 of the display 510.

The transparent cover 420, the first base material 2641 including the first electrode 2410, the polarizing layer 1004, and the display 510 can be bonded together using bonding layers 2643, 2645, and 2647. For example, the transparent cover 420 can be bonded to the first base material 2641 including the first electrode 2410 using the first bonding layer 2643. Alternatively, the first base material 2641 and the polarizing layer 1004 can be bonded together using the second bonding layer 2645. Alternatively, the polarizing layer 1004 can be bonded to the display 510 including the second electrode 2420 using the third bonding layer 2647.

According to various embodiments, at least one of the first base material 2641, the second bonding layer 2645, the polarizing layer 1004, and the third bonding layer 2647 can be the first dielectric layer 2430 of FIG. 24. That is, at least one of the first base material 2641, the second bonding layer 2645, the polarizing layer 1004, and the third bonding layer 2647 can insulate between the first electrode 2410 and the second electrode 2420 to detect a location of the touch of the external object. Alternatively, at least one of the first base material 2641, the second bonding layer 2645, the polarizing layer 1004, and the third bonding layer 2647 can insulate between the first electrode 2410 and the second electrode 2420 to detect the pressure of the external object.

Referring to FIG. 26F, the first electrode 2410 can be formed on the polarizing layer 1004. The second electrode 2420 can be formed on the display 510. For example, the second electrode 2420 can be formed on the first substrate 1001 of the display 510.

According to various embodiments, the transparent cover 420, the polarizing layer 1004 including the first electrode 2410, and the display 510 can be bonded together using bonding layers 2651 and 2653. For example, the transparent cover 420 can be bonded to the polarizing layer 1004 including the first electrode 2410 using the first bonding layer 2651. Alternatively, the polarizing layer 1004 and the display 510 can be bonded together using the second bonding layer 2653.

According to various embodiments, at least one of the polarizing layer 1004 and the second bonding layer 2653 can be the first dielectric layer 2430 of FIG. 24. That is, the polarizing layer 1004 and/or the second bonding layer 2653 can insulate between the first electrode 2410 and the second electrode 2420 to detect a location of the touch of the external object. Alternatively, the polarizing layer 1004 and/or the second bonding layer 2653 can insulate between the first electrode 2410 and the second electrode 2420 to detect the pressure of the external object.

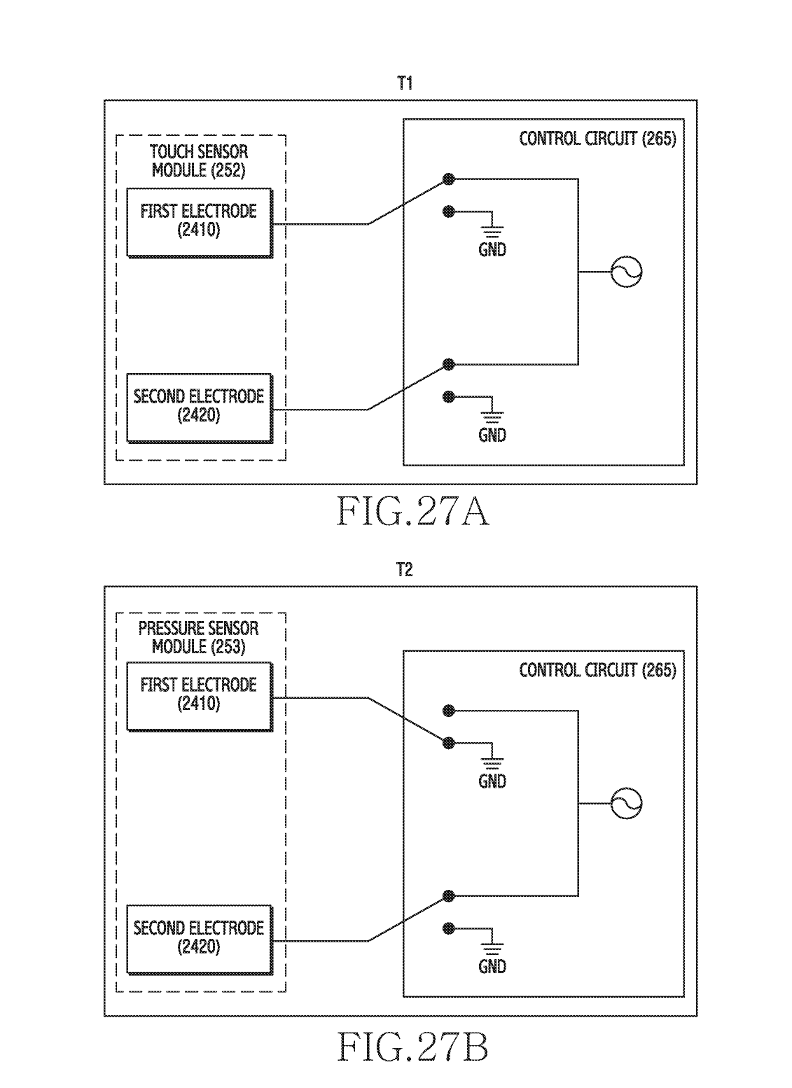

FIGS. 27A and 27B are block diagrams of an electronic apparatus according to various embodiments of the present disclosure.

Referring to FIG. 27A, the control circuit 265 can drive the first electrode 2410 and the second electrode 2420 as the touch sensor module 252 in the first time intervals T1. In the first time periods T1, the control circuit 265 can apply a transmit signal to the first electrode 2410 and receive a receive signal corresponding to the transmit signal through the second electrode 2420. Alternatively, in the first time periods T1, the control circuit 265 can apply a transmit signal for locating the touch to the second electrode 2420, and receive a receive signal corresponding to the transmit signal through the first electrode 2410. The control circuit 265 can detect a location of the touch by detecting a capacitance change between the first electrode 2410 and the second electrode 2420 based on the touch of the external object.

Referring to FIG. 27B, the control circuit 265 can drive the first electrode 2410 and the second electrode 2420 as the pressure sensor module 253 in the second time intervals T2. In the second time periods T2, the control circuit 265 can connect the first electrode 2410 to the GND and apply a transmit signal for detecting the pressure to the second electrode 2420. In the second time periods T2, the control circuit 265 can detect a capacitance change of each individual electrode of the second electrode 2420 based on a distance change between the first electrode 2410 and the second electrode 2420 according to the pressure of the external object. Alternatively, in the second time periods T2, the control circuit 265 can connect the second electrode 2420 to the GND and apply a transmit signal for detecting the pressure to the first electrode 2410. In so doing, in the second time periods T2, the control circuit 265 can detect a capacitance change of each individual electrode of the first electrode 2410 based on the distance change between the first electrode 2410 and the second electrode 2420 according to the pressure of the external object.

In second time intervals T2, the control circuit 265 can drive apply a transmit signal for detecting the pressure to, but not limited to, the second electrode 2420 and receive a receive signal corresponding to the transmit signal through, but not limited to, the second electrode 2420. Alternatively, in second time intervals T2, the control circuit 265 can apply a transmit signal for detecting the pressure to the first electrode 2410, and receive a receive signal corresponding to the transmit signal through the second electrode 2420. The control circuit 265 can detect the capacitance change based on a thickness change of the first dielectric layer 2430, that is, based on the distance change between the first electrode 2410 and the second electrode 2420 according to the pressure of the external object.

According to various embodiments, an electronic device 101 can include a housing 410 including a first surface 410a facing a first direction a second surface 410b facing a second direction D2 which is opposite to the first direction D1, and a transparent cover 420 which forms at least part of the first surface 410a; a display 510 interposed between the first surface 410a and the second surface 410b of the housing and exposed through the transparent cover 420; a first electrode 520 interposed between the transparent cover 420 and the display 510; a second electrode 530 interposed between the first electrode 520 and the display 510; a third electrode 540 interposed between the second electrode 530 and the display 510; a first dielectric layer 550 interposed between the first electrode 520 and the second electrode 530; a second dielectric layer 560 interposed between the second electrode 530 and the third electrode 540; and at least one control circuit 265 electrically coupled to the display 510, the first electrode 520, the second electrode 530, and the third electrode 540, wherein the at least one control circuit 265 detects a location of a touch of an external object on the first surface 510a using the first electrode 520 and the second electrode 530, and detects pressure of the external object on the first surface 510a using the second electrode 530 and the third electrode 540.

According to various embodiments, the at least one control circuit 265 can apply a transmit signal to the second electrode 530, and receive a receive signal corresponding to the transmit signal through the first electrode 520 and the third electrode 540.

According to various embodiments, the at least one control circuit 265 can receive the receive signal through the first electrode 520 in first time periods T1, and receive the receive signal through the third electrode 540 in second time periods T2.

According to various embodiments, the second time periods T2 may not overlap at least part of the first time periods T1.

According to various embodiments, the at least one control circuit 265 can control the display 510 in third time periods T3 which do not overlap at least part of the first time periods T1 or the second time periods T2.

According to various embodiments, at least one of the first time period T1, the second time period T2, and the third time period T3 can have a different interval.

According to various embodiments, the second dielectric layer 560 can include at least part of a different material from the first dielectric layer 550.

According to various embodiments, the second dielectric layer 560 can be thicker than the first dielectric layer 550.

According to various embodiments, at least one of the first electrode 520, the second electrode 530, and the third electrode 540 can include at least one of indium tin oxide (ITO) indium zinc oxide (IZO), Poly(3,4-ethylenedioxythiophene) (PEDOT), Ag nanowire, transparent conducting polymer, and grapheme.

According to various embodiments, the display 510 can include an OLED.

According to various embodiments, the first electrode 520 can include a first opening 620 which overlaps at least part of the third electrode 540, when viewed from the transparent cover 420, and the third electrode 540 can include a second opening 820 which overlaps at least part of the first electrode 520, when viewed from the transparent cover 420.

According to various embodiments, at least one of the first electrode 520, the second electrode 530, and the third electrode 540 can be formed on the transparent cover 420.

According to various embodiments, at least one of the first electrode 520, the second electrode 530, and the third electrode 540 can be formed on the first dielectric layer 550 or the second dielectric layer 560.

According to various embodiments, at least one of the first electrode 520, the second electrode 530, and the third electrode 540 can be formed directly on the display 510.

According to various embodiments, an electronic apparatus can include a housing 410 including a first surface 410a facing a first direction D1, a second surface 410b facing a second direction D2 which is opposite to the first direction D1, and a transparent cover 420 which forms at least part of the first surface 410a; a display 510 interposed between the first surface 410a and the second surface 410b of the housing 410 and exposed through the transparent cover 420; a first electrode 1210 interposed between the transparent cover 420 and the display 510; a second electrode 1220 interposed between the first electrode 1210 and the display 510; a third electrode 1230 substantially coplanar with the second electrode 1220; a first dielectric layer 1240 interposed between the first electrode 1210 and the second electrode 1220; a second dielectric layer 1310 interposed between the second electrode 1220 and the third electrode 1230; and at least one control circuit 265 electrically coupled to the display 510, the first electrode 1210, the second electrode 1220, and the third electrode x1230.

The control circuit 265 can detect pressure of an external object on the first surface 410a using the first electrode 1210 and the second electrode 1220, and detects a location of a touch of the external object on the first surface 410a using the first electrode 1210 and the third electrode 1230.

According to various embodiments, when viewed from the transparent cover 420, an overlapping region of the first electrode 1210 and the second electrode 1220 is greater than an overlapping region of the first electrode 1210 and the third electrode 1230.

According to various embodiments, an electronic device 2401 can include a housing 410 including a first surface 410a facing a first direction D1, a second surface 410b facing a second direction D2 which is opposite to the first direction D1, and a transparent cover 420 which forms at least part of the first surface 410a; a display 510 interposed between the first surface 410a and the second surface 410b of the housing 410 and exposed through the transparent cover 420; a first electrode 2410 interposed between the transparent cover 420 and the display 510; a second electrode 2420 interposed between the transparent cover 420 and the display 510; and at least one control circuit 265 electrically coupled to the display 510, the first electrode 2410, and the second electrode 2420, wherein the control circuit 265 detects a location of a touch of an external object on the first surface 410a using the first electrode 2410 and the second electrode 2420, and detects pressure of the external object on the first surface 410a using the first electrode 2410 and the second electrode 2420.

According to various embodiments, the electronic device 2401 can further include a first dielectric layer 1240 interposed between the first electrode 2410 and the second electrode 2420, wherein the first electrode 2410 and the second electrode 2420 are disposed on either surface of the first dielectric layer 1240.

According to various embodiments, the at least one control circuit 265 can apply a transmit signal for locating the touch to the first electrode 2410, and receives a receive signal corresponding to the transmit signal through the second electrode 2420.

According to various embodiments, the at least one control circuit 265 can apply a transmit signal for detecting the pressure to the first electrode 2410, and receives a receive signal corresponding to the transmit signal through the second electrode 2420.

As set forth above, by integrating the pressure sensor module with the touch sensor module, the thickness and the volume of the electronic apparatus can be reduced. The power consumption can also lessen by integrating the control circuit for controlling the pressure sensor with the control circuit for controlling the touch sensor.

While the present disclosure has been shown and described with reference to various embodiments thereof, it will be understood by those skilled in the art that various changes in form and details may be made therein without departing from the spirit and scope of the present disclosure as defined by the appended claims and their equivalents.

What is claimed is:

1. An electronic apparatus comprising:
a housing comprising a first surface facing a first direction, a second surface facing a second direction which is opposite to the first direction, and a transparent cover which forms at least part of the first surface;
a display interposed between the first surface and the second surface of the housing and exposed through the transparent cover;
a first electrode interposed between the transparent cover and the display;
a second electrode interposed between the first electrode and the display;
a third electrode interposed between the second electrode and the display;
a first dielectric layer interposed between the first electrode and the second electrode;
a second dielectric layer interposed between the second electrode and the third electrode; and
at least one processor electrically coupled to the display, the first electrode, the second electrode, and the third electrode,
wherein the at least one processor is configured to:
detect a location of a touch input of an external object on the first surface using the first electrode and the second electrode, and
detect pressure of the touch input of the external object on the first surface using the second electrode and the third electrode.

2. The electronic apparatus of claim 1, wherein the at least one processor is configured to:
apply a transmit signal to the second electrode, and
receive a receive signal corresponding to the transmit signal through the first electrode and the third electrode.

3. The electronic apparatus of claim 2, wherein the at least one processor is configured to:
receive the receive signal through the first electrode in first time periods, and
receive the receive signal through the third electrode in second time periods.

4. The electronic apparatus of claim 3, wherein the second time periods do not overlap at least part of the first time periods.

5. The electronic apparatus of claim 3, wherein the at least one processor controls the display in third time periods which do not overlap at least part of the first time periods or the second time periods.

6. The electronic apparatus of claim 5, wherein at least one of the first time period, the second time period, or the third time period has a different interval.

7. The electronic apparatus of claim 1, wherein the second dielectric layer comprises at least part of a different material from the first dielectric layer.

8. The electronic apparatus of claim 1, wherein the second dielectric layer is thicker than the first dielectric layer.

9. The electronic apparatus of claim 1, wherein at least one of the first electrode, the second electrode, or the third electrode comprises at least one of indium tin oxide (ITO), indium zinc oxide (IZO), Poly(3,4-ethylenedioxythiophene) (PEDOT), Ag nanowire, transparent conducting polymer, or grapheme.

10. The electronic apparatus of claim 1, wherein the display comprises an organic light emitting diode (OLED).

11. The electronic apparatus of claim 1, wherein the first electrode comprises a first opening which overlaps at least part of the third electrode, when viewed from the transparent cover, and
wherein the third electrode comprises a second opening which overlaps at least part of the first electrode, when viewed from the transparent cover.

12. The electronic apparatus of claim 1, wherein at least one of the first electrode, the second electrode, or the third electrode is formed on the transparent cover.

13. The electronic apparatus of claim 1, wherein at least one of the first electrode, the second electrode, or the third electrode is formed on the first dielectric layer or the second dielectric layer.

14. The electronic apparatus of claim 1, wherein at least one of the first electrode, the second electrode, or the third electrode is formed directly on the display.

15. An electronic apparatus comprising:
a housing comprising a first surface facing a first direction, a second surface facing a second direction which is opposite to the first direction, and a transparent cover which forms at least part of the first surface;
a display interposed between the first surface and the second surface of the housing and exposed through the transparent cover;
a first electrode interposed between the transparent cover and the display;
a second electrode interposed between the first electrode and the display;
a third electrode substantially coplanar with the second electrode;
a first dielectric layer interposed between the first electrode and the second electrode;
a second dielectric layer interposed between the second electrode and the third electrode; and
at least one processor electrically coupled to the display, the first electrode, the second electrode, and the third electrode,
wherein the processor is configured to:
detect pressure of a touch input of an external object on the first surface using the first electrode and the second electrode, and
detect a location of the touch input of the external object on the first surface using the first electrode and the third electrode.

16. The electronic apparatus of claim 15, wherein, when viewed from the transparent cover, an overlapping region of the first electrode and the second electrode is greater than an overlapping region of the first electrode and the third electrode.

17. An electronic apparatus comprising:
a housing comprising a first surface facing a first direction, a second surface facing a second direction which is opposite to the first direction, and a transparent cover which forms at least part of the first surface;
a display interposed between the first surface and the second surface of the housing and exposed through the transparent cover;
a first electrode interposed between the transparent cover and the display;
a second electrode interposed between the transparent cover and the display; and
at least one processor electrically coupled to the display, the first electrode, and the second electrode,
wherein the processor is configured to:
detect a location of a touch input of an external object on the first surface using the first electrode and the second electrode, and
detect pressure of the touch input of external object on the first surface using the first electrode and the second electrode.

18. The electronic apparatus of claim 17, further comprising:
a first dielectric layer interposed between the first electrode and the second electrode,
wherein the first electrode and the second electrode are disposed on either surface of the first dielectric layer.

19. The electronic apparatus of claim 17, wherein the at least one processor is configured to:
apply a transmit signal for locating the touch to the first electrode, and
receive a receive signal corresponding to the transmit signal through the second electrode.

20. The electronic apparatus of claim 17, wherein the at least one processor is configured to:
apply a transmit signal for detecting the pressure to the first electrode, and
receive a receive signal corresponding to the transmit signal through the second electrode.
